(19) United States
(12) Patent Application Publication
(10) Pub. No.: US 2018/0219187 A1
(43) Pub. Date: Aug. 2, 2018

(54) VAPOR DEPOSITION SOURCE, VAPOR DEPOSITION DEVICE, AND METHOD FOR MANUFACTURING VAPOR DEPOSITION FILM

(71) Applicant: Sharp Kabushiki Kaisha, Sakai City, Osaka (JP)

(72) Inventors: Satoshi INOUE, Sakai City (JP); Katsuhiro KIKUCHI, Sakai City (JP); Shinichi KAWATO, Sakai City (JP); Manabu NIBOSHI, Sakai City (JP); Yuhki KOBAYASHI, Sakai City (JP)

(21) Appl. No.: 15/747,186

(22) PCT Filed: Aug. 3, 2016
(86) PCT No.: PCT/JP2016/072871

§ 371 Date: Jan. 24, 2018

(30) Foreign Application Priority Data
Aug. 10, 2015 (JP) 2015-158559

(51) Int. Cl. H01L 51/56; C23C 14/26; H01L 51/00

(52) U.S. Cl. CPC H01L 51/56; H01L 51/001; C23C 14/26

(57) ABSTRACT

A vapor deposition particles ejecting unit (30) in a vapor deposition source (10) includes: a plurality of stages of nozzle units each including at least one vapor deposition nozzle (32, 52) and stacked while separated from each other in a vertical direction; and at least one hollow portion (43) formed between the at least one vapor deposition nozzle and the at least one vapor deposition nozzle of respective stages. The at least one hollow portion is surrounded on four sides by a side wall (44) including at least one opening (45) formed in the side wall and connecting the at least one hollow portion and a vacuum chamber space (2a).

### TECHNICAL FIELD

The present invention relates to a vapor deposition source, a vapor deposition device including the vapor deposition source, and a vapor deposition film manufacturing method using the vapor deposition device to manufacture (that is, film forming) the vapor deposition film.

### BACKGROUND ART

EL display devices including EL elements using Electro luminescence (hereinafter, referred to as “EL”) made from organic or inorganic materials have been developed as a candidate of a next-generation display technique which has an all-solid-type structure, self luminous characteristics, and excel in lower driving voltage, and high-speed responsivity.

The EL elements are generally film-formed by a vacuum vapor deposition technique which evaporates vapor deposition particles (target film forming components) onto a target film forming substrate under reduced pressure (high vacuum) through a vapor deposition mask (also referred to as “a shadow mask”) to which predetermined pattern openings are formed. In the above application, a scan vapor deposition technique which does not require the vapor deposition mask and a vapor deposition source both as large as a larger target film forming substrate, is the promising method for a large substrate film forming technique for processing a larger substrate as the target film forming substrate. In the scan vapor deposition technique, scan film forming is performed in which the film forming is performed while the target film forming substrate is scanned using the vapor deposition source smaller than the target film forming substrate, or using the vapor deposition mask and the vapor deposition source both smaller than the target film forming substrate.

In the film forming using the vacuum vapor deposition technique, a vapor deposition material is heated to be vaporized or sublimated under high vacuum in a vacuum chamber. The vacuum chamber can hold the inside under reduced pressure, and the vapor deposition source including a heater and an ejection port is disposed in the vacuum chamber. The vapor deposition material vaporized or sublimated after being heated by the heater is ejected outside from ejection ports as vapor deposition particles to cover the target film forming substrate.

Unfortunately, the vapor deposition material vaporized or sublimated after being heated by the heater is ejected from ejection ports after scattering by an inner wall of the vapor deposition source (that is, the inner wall of a holder containing the heater), and repeating collisions among the vapor deposition particles.

Due to this scattering of the vapor deposition particles, the vapor deposition particles ejected from the ejection ports are ejected in various directions.

In the vacuum vapor deposition technique, the vapor deposition particles ejected toward the target film forming substrate contribute to the film forming; however, other vapor deposition particles do not contribute to the film forming. Thus, in the vacuum vapor deposition technique, the material not layered on the target film forming substrate as the vapor deposition film becomes a loss. Consequently, the lower directivity of the vapor deposition particles results in the lower material utilization efficiency.

Thus, methods have been suggested in which the scattering direction of the vapor deposition particles is restricted to increase directivity of the vapor deposition particles, and, appropriately lead the vapor deposition particles to the evaporation area (e.g., PTL 1).

PTL 1 discloses that the flow of the vapor deposition particles (a vapor deposition flow) is controlled by using regulation plates configured to regulate the flight direction of the vapor deposition particles to improve utilization efficiency of the vapor deposition material and film forming quality and thus to realize uniform vapor deposition.

In the vapor deposition device described in PTL 1, the target film forming substrate as a vapor deposition target and the vapor deposition source are disposed in the vacuum chamber. The vapor deposition device is configured to form the vapor deposition film (not illustrated) on the target film forming substrate by covering the target film forming substrate with the vapor deposition particles discharged from the vapor deposition source.

The vapor deposition source described in PTL 1 includes three frames which are stacked. A heating coil is wound around each of the frames.

The lowest frame is a heater (vapor deposition particles generation section) configured to generate the vapor deposition particles by containing and heating the vapor deposition material. The rest of the two frames are vapor deposition flow regulation layers (vapor deposition flow controllers) configured to regulate the direction of the vapor deposition particles heading from the lowest frame, that is heater, to the target film forming substrate.

A plurality of ventilation partitions having nozzle shape (vapor deposition nozzles, the ejection ports) are formed in the two frames used as vapor deposition flow regulation layers. The ventilation partitions are divided by the regulation plates which are installed upright in the direction from the lowest frame used as the heater to the target film forming substrate.

With the above, the scattering direction of the vapor deposition particles discharged from the heater through each of the ventilation partitions is regulated to the direction along side faces of the regulation plates in each of the ventilation partitions.

### CITATION LIST

### Patent Literature

PTL 1: JP 2004-137583 A (published on May. 13, 2004)

### SUMMARY OF INVENTION

### Technical Problem

In PTL 1, scattering of the vapor deposition particles in a X axis direction, that is an alignment direction of the regulation plates, is regulated. However, in the vapor deposition device described in PTL 1, the high pressure in the ventilation partitions and the low pressure in the vacuum chamber result in a large pressure difference between the pressure in the ventilation partitions and the pressure in the vacuum chamber.

Consequently, in the vapor deposition device described in PTL 1, particles scattering eventually occurs at the outlet of the ventilation partitions to increase unnecessary vapor deposition particles scattering in the X axis direction, that is the alignment direction of the regulation plates.

As the result, the structure described in PTL 1 results in broad film thickness distribution of the vapor deposition of the vapor deposition film in the x axis direction and the low material utilization efficiency.

Especially, in a case of the scan film forming using the scan vapor deposition technique, to control the vapor deposition flow, a film thickness distribution restriction member (not illustrated) which is referred to as a restriction plate, is preferably disposed over the vapor deposition source, and the vapor deposition mask (not illustrated) is fixedly disposed over the film thickness distribution restriction member, and a target film forming substrate 200 is further disposed over the vapor deposition mask.

In the structure described in PTL 1, the regulation of vapor deposition flow by the limitation member increases because the film thickness distribution of the vapor deposition film in the X axis direction becomes broad. Consequently, the material utilization efficiency contributing to the film forming further decreases.

In light of the foregoing, an object of the present invention is to provide the vapor deposition source, the vapor deposition device and the method for manufacturing the vapor deposition film with higher material utilization efficiency than that of the related art.

### Solution to Problem

For coping with the problem, a vapor deposition source according to an aspect of the present invention includes a vapor deposition particles generation section configured to heat a vapor deposition material and generate vapor deposition particles in a gaseous state, and a vapor deposition particles ejecting section configured to eject the vapor deposition particles generated in the vapor deposition particles generation section. The vapor deposition particles ejecting section is at least disposed in a vacuum chamber and includes a plurality of stages of vapor deposition nozzle sections each including at least one vapor deposition nozzle and stacked while separated from each other in a vertical direction, and at least one hollow portion formed between the at least one vapor deposition nozzle and the at least one vapor deposition nozzle of respective stages of the plurality of stages of vapor deposition nozzle sections. The hollow portion is surrounded on four sides by an outer wall including at least one opening formed in the outer wall and connecting the at least one hollow portion and an inner space of the vacuum chamber.

For coping with the above, a vapor deposition device according to an aspect of the present invention is a vapor deposition device configured to form a vapor deposition film with a predetermined pattern on a target film forming substrate and includes a vapor deposition unit including the vapor deposition source and the vacuum chamber configured to hold at least the vapor deposition particles ejecting section of the vapor deposition unit in the vacuum chamber under reduced pressure atmosphere.

For coping with the above, a method for manufacturing a vapor deposition film according to an aspect of the present invention is a method for forming a vapor deposition film on a target film forming substrate using a vapor deposition device. The vapor deposition device includes a vapor deposition unit and a vacuum chamber. The vapor deposition unit includes a vapor deposition source including a vapor deposition particles generation section configured to heat a vapor deposition material and generate vapor deposition particles in a gaseous state and a vapor deposition particles ejecting section configured to eject the vapor deposition particles generated in the vapor deposition particles generation section. The vapor deposition particles ejecting section is at least disposed in a vacuum chamber and includes a plurality of stages of vapor deposition nozzle sections each including at least one vapor deposition nozzle and stacked while separated from each other in a vertical direction and at least one hollow portion formed between the at least one vapor deposition nozzle and the at least one vapor deposition nozzle of respective stages of the plurality of stages of vapor deposition nozzle sections. The at least one hollow portion is surrounded on four sides by an outer wall including at least one opening formed in the outer wall and connecting the at least one hollow portion and an inner space of the vacuum chamber. The vacuum chamber is configured to hold at least the vapor deposition particles ejecting section of the vapor deposition unit in the vacuum chamber under reduced pressure atmosphere. The method includes ejecting the vapor deposition particles from the vapor deposition source under the reduced pressure atmosphere, and covering a target film forming area on the target deposition substrate with the vapor deposition particles.

### Advantageous Effects of Invention

According to one aspect of the present invention, the vapor deposition source, the vapor deposition device and the method for manufacturing the vapor deposition film with higher material utilization efficiency than that of the related art can be provided.

### BRIEF DESCRIPTION OF DRAWINGS

FIG. 1 is a perspective view illustrating a schematic structure of a vapor deposition source according to a first embodiment of the present invention.

FIG. 2 is a plan view illustrating the schematic structure of the vapor deposition source illustrated in FIG. 1.

FIG. 3 is a perspective view illustrating a schematic structure of the principal part of a vapor deposition device according to the first embodiment of the present invention.

FIGS. 4A to 4C are diagrams explaining derivation of an n value.

FIG. 5A is a graph schematically showing film thickness distribution of a vapor deposition film formed by vapor deposition particles passing a second-stage nozzle after passing a first-stage nozzle, and FIG. 5B is a graph schematically showing film thickness distribution of the vapor deposition film formed by the vapor deposition particles passing the first-stage nozzle.

FIG. 6 is a graph showing effect of the vapor deposition device according to the first embodiment of the present invention.

FIG. 7 is a perspective view illustrating a schematic structure of the principal part of the vapor deposition device according to an example of a modified example of the first embodiment of the present invention.

FIG. 8 is a perspective view illustrating a schematic structure of the vapor deposition source according to a second embodiment of the present invention.

FIG. 9 is a plan view illustrating the schematic structure of the vapor deposition source illustrated in FIG. 8.

FIG. 10 is a perspective view illustrating a schematic structure of the principal part of the vapor deposition device according to the second embodiment of the present invention.

FIGS. 11A and 11B are graphs showing effect of the vapor deposition source according to the second embodiment of the present invention.

FIG. 12 is a perspective view illustrating a schematic structure of the vapor deposition source according to a third embodiment of the present invention.

FIG. 13 is a plan view illustrating the schematic structure of the vapor deposition source illustrated in FIG. 12.

FIGS. 14A and 14B are graphs showing effect of the vapor deposition source according to the third embodiment of the present invention.

FIG. 15 is a perspective view illustrating a schematic structure of the vapor deposition source according to a fourth embodiment of the present invention.

FIG. 16 is a plan view illustrating the schematic structure of the vapor deposition source illustrated in FIG. 15.

FIG. 17 is a graph showing effect of the vapor deposition device according to the fourth embodiment of the present invention.

FIG. 18 is a perspective view illustrating a schematic structure of the vapor deposition source according to a fifth embodiment of the present invention.

FIG. 19 is a plan view illustrating the schematic structure of the vapor deposition source illustrated in FIG. 18.

FIG. 20 is a graph showing effect of the vapor deposition device according to the fifth embodiment of the present invention.

### DESCRIPTION OF EMBODIMENT

One example of embodiments of the present invention will be described in detail below.

### First Embodiment

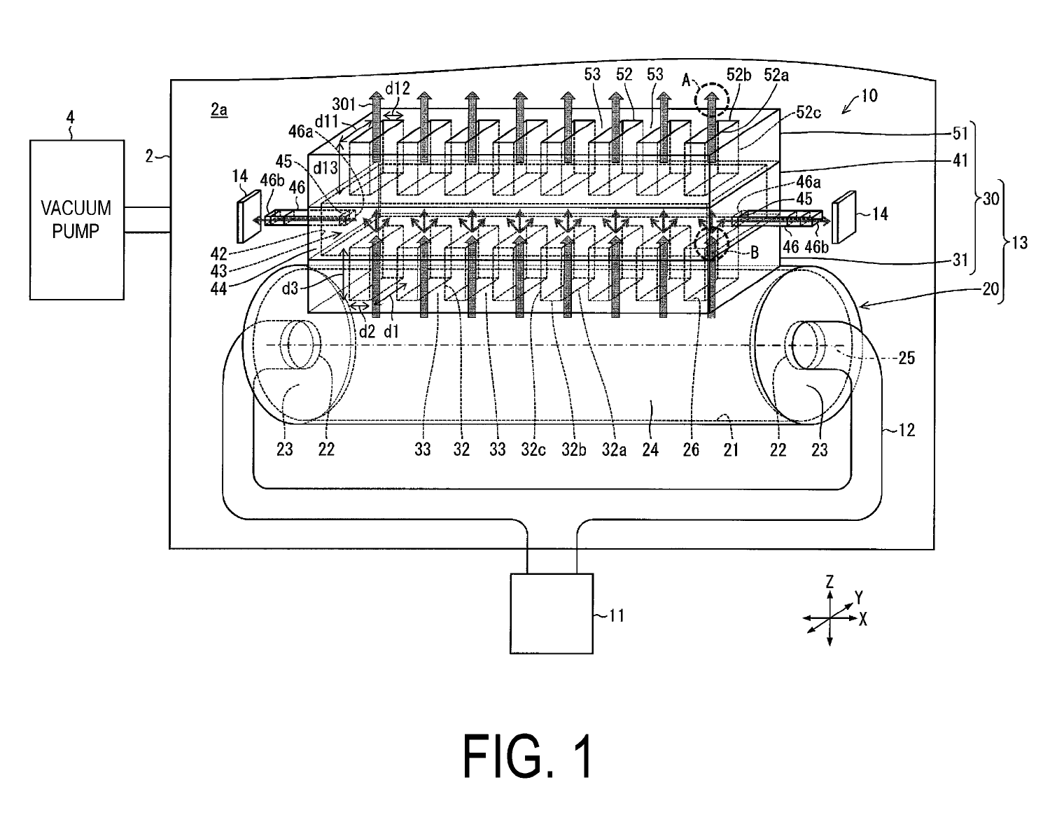

One embodiment of the present invention will be described on the basis of FIG. 1 to FIG. 7 as follows.

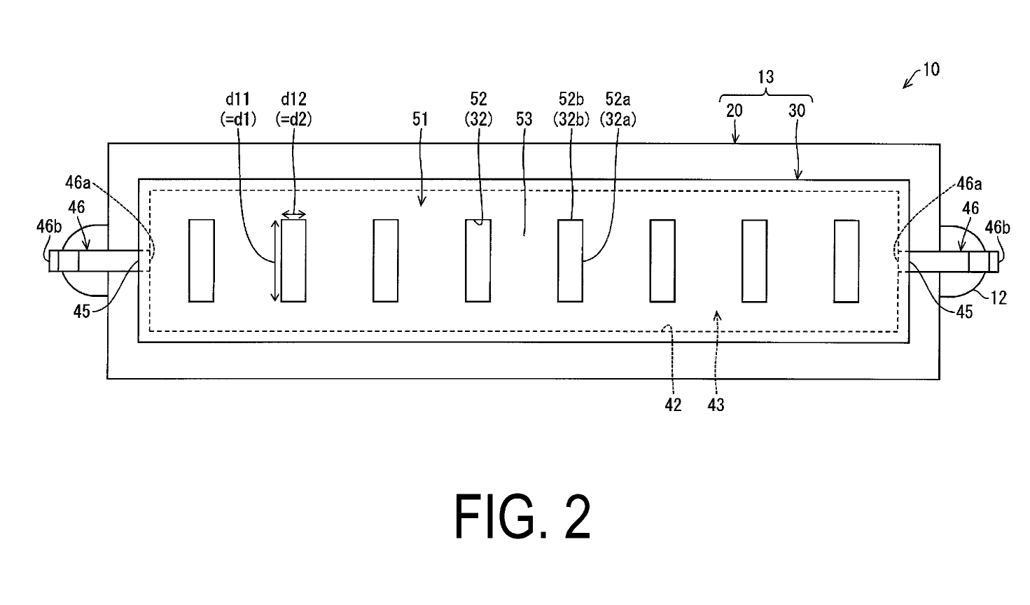

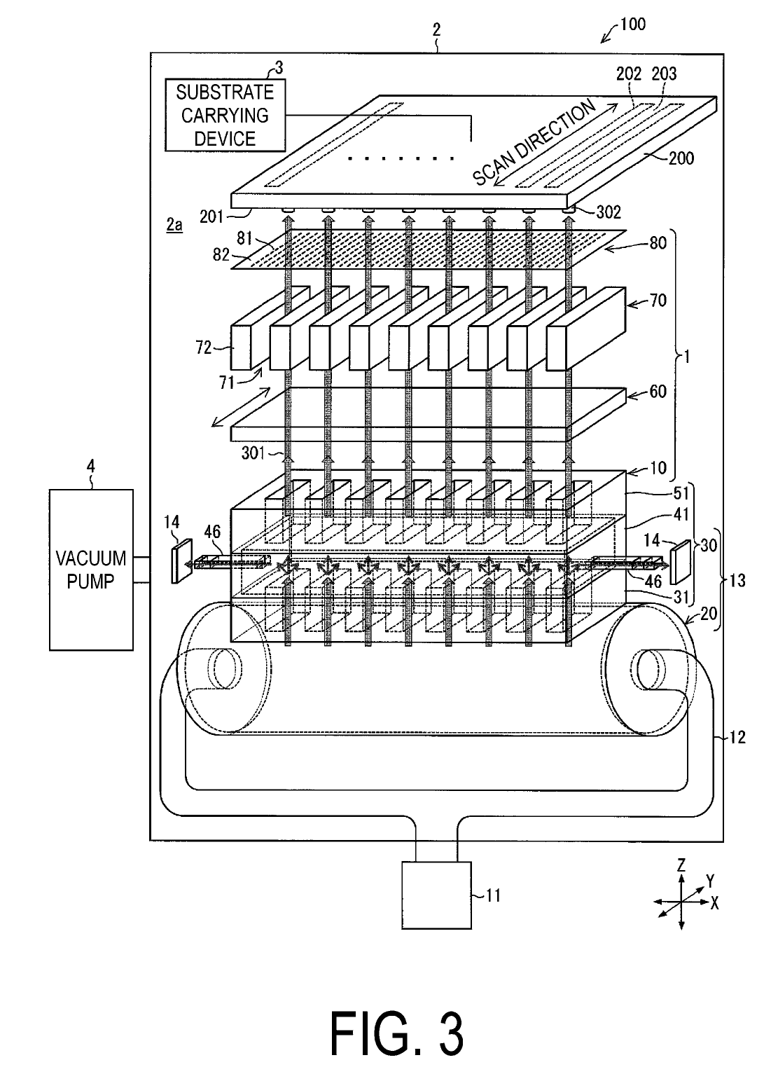

FIG. 1 is a perspective view illustrating a schematic structure of a vapor deposition source 10 according to a first embodiment. FIG. 2 is a plan view illustrating the schematic structure of the vapor deposition source 10 illustrated in FIG. 1. FIG. 3 is a perspective view illustrating a schematic structure of the principal part of a vapor deposition device 100 according to the present embodiment.

In FIG. 1 to FIG. 3, the number of vapor deposition nozzles 32 and 52, the number of restriction plate openings 71, and the number of mask openings 81 and other descriptions are partially omitted, and each structural element shape is simplified for the sake of convenience of illustration.

The vapor deposition device 100 (film forming device) and the method for manufacturing the vapor deposition film (film forming method, evaporation method) according to the present embodiment are specifically useful for evaporation (film forming) of an EL layer such as a light-emitting layer forming an EL element in EL display devices such as an organic EL display.

One example will be described as follows, as a case that the vapor deposition device 100 and the method for manufacturing the vapor deposition film according to the present embodiment are applied to the manufacture of the organic EL display with RGB full-color display in which the organic EL elements for red (R), green (G), blue (B) are arranged onto a substrate as sub pixels. In the example, RGB separate coating method is used for film-forming the light-emitting layer (organic film) of the organic EL elements as a vapor deposition film 302.

However, the present embodiment is not limited to the above, and the vapor deposition device 100 and the method for manufacturing the vapor deposition film according to the present embodiment are applicable to general device manufacturing schemes using the vapor deposition technique including manufacturing schemes of the organic EL display devices and the inorganic EL display devices.

Note that, in the following description, a horizontal axis along a direction (scan direction) in which the target film forming substrate 200 is carried is denoted as a Y axis; a horizontal axis along a direction perpendicular to the scan direction of the target film forming substrate 200 is denoted as an X axis; and a vertical axis (up-down direction axis) which is in a direction of the normal line of a target film forming surface 201 in the target film forming substrate 200 and perpendicular to both the X axis and the Y axis is denoted as a Z axis. Furthermore, the X axis direction is referred as a row direction (first direction), and the Y axis direction is referred to as a column direction (second direction), and except for specifically mentioned, an up-arrow direction of the Z axis is referred to as an upside for the sake of explanatory convenience.

### Schematic Structure of Vapor Deposition Device 100

As illustrated in FIG. 3, the vapor deposition device 100 according to the present embodiment includes a vapor deposition unit 1, a vacuum chamber 2, a substrate carrying device 3 (substrate moving device), a vacuum pump 4 (evacuation pump), an adhesion prevention plate and a controller (both not illustrated).

Furthermore, the vapor deposition unit 1 includes the vapor deposition source 10, a shutter 60, a restriction plate unit 70, a vapor deposition mask 80, and various holding members (not illustrated) for holding the vapor deposition source 10, the shutter 60, the restriction plate unit 70, and the vapor deposition mask 80.

As illustrated in FIG. 1 to FIG. 3, the vapor deposition source 10 includes a vapor deposition particles generation unit 11, a pipe 12, and a vapor deposition source main body 13. Among the above, the vapor deposition source main body 13 and part of the pipe 12 are disposed in the vacuum chamber 2 with the substrate carrying device 3, the shutter 60, the restriction plate unit 70, the vapor deposition mask 80, the various holding members (not illustrated) and the adhesion prevention plate.

The part of the pipe 12, the vapor deposition particles generation unit 11, the vacuum pump 4, and the controller (not illustrated) are disposed outside of the vacuum chamber 2.

The target film forming substrate 200, the vapor deposition mask 80, the restriction plate unit 70, the shutter 60, and the vapor deposition source 10 are disposed facing each other in the Z axis direction in this order from the target film forming substrate 200 side, for example, and are spaced from each other at a distance. Among the above, the vapor deposition mask 80, the restriction plate unit 70, and the vapor deposition source 10 have fixed positional relation to each other (that is, the positional relation in the X axis, Y axis, and Z axis).

The target film forming substrate 200, the vapor deposition mask 80, the restriction plate unit 70, the shutter 60, and the vapor deposition source 10 are held by the holding members (not illustrated) as needed. The vapor deposition mask 80, the restriction plate unit 70, the shutter 60, and the vapor deposition source 10 may be held by a single holding member or may be separately held by respective holding members as long as the positional relation is maintained.

An example will be described below in which the vapor deposition source 10 is disposed under the target film forming substrate 200 with the target film forming surface 201 thereof facing downward, and the vapor deposition particles are evaporated (an up deposition) from below upward, and each of the vapor deposition mask 80, the restriction plate unit 70, and the vapor deposition source 10 is fixed by the respective holding members or is directly fixed to the inner wall of the vacuum chamber 2. However, the present embodiment is not limited to the structure.

Each structural element described above will be described in detail as follows.

### Vacuum Chamber 2

The vacuum chamber 2 is a film forming vessel including an airtight film forming container which can hold the inside under the reduced pressure (under vacuum). The vacuum chamber 2 includes the vacuum pump 4 provided thereto. The vacuum pump 4 is configured to evacuate the vacuum chamber 2 in a vacuum state through an exhaust port (not illustrated) to hold the inside of the vacuum chamber 2 under vacuum (a predetermined degree of vacuum) during the vapor deposition. As described above, the vacuum pump 4 is disposed outside of the vacuum chamber 2.

The vacuum chamber 2 is preferably held in high vacuum and a degree of vacuum (ultimate pressure) in the vacuum chamber 2 (that is, the vacuum chamber space 2a) is preferably 1×10⁻³ Pa or greater (in other words, pressure is 1.0×10⁻³ Pa or less).

A necessary and sufficient value for mean free path of vapor deposition particles 301 can be obtained at a degree of vacuum of 1.0×10⁻³ Pa or greater.

In a case that a degree of vacuum in the vacuum chamber space 2a is less than 1.0×10⁻³ Pa, the mean free path of the vapor deposition particles 301 is shortened, and the vapor deposition particles 301 are scattered. This may cause decreased efficiency for the vapor deposition particles 301 to reach the target film forming substrate 200 and decreased collimation components. As a result, blurring of the film forming pattern may occur.

Consequently, in the present embodiment, the degree of vacuum in the vacuum chamber space 2a is set to 1.0×10⁻³ Pa or greater (in other words, pressure in the vacuum chamber space 2a being 1.0×10⁻³ Pa or less).

### Vapor Deposition Source 10

The vapor deposition source 10 ejects (discharges) the vapor deposition material such as organic luminescent materials as the vapor deposition particles 301 by heating the vapor deposition material, that is a film forming material, to vaporize or sublimate the vapor deposition material under vacuum.

As described above, the vapor deposition source 10 according to the present embodiment includes the vapor deposition particles generation unit 11, the pipe 12, and the vapor deposition source main body 13.

The vapor deposition particles generation unit 11 is a vapor deposition particles generation section (vapor deposition particles generation source) configured to heat the vapor deposition material to generate the vapor deposition particles 301.

The vapor deposition particles generation unit 11 includes a heating vessel, referred to as a melting pot or a boat, configured to contain the vapor deposition material therein, and a heating device (heater) surrounding the heating vessel and configured to heat the vapor deposition material in the heating vessel by adjusting and controlling temperature of the heating vessel.

The vapor deposition particles generation unit 11 is configured to heat the vapor deposition material in the heating vessel using the heating device to vaporize (in a case that the vapor deposition material is a liquid material) or sublimate (in a case that the vapor deposition material is a solid material) the vapor deposition material. As a result, the vapor deposition material is gasified, and the gaseous vapor deposition particles 301 (vapor deposition particles gas) are generated. Consequently, as described above, disposing the vapor deposition particles generation unit 11 outside of the vacuum chamber 2 allows the heating vessel to be refilled with the vapor deposition material or the vapor deposition material to be replaced with other vapor deposition materials with ease.

The pipe 12 is a load-lock type pipe connecting the vapor deposition particles generation unit 11 and the vapor deposition source main body 13.

The vapor deposition source main body 13 includes a vapor deposition particles diffusion unit 20 and a vapor deposition particles ejecting unit 30.

The vapor deposition particles diffusion unit 20 is a vapor deposition particles diffusion section including a diffusion space for diffusing the vapor deposition particles 301 supplied to the vapor deposition particles ejecting unit 30. With the configuration, the vapor deposition particles 301 can be uniformly ejected from a vapor deposition nozzle 52 facing outside of the vapor deposition source 10 in the vapor deposition particles ejecting unit 30.

The vapor deposition particles diffusion unit 20 includes a hollow vapor deposition particles diffusion vessel including a vapor deposition particles diffusion room 21 therein as a vapor deposition particles diffusion space for diffusing the vapor deposition particles 301 introduced from the vapor deposition particles generation unit 11.

The vapor deposition particles diffusion room 21 preferably has a sufficiently large space for each vapor deposition nozzles 32 and 52 in the vapor deposition particles ejecting unit 30. With the configuration, the vapor deposition particles 301 can be ejected nearly uniformly from every vapor deposition nozzle 52. The vapor deposition nozzles 32 and 52 will be described later.

A vapor deposition particles inlet 22 configured to allow the vapor deposition particles 301 to be introduced into the inside (that is, the inside of the vapor deposition particles diffusion room 21) is formed at the vapor deposition particles diffusion unit 20. The pipe 12 is connected to the vapor deposition particles inlet 22. With the configuration, the vapor deposition material is provided (carried) to the vapor deposition particles diffusion unit 20 from the vapor deposition particles generation unit 11 through the pipe 12.

The number and the position of the vapor deposition particles inlets 22 are not limited to a specific number and position as long as the vapor deposition particles 301 can be uniformly diffused; however, for example, the vapor deposition particles inlets 22 are preferably disposed at both of the ends (that is, both end surfaces 23 in the X axis direction) of the vapor deposition particles diffusion unit 20 in the X axis direction.

The vapor deposition particles diffusion unit 20 has, for example, a drum shape (cylindrical shape, that is, a hollow column shape).

The vapor deposition particles diffusion unit 20 is connected to the vapor deposition particles ejecting unit 30 at a part of a peripheral surface 24 (that is, a cylindrical surface parallel to a cylinder axis 25 illustrated in FIG. 1 as the dot-dash line). With the configuration, the vapor deposition particles diffusion unit 20 and the vapor deposition particles ejecting unit 30 are integrated with each other.

Delivery ports 26 (openings of the vapor deposition particles diffusion unit) configured to allow the vapor deposition particles 301 to be delivered to the vapor deposition particles ejecting unit 30 are formed at a connecting section connecting the vapor deposition particles ejecting unit 30 and the vapor deposition particles diffusion unit 20 at the peripheral surface 24.

On the other hand, the vapor deposition particles ejecting unit 30 includes a plurality of stages of nozzle sections (vapor deposition nozzle section) and a hollow portion formed between the stages of the nozzle sections and connected to the hollow portion 2a in the vacuum chamber 2 (hereinafter, referred to as “a vacuum chamber space”) not via the respective nozzle section.

The vapor deposition particles ejecting unit 30 illustrated in FIG. 1 to FIG. 3 includes a first nozzle unit 31 (first vapor deposition nozzle section) and a second nozzle unit 51 (second vapor deposition nozzle section) as nozzle sections. Furthermore, the vapor deposition particles ejecting unit 30 includes a pressure adjusting unit 41 forming a hollow portion 43 as the hollow portion between the first nozzle unit 31 and the second nozzle unit 51.

The first nozzle unit 31, the pressure adjusting unit 41, and the second nozzle unit 51 are separate block shaped units, and are stacked in this order from the vapor deposition particles diffusion unit 20 side and integrated with each other.

The first nozzle unit 31 and the second nozzle unit 51 are plate shaped members of which main surfaces are an XY plane, and, for example, have a rectangular shape with a major axis in the X axis direction in plan view.

The plurality of vapor deposition nozzles 32 (nozzle openings, a first vapor deposition nozzle; hereinafter sometimes referred to as “a first-stage nozzles”), which are nozzle-shaped openings penetrating in the up-down direction, are arranged in the X axis direction in the first nozzle unit 31 with a constant pitch.

Each of the vapor deposition nozzles 32 has a rectangular shape with the major axis in the Y axis direction in plan view. Thus, each of the vapor deposition nozzles 32 is formed in a rectangular shape with a first side 32a parallel to the Y axis direction as the long side, a second side 32b parallel to the X axis direction as the short side in plan view.

The vapor deposition nozzles 32 are disposed such that the long sides thereof are parallel to the Y axis and face each other in plan view. Consequently, a plurality of regulation plates 33 (non-opening) forming nozzle walls of the vapor deposition nozzles 32 as shields are aligned along the X axis direction with a constant pitch and between the vapor deposition nozzles 32 adjacent to each other in the X axis direction.

Furthermore, the plurality of vapor deposition nozzles 52 (nozzle openings, a second vapor deposition nozzle; hereinafter sometimes referred to as “a second-stage nozzle”), which are nozzle-shaped openings penetrating in the up-down direction, are arranged along the X axis direction in the second nozzle unit 51 with a constant pitch.

Each of the vapor deposition nozzles 52, similar to the vapor deposition nozzle 32, has a rectangular shape with the major axis in the Y axis direction in plan view. Thus, each of the vapor deposition nozzles 52 is formed in a rectangular shape with a first side 52a parallel to the Y axis direction as the long side, and a second side 52b parallel to the X axis direction as the short side in plan view.

The vapor deposition nozzles 52 are disposed such that the long sides thereof are parallel to the Y axis and face each other in plan view. Consequently, a plurality of regulation plates 53 (non-opening) forming nozzle walls of the vapor deposition nozzles 52 as shields are aligned in the X axis direction with a constant pitch and between the vapor deposition nozzles 52 adjacent to each other in the X axis direction.

Each of the vapor deposition nozzles 32 is formed such that the length of the first side 32a (an opening width d1 in the Y axis direction) parallel to the Y axis direction is longer than the length of the third side 32c (depth, a nozzle length d3) parallel to the Z axis direction of each of the vapor deposition nozzles 32.

Furthermore, each of vapor deposition nozzles 52 is formed such that, in plan view, the length of the first side 52a (opening width d11 in the Y axis direction) parallel to the Y axis direction is longer than the length of the third side 52c (depth, nozzle length d13) parallel to the Z axis direction of each of the vapor deposition nozzles 52.

Here, the Y axis direction indicates a scan direction of the target film forming substrate 200, in other words, a carrying direction of the target film forming substrate 200. Furthermore, the Z axis direction indicates the ejecting direction of the vapor deposition particles 301 in the vapor deposition particles ejecting unit 30.

As described above, in a case that film forming is performed while the target film forming substrate 200 is carried, the passing time at which the target film forming substrate 200 passes over the opening area (that is, over the vapor deposition nozzles 32 and 52) in the vapor deposition particles ejecting unit 30 is preferably required to be short as much as possible to speed up a takt time. However, the film forming rate (vapor deposition rate, film forming speed) of the vapor deposition source 10 has an upper limit. Consequently, in a case of carrying the target film forming substrate 200 at a constant speed for the film forming, a long opening width of the vapor deposition nozzles 32 and 52 (the opening widths d1 and d11 in the Y axis direction) of the target film forming substrate 200 in the carrying direction allows the thicker vapor deposition film 302 to be formed. Consequently, the vapor deposition nozzles 32 and 52 are formed such that the d1 and the dll, which are the opening widths in the Y axis direction of the vapor deposition nozzles 32 and 52, respectively, are longer than the d3 and the d13, which are the nozzle lengths in the Z axis direction of the vapor deposition nozzles 32 and 52, respectively. This allows the takt time to be speeded up.

The delivery port 26 of the vapor deposition particles diffusion unit 20 is connected to the vapor deposition nozzle 32 of the first nozzle unit 31 located in the lowest stage of the vapor deposition particles ejecting unit 30. The delivery port 26, for example, is identical with the vapor deposition nozzle 32 in shape in plan view, and is connected to the vapor deposition nozzle 32 with an opening end of the delivery port 26 connected to the opening end of the vapor deposition nozzle 32 each other.

Furthermore, the vapor deposition particles diffusion unit 20 is formed to be connected to the vapor deposition particles ejecting unit 30 without forming any space between the vapor deposition particles diffusion unit 20 and the vapor deposition particles ejecting unit 30.

With the configuration, the vapor deposition particles 301 diffused in the vapor deposition particles diffusion unit 20 are supplied to the vapor deposition particles ejecting unit 30 through the delivery port 26.

On the other hand, the vapor deposition nozzle 52 of the second nozzle unit 51 located at the highest stage of the vapor deposition particles ejecting unit 30 is used as an ejection port for ejecting the vapor deposition particles 301 outside of the vapor deposition source 10.

The delivery port 26, the vapor deposition nozzle 32, and the vapor deposition nozzle 52 have the identical shape in plan view, and are disposed while superimposed with each other such that central axes (opening center) thereof match. FIG. 2 illustrates that the vapor deposition nozzle 32 and the vapor deposition nozzle 52 are fully overlapped in plan view.

Furthermore, the pressure adjusting unit 41 is a frame-shaped block member, and includes a space forming opening section 42 forming the hollow portion 43 connecting the vapor deposition nozzle 32 and the vapor deposition nozzle 52.

An opening 45 as an exhaust port (ventilation port) is formed in a part of a side wall 44, which is an outer wall of the pressure adjusting unit 41. With the configuration, part of the pressure adjusting unit 41 is opened facing the outside of the vapor deposition source 10 (that is, the vacuum chamber space 2a). Consequently, the hollow portion 43 in the pressure adjusting unit 41 is partially connected to the vacuum chamber space 2a via the opening 45, which is a connecting port to the vacuum chamber space 2a,so as to form a close space partially opened to the vacuum chamber space 2a.

That is, the hollow portion 43 has a structure including the first nozzle unit 31 and the second nozzle unit 51 as the bottom wall and the top wall respectively, and including the four quarters surrounded by the side walls 44 of the pressure adjusting unit 41. In addition, the hollow portion 43 connects to the outside of the vapor deposition source 10, that is the vacuum chamber space 2a,only through the vapor deposition nozzle 52 and the opening 45. Consequently, the opening 45 functions as a pressure adjusting section configured to relieve pressure in the closed hollow portion 43.

The opening 45 is preferably formed to keep inner pressure in the hollow portion 43 to be constant. Consequently, at least one opening 45 or preferably at least one set of openings 45 may be formed. Further preferably, the openings 45 are formed in the side walls 44 (the side wall surface of the short side), which are both ends of the pressure adjusting unit 41 in the X axis direction, at positions facing each other by interposing the center point of the pressure adjusting unit 41 (that is, the center point of the hollow portion 43).

The opening 45 may be formed in a part of the side wall 44 of the pressure adjusting unit 41; however, a too large opening 45 reduces the number of the vapor deposition particles 301 discharged from the vapor deposition nozzle 52. Consequently, the total opening area of the openings 45, in other words, the sum of the opening areas of the openings 45 is preferably sufficiently small compared with the opening area of each of the vapor deposition nozzles 52, and is preferably 1/10 or less the opening area of each of the vapor deposition nozzles 52 (in other words, the opening area of a single vapor deposition nozzle). The vapor deposition nozzle 52 is formed in the second nozzle unit 51, which is the highest stage, and is also the nozzle unit in the succeeding stage of the hollow portion 43 (upper stage, that is, on the downstream side in the ejecting direction of the vapor deposition particles of two nozzle units interposing the hollow portion 43).

The opening 45 may be formed to directly face the vacuum chamber 2 for direct connection to the vacuum chamber space 2a,or may connect to the vacuum chamber space 2a via a pressure adjusting device such as a pressure adjusting valve 46 as illustrated in FIG. 1 and FIG. 3. The pressure adjusting valve 46 is configured to adjust pressure in the hollow portion 43 by adjusting the degree of opening (opening area) of the opening 45.

Examples of the pressure adjusting valve 46 include needle valves; however, are not specifically limited to a specific valve as long as valves can adjust pressure in the hollow portion 43 by adjusting the degree of opening of the opening 45. Note that the pressure adjusting valve 46 is preferably a solenoid valve for keeping the inside of the vacuum chamber 2 under a reduced pressure atmosphere (vacuum state).

Each of the openings 45 preferably has the same mechanism to keep inner pressure in the hollow portion 43 to be at a constant pressure. Thus, as described above, in a case of attaching the pressure adjusting valve 46 to the opening 45, the pressure adjusting valve 46 is preferably disposed in each opening 45, and the same pressure adjusting valves 46 are preferably each disposed in the opening 45.

Attaching the pressure adjusting valve 46 in the opening 45 makes it possible to adjust the film forming rate and prevent excess emission (discharge) of the vapor deposition particles 301 from the opening 45.

In the case that the pressure adjusting valve 46 is disposed in the opening 45, the film forming rate is confirmed in advance while the pressure adjusting valve 46 is closed, and thereafter the film forming rate is adjusted so as not to decrease too much while the pressure adjusting valve 46 is opened, and the film thickness distribution is confirmed. Note that, a decrease in the film forming rate is preferably suppressed within 30%.

The vapor deposition particles 301 are discharged from the opening 45 to some extent because the opening 45 is formed in the pressure adjusting unit 41 in the vapor deposition device 100. Consequently, a vapor deposition particles retrieving member 14 configured to retrieve the vapor deposition particles 301 discharged from the opening 45 is preferably disposed between the opening 45 and the vacuum chamber 2 via the vacuum chamber space 2a.

In a case that the pressure adjusting valve 46 is not disposed in the opening 45, the vapor deposition particles retrieving member 14 is disposed facing the opening 45 and is spaced from the opening 45. In this case, the vapor deposition particles retrieving member 14 is preferably disposed close to the opening 45 and facing the opening 45.

In a case that the pressure adjusting valve 46 is disposed in the opening 45, the vapor deposition particles retrieving member 14 is disposed facing an opening end 46b and is spaced from the opening end 46b . The opening end 46b is an end facing an opening end 46a located near a connecting portion to the opening 45 in the pressure adjusting valve 46. In this case, the vapor deposition particles retrieving member 14 is preferably disposed facing the opening end 46b.

Examples of the vapor deposition particles retrieving member 14 include, for example, cold traps such as cooling plates.

The vapor deposition particles 301 discharged from the opening 45 or the pressure adjusting valve 46 to the outside of the vapor deposition source 10 are sprayed to the vapor deposition particles retrieving member 14. As a result, the temperature of the vapor deposition particles 301 becomes below the temperature at which the vapor deposition particles 301 gasify and the vapor deposition particles 301 are retrieved by the vapor deposition particles retrieving member 14.

In a case that the vapor deposition particles retrieving member 14 is, for example, a cooling plate, the vapor deposition particles 301 sprayed to the vapor deposition particles retrieving member 14 adheres to the cooling plate as the solid vapor deposition material, and are retrieved. The vapor deposition material adhering to the cooling plate is mechanically scraped off for reuse.

On the other hand, while the vapor deposition source 10 ejects the vapor deposition particles 301 gasified in the vapor deposition particles generation unit 11 outside as in the gaseous form, the vapor deposition source 10 is preferably heated to a temperature higher than or equal to the temperature at which the vapor deposition material gasifies (sublimation temperature or vaporization temperature) to prevent adhesion and clogging of the vapor deposition material in the path of the vapor deposition source 10. Thus, the whole vapor deposition source 10 is preferably heated to a temperature 50° C. or higher than the temperature at which the vapor deposition material gasifies.

Consequently, in the vapor deposition source 10, not only the vapor deposition particles generation unit 11 but also the pipe 12 and the vapor deposition source main body 13 are preferably heated to a temperature higher than or equal to the temperature at which the vapor deposition material gasifies (for example, a temperature of the heating vessel in the vapor deposition particles generation unit 11, referred to as the melting pot or the boat, or higher).

Thus, the pipe 12 and the vapor deposition source main body 13 are provided with heating members (heaters), such as induction coils (not illustrated), to adjust and control the temperature of the pipe 12 and each element of the vapor deposition source main body 13; specifically the pipe 12, the vapor deposition particles diffusion unit 20, and the first nozzle unit 31, the pressure adjusting unit 41, and the second nozzle unit 51 in the vapor deposition particles ejecting unit 30.

The heating member may be disposed around or in the pipe 12, the vapor deposition particles diffusion unit 20, the first nozzle unit 31, the pressure adjusting unit 41, and the second nozzle unit 51. In the former case, for example, the heating member may be wound around the pipe 12, the vapor deposition particles diffusion unit 20, the first nozzle unit 31, the pressure adjusting unit 41, and the second nozzle unit 51. In the latter case, for example, the heating member may be embedded in the hollowed walls or the like of the pipe 12, the vapor deposition particles diffusion unit 20, the first nozzle unit 31, the pressure adjusting unit 41, and the second nozzle unit 51.

The temperature of the heating vessel (for example, the melting pot) in the vapor deposition particles generation unit 11 is preferably the temperature, for example, in the range of from 200 to 400° C. at which the vapor deposition material can gasify, and in the case that the vapor deposition material is, for example, aluminum quinolinol complex (Alq₃), the temperature preferably ranges from 250° C. to 270° C.

Furthermore, the temperatures of the pipe 12, the vapor deposition particles diffusion unit 20, the first nozzle unit 31, the pressure adjusting unit 41, and the second nozzle unit 51, specifically the temperatures of the pipe 12, the vapor deposition particles diffusion room 21, each of the vapor deposition nozzles 32 and 52, and the hollow portion 43 are all preferably increased a temperature (for example, 400° C.) sufficiently higher than the temperature at which the vapor deposition material gasifies, for preventing adhesion of the vapor deposition material.

The vapor deposition particles 301, supplied from the vapor deposition particles diffusion unit 20 to the vapor deposition particles ejecting unit 30, except for the vapor deposition particles 301 discharged outside from the opening 45, are ejected from the vapor deposition source 10 passing through the vapor deposition nozzle 32, the hollow portion 43, and the vapor deposition nozzle 52.

In the vapor deposition particles ejecting unit 30, the physical nozzle lengths d3 and d13 of each of the vapor deposition nozzles 32 and 52 in the direction of the normal line (that is, the Z axis direction) of the first nozzle unit 31 and the second nozzle unit 51 allow linearity of the vapor deposition particles 301 to be improved.

In this case, in the vapor deposition source 10, the hollow portion 43 is formed between the vapor deposition nozzle 32 and the vapor deposition nozzle 52, and the opening 45 is formed as a connecting port connecting the hollow portion 43 and the vacuum chamber space 2a,that is vacuum space. This allows pressure in the hollow portion 43 to naturally reduce.

As a result, the pressure in the hollow portion 43 is lower than the pressure in the vapor deposition particles generation unit 11, the pipe 12, the vapor deposition particles diffusion unit 20, and the first nozzle unit 31, but higher than the pressure in the vacuum chamber space 2a.

Thus, according to the present embodiment, a physical phenomenon led by the physical structure of the vapor deposition particles ejecting unit 30 results in pressure in the vapor deposition nozzle 32>pressure in the hollow portion 43>pressure in the vapor deposition nozzle 52>pressure in the vacuum chamber space 2a.

Consequently, with the vapor deposition source 10, pressure difference between the vacuum chamber space 2a and the vapor deposition nozzle 52, which is the outlet (ejection ports) for the vapor deposition particles 301 to the outside (in other words, pressure difference between before and after ejection of the vapor deposition particles 301), can be reduced at the final stage at which the vapor deposition particles 301 are ejected from the vapor deposition particles ejecting unit 30, so as to prevent the vapor deposition particles 301 from scattering at the outlet. As a result, the vapor deposition particles 301 can be efficiently ejected in the desired ejecting direction.

Note that, the pressure in the hollow portion 43 can be changed by changing the temperature of the hollow portion 43. However, pressure control range is small only with the temperature change of the hollow portion 43.

As described above, in the present embodiment, the opening 45 connecting the hollow portion 43 and the vacuum chamber space 2a is formed to let the pressure in the hollow portion 43 directly escape from the opening 45. Consequently, according to the present embodiment, forming the opening 45 enables the space pressure to directly and dynamically change.

Note that, in the present embodiment, as described above, the vapor deposition source 10 is heated and controlled in order to keep the temperature of the vapor deposition nozzle 32, the hollow portion 43, and the vapor deposition nozzle 52 to be at a constant temperature (that is, the same temperature).

Note that, the pressure in the vapor deposition particles diffusion unit 20 is preferably a few Pa, and the pressure in the hollow portion 43 preferably ranges from 1×10⁻⁻¹ Pa to 1×10⁻³ Pa, and the pressure in the vacuum chamber space 2a is preferably 1×10⁻³ Pa or less (here, the pressure in the hollow portion 43 >the pressure in the vacuum chamber space 2a).

Furthermore, larger pressure difference between the outlet and the inlet of each of the vapor deposition nozzles 32 and 52 tends to increase scattering of the vapor deposition particles 301. Consequently, the pressure difference between the outlet and the inlet of the vapor deposition nozzle 32 preferably ranges from 10 to 1000 times, and the pressure difference between the outlet and the inlet of the vapor deposition nozzle 52 preferably ranges from 10 to 100 times.

### Substrate Carrying Device 3

The substrate carrying device 3 holds the target film forming substrate 200, includes a motor (not illustrated), and drives the motor on the basis of signals from the motor drive controller in a controller (not illustrated) to carry the target film forming substrate 200.

In the present embodiment, as illustrated in FIG. 3, the substrate carrying device 3 carries (inline carry) the target film forming substrate 200 in the Y axis direction over the vapor deposition mask 80, and the vapor deposition material is evaporated, while the target film forming substrate 200 is held with the target deposition surface 201 facing a mask surface of the vapor deposition mask 80.

Examples of the substrate carrying device 3 are not specifically limited to a specific device, and, for example, include known various moving devices such as roller type moving devices and oil hydraulic moving devices.

### Vapor Deposition Mask 80

The vapor deposition mask 80 is a plate-shaped member with the mask surface, that is the main surface, parallel to the XY plane. In the present embodiment, as illustrated in FIG. 3, the scan vapor deposition is performed with the Y axis direction as the scan direction. Consequently, the vapor deposition mask 80 which is at least smaller than the target film forming substrate 200 in size in the Y axis direction is used.

A plurality of mask openings 81 (openings) are formed in the vapor deposition mask 80 at the main surface. The mask opening 81 is a through hole functioning as a path, which causes the vapor deposition particles 301 (vapor deposition material) to pass during the vapor deposition. On the other hand, the area of the vapor deposition mask 80 other than the mask openings 81 is a non-opening 82, and functions as a shutoff portion configured to shut off the flow of the vapor deposition particles 301 during the vapor deposition.

Each of the mask openings 81 is formed corresponding to a part of a pattern of each of the vapor deposition films 302 to be formed on the target film forming substrate 200. In a case that the separate forming of the light-emitting layers for each color of the organic EL element as described above is performed as pattern film forming for the vapor deposition film 302, the mask opening 81 is formed in accordance with a size and a pitch of each light-emitting layer in the X axis direction.

Note that, FIG. 3 illustrates an example in which a plurality of slot shaped mask openings 81 are disposed two-dimensionally. However, the present embodiment is not limited to the above, and a large number of the mask openings 81 may be formed in the vapor deposition mask 80 in accordance with a predetermined vapor deposition film pattern, and, for example, a plurality of slit-shaped mask openings 81 extending in the Y axis direction may be arranged in the X axis direction.

By using the vapor deposition mask 80, only the vapor deposition particles 301 passing through the mask opening 81 reach the target film forming substrate 200 to form the vapor deposition film 302 having a pattern corresponding to the mask opening 81 on the target film forming substrate 200. In the present embodiment, the vapor deposition is performed by scanning the target film forming substrate 200 in the Y axis direction using the vapor deposition mask 80 to form the stripe-shaped vapor deposition film 302 on the target film forming substrate 200.

Note that, in a case that the vapor deposition material is a material for the light-emitting layer of the organic EL display, the vapor deposition for the light-emitting layers in organic EL vapor deposition process is performed separately for each light-emitting layer.

The area not for adhesion of the vapor deposition particles in the target film forming substrate 200 is covered with the shutter 60 and the adhesion prevention plate and the like (not illustrated).

Examples of the vapor deposition mask 80 are preferably metallic masks; however, the examples thereof are not limited to this, and may include resinous or ceramic masks, and compound masks using these materials.

Furthermore, the vapor deposition mask 80 may be used as it is, or may be fixed to a mask frame (not illustrated) under tension to suppress deformation caused by self-weight. In plan view, the mask frame is formed in a rectangular shape with a size identical to or larger than that of the vapor deposition mask 80. Note that, the plan view illustrates a view from the direction perpendicular to the main surface of the vapor deposition mask 80 (that is, the direction parallel to the Z axis).

### Restriction Plate Unit 70

While the vapor deposition particles ejecting unit 30 is disposed integrally with the vapor deposition particles generation unit 11, which is the vapor deposition particles generation source, in the vapor deposition source 10, and used for ejecting the vapor deposition particles 301 in the predetermined direction, the restriction plate unit 70 is spaced from the vapor deposition source 10, and used for controlling the flow of the vapor deposition particles 301 after discharged from the vapor deposition particles generation unit 11 and changing the scattering direction of the vapor deposition particles 301. Consequently, the restriction plate unit 70 does not have any specific pressure conditions.

The restriction plate units 70, in plan view, are extended parallel to the Y axis, spaced from each other in the X axis direction, and include a plurality of restriction plates 72 aligned parallel to each other with a constant pitch. The plurality of restriction plates 72 each is an identical-sized plate member.

Furthermore, in plan view, the restriction plate opening 71 (through hole) penetrating in the up-down direction is formed between the restriction plates 72 adjacent each other in the X axis direction.

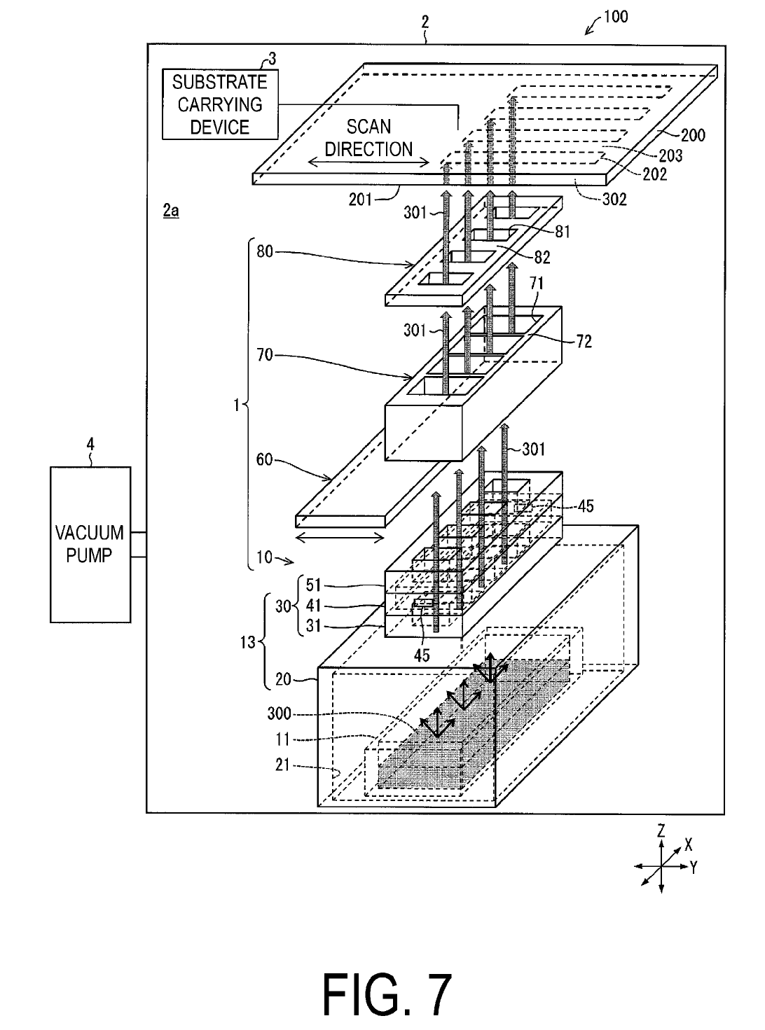

A method for holding each restriction plate 72 is not limited a specific method as long as the relative position and attitude of each restriction plate 72 can be maintained in a constant manner. A structure is possible in which the restriction plate unit 70 includes a holding member (not illustrated) connecting and holding the restriction plates 72, and each restriction plate 72 is fixed to the holding member by screwing, welding or the like. Furthermore, as illustrated in FIG. 7 described later, the restriction plate unit 70 may be a rectangular-shaped single plate, in plan view, with the XY plane as the main surface, and may have a plurality of restriction plate openings 71 formed along the X axis direction with a constant pitch. Consequently, the restriction plate 72 disposed between adjacent restriction plate openings 71 may be a block-shaped unit aligned in the X axis direction with a constant pitch.

Although illustration of the holding member is omitted in FIG. 3, the restriction plate unit 70 has an outer shape, in plan view, having a size identical to or larger than that of the outer shape of the vapor deposition mask 80.

The aligned pitch of the restriction plate openings 71 is identical to the aligned pitch of the vapor deposition nozzles 52 in the vapor deposition source 10, and thus, the restriction plate openings 71 and the vapor deposition nozzles 52 are arranged in a one-to-one relationship.

On the other hand, the aligned pitch of the restriction plate opening 71 is formed larger than the aligned pitch of the mask opening 81, and thus, the plurality of mask openings 81 are disposed between adjacent restriction plates 72 in the X axis direction in plan view.

The restriction plate unit 70 includes each restriction plate 72 to partition the space between the vapor deposition mask 80 and the vapor deposition source 10 into a plurality of vapor deposition spaces formed from, the restriction plate openings 71. As a result, the passing angle of the vapor deposition particles 301 ejected from the vapor deposition source 10 is restricted.

The vapor deposition particles 301 ejected from the vapor deposition nozzle 52 reach the target film forming substrate 200 after passing the restriction plate opening 71 and the mask opening 81.

The vapor deposition particles 301 ejected from the vapor deposition nozzle 52 pass the restriction plate opening 71, and thus the incident angle of the vapor deposition particles 301 into the target film forming substrate 200 is limited at a constant angle or less.

In a case of the scan vapor deposition by using the restriction plate unit 70, the vapor deposition particles 301 having an ejection angle larger than the divergence angle of the vapor deposition particles 301 restricted by the restriction plate 72 are blocked (captured) by the restriction plate 72.

Consequently, the smaller divergence angle of the vapor deposition particles 301 ejected into the restriction plate unit 70 increases the amount of the vapor deposition flow passing the restriction plate opening 71 so as to improve the material utilization efficiency.

In the vapor deposition source 10 according to the present embodiment, the plurality of stages of nozzle units including vapor deposition nozzles such as the vapor deposition nozzles 32 and 52 (for example, the first nozzle unit 31 and the second nozzle unit 51) are disposed.

Consequently, directivity of the vapor deposition flow is high, and thus the percentage of the vapor deposition particles 301 passing through the restriction plate opening 71 increases in comparison with that of devices of the related art. Consequently, the material utilization efficiency of the vapor deposition material is improved in comparison with that of devices of the related art.

Furthermore, because the vapor deposition film 302 is formed on the target film forming substrate 200 by only the vapor deposition particles 301 passing through the restriction plate opening 71, the film thickness distribution of the deposition pattern formed on the target film forming substrate 200 can be improved. Consequently, the vapor deposition film 302 can be formed on the target film forming substrate 200 with high precision.

In the present embodiment, the vapor deposition nozzles 32 and 52 and the restriction plate opening 71 are formed while superimposed with each other with each central axis (opening center) lined each other in plan view. Consequently, the spread of the vapor deposition flow can be suppressed with higher precision.

However, as illustrated in FIG. 3, in the present embodiment, the opening sizes of the vapor deposition nozzles 32 and 52 and the restriction plate opening 71 in plan view are different from each other.

Note that, the size of the restriction plate opening 71 is not specifically limited to a specific size and can be properly set in accordance with the size of the target film forming substrate 200 and the deposition pattern to be formed.

The restriction plate unit 70 is kept at an ambient temperature without heating to shield slant components of the vapor deposition particles 301, or is preferably cooled by a cooling mechanism (heat exchanger) (not illustrated). Consequently, the temperature of the restriction plate 72 is lower than the temperature of the vapor deposition nozzles 32 and 52. In this way, disposing the cooling mechanism configured to cool the restriction plate 72 enables unnecessary vapor deposition particles 301, which come in contact with the restriction plate 72 and are ejected not parallel to the Z axis, to be solidified and captured. Consequently, the moving direction of the vapor deposition particles 301 can be even closer to the direction of the normal line of the target film forming substrate 200.

Note that, the cooling mechanism is not specifically limited to a specific mechanism; however, the cooling mechanism is preferably water-cooled cooling mechanisms configured to circulate cooling water for cooling. That is, the restriction plate unit 70 (the restriction plate 72) is preferably a water-cooled restriction plate unit (water-cooled restriction plate 72).

### Shutter 60

Furthermore, to control the vapor deposition particles 301 ejected from the vapor deposition source 10 reaching the vapor deposition mask 80, the shutter 60 is disposed between the vapor deposition mask 80 and the vapor deposition source 10, in the present embodiment, between the restriction plate unit 70 and the vapor deposition source 10 so that the vapor deposition particles 301 pass toward the target film forming substrate 200 or are blocked.

The shutter 60 blocks off the path for ejecting the vapor deposition particles 301 to prevent the vapor deposition particles 301 from reaching the target film forming substrate 200 in a case that the vapor deposition rate is to be stabilized or the vapor deposition is unnecessary.

The shutter 60 is disposed between, for example, the vapor deposition mask 80 and the vapor deposition source 10 and can be advanced and retreated therebetween by a shutter actuator (not illustrated).

The shutter actuator holds the shutter 60 and actuates the shutter 60 on the basis of a vapor deposition OFF signal/a vapor deposition ON signal from a controller (not illustrated).

Activating the shutter actuator and properly interposing the shutter 60 between the restriction plate unit 70 and the vapor deposition source 10, as illustrated in FIG. 3, make it possible to prevent the vapor deposition to an unnecessary area (non-target deposition area 203) in the target film forming substrate 200.

### Method for Manufacturing Vapor Deposition Film

In the next, a manufacturing method (deposition method) for the vapor deposition film 302 will be described as a vapor deposition method using the vapor deposition source 10.

In the present embodiment, the scan deposition scheme in which film forming is performed by scanning the target film forming substrate 200 is used as a film forming scheme, and the vapor deposition source 10 and the target film forming substrate 200 are relatively moved with the Y axis direction as the scan direction so as to perform the scan vapor deposition.

More specifically, a substrate carrier film forming scheme in which film forming is performed by carrying the target film forming substrate 200 is used for the film forming in the present embodiment. That is, in the present embodiment, the vapor deposition device 100, as described above, includes the shutter 60, the restriction plate unit 70, and the vapor deposition mask 80 between the vapor deposition source 10 and the target film forming substrate 200, and the vapor deposition mask 80, the restriction plate unit 70, and the vapor deposition source 10 are each fixed to somewhere in the inner wall of the vacuum chamber 2. With the structure, the vapor deposition device 100 moves the target film forming substrate 200 relative to the vapor deposition mask 80, the restriction plate unit 70, and the vapor deposition source 10 by using the substrate carrying device 3, and thus performs the vapor deposition (scan vapor deposition) while scanning the target film forming substrate 200. In this case, the shutter 60 is interposed between the restriction plate unit 70 and the vapor deposition source 10. This prevents an unnecessary area (the non-target deposition area 203) in the target film forming substrate 200 from experiencing the vapor deposition.

Consequently, in the present embodiment, first, the vapor deposition source 10, the shutter 60, the restriction plate unit 70, the vapor deposition mask 80, and the target film forming substrate 200 face each other and are spaced at a constant distance.

In this case, relative positional alignment between the vapor deposition mask 80 and the target film forming substrate 200, that is, the alignment adjustment and gap control between the vapor deposition mask 80 and the target film forming substrate 200 are performed by using an alignment marker (not illustrated) disposed on both the vapor deposition mask 80 and the target film forming substrate 200.

Furthermore, by using the alignment marker (not illustrated) disposed on the vapor deposition mask 80, the restriction plate unit 70, and the vapor deposition source 10, the vapor deposition mask 80 and the restriction plate unit 70 face each other, and the relative positional alignment between the target film forming substrate 200 and the vapor deposition unit 1 is performed (a positional alignment step) to match the central axis (opening center) of the vapor deposition nozzle 52 in the vapor deposition source 10 and the central axis (opening center) of the restriction plate opening 71 in the restriction plate unit 70.

Subsequently, the vapor deposition particles 301 are ejected from the vapor deposition source 10 under the reduced pressure atmosphere (vacuum state) (a step of ejecting the vapor deposition particles). Here, in a case that the pressure adjusting valve 46 is disposed in the opening 45, in the step of ejecting the vapor deposition particles, the vapor deposition particles 301 are ejected from the vapor deposition source 10 with the pressure adjusting valve 46 closed to confirm the film forming rate (a step of confirming a film forming rate). Subsequently, the pressure adjusting valve 46 is opened to decrease pressure in the hollow portion 43 lower than pressure in the vapor deposition nozzle 32 in the first nozzle unit 31, which is the nozzle unit upstream of the nozzle units interposing the hollow portion 43 in an ejecting direction of the vapor deposition particles. Subsequently, while the vapor deposition film 302 formed on the target film forming substrate 200 is checked for the film thickness distribution (for example, the film thickness distribution of the vapor deposition film 302 formed on the non-target film forming area 203 in the target film forming substrate 200), the vapor deposition particles 301 are ejected from the vapor deposition source 10 to adjust the film forming rate (a step of adjusting a film forming rate adjusting step).

Then, in plan view, the target film forming substrate 200 is moved in the scan direction (that is, the Y axis direction perpendicular to the arrangement direction of the vapor deposition nozzle 52 and the restriction plate opening 71) to cover the target film forming area 202 of the target film forming substrate 200 with the vapor deposition particles 301 while the target film forming substrate 200 is relatively moved to the vapor deposition unit 1 (a step of covering a target film forming area).

Here, in the present embodiment, the vapor deposition particles 301 (a vapor deposition flow) pass through the vapor deposition nozzle 32 toward the hollow portion 43 with pressure in the hollow portion 43 released by using the opening 45, and are finally ejected toward the target film forming substrate 200 from the vapor deposition nozzle 52 in the step of covering a target film forming area.

Consequently, in the present embodiment, in the step of covering a target film forming area, the pressure in the hollow portion 43 between the vapor deposition nozzle 32 and the vapor deposition nozzle 52 in the vapor deposition particles ejecting unit 30 is lower than the pressure in the vapor deposition nozzle 32 upstream of the vapor deposition nozzles interposing the hollow portion 43 in the ejecting direction of the vapor deposition particles, and is higher than the pressure in the vapor deposition nozzle 52 downstream of the vapor deposition nozzles interposing hollow portion 43 in the ejecting direction of the vapor deposition particles. Consequently, the pressure in the vapor deposition particles ejecting unit 30 has a following relation: pressure in the vapor deposition nozzle 32 >pressure in the hollow portion 43 >pressure in the vapor deposition nozzle 52 >pressure in the vacuum chamber space 2a, which gradually decreases from the vapor deposition nozzle 32 side.

Thus, according to the present embodiment, the pressure in the vapor deposition particles ejecting unit 30 can be gradually brought close to the pressure in the vacuum chamber space 2a. As a result, pressure difference between an area around the vapor deposition source 10 of the vapor deposition particles 301 and area near the outlet, that is, pressure difference between the boundary portion between the vapor deposition source 10 and the vacuum chamber space 2a and the vacuum chamber space 2a can be lowered so as to prevent the vapor deposition particles 301 from scattering at the outlet of the vapor deposition nozzle 52.

Consequently, according to the present embodiment, loss of the vapor deposition particles 301 due to the scattering is reduced, and as a result, the number of vapor deposition particles 301 ejected in the predetermined direction can be increased. Thus, according to the present embodiment, the material utilization efficiency can be improved in comparison with that of the devices of the related art.

Note that, as described above, in the step of covering a target film forming area, the vapor deposition particles 301 ejected through the opening 45 which do not contribute to the vapor deposition film 302 being formed on the target film forming substrate 200 are retrieved by the vapor deposition particles retrieving member 14 for reuse.

Furthermore, in the present embodiment, unnecessary components of the vapor deposition particles 301 ejected from the vapor deposition nozzle 52 are blocked at the restriction plate unit 70, and as a result, the flight direction is kept constant. Subsequently, the vapor deposition particles 301 pass through the vapor deposition mask 80 including a large number of the mask openings 81, and the vapor deposition film are regularly pattern-formed on the target film forming substrate 200. Consequently, directivity of the vapor deposition particles 301 is high, and the vapor deposition film 302 can be formed with high definition.

Furthermore, according to the above described method, the vapor deposition mask 80 can be small in size by the scan vapor deposition with the vapor deposition device 100 and thus, the pattern film forming can be performed with high precision. Furthermore, according to the above described method, the small vapor deposition mask 80 can be used for the pattern film forming for the large target film forming substrate 200.

### Advantageous Effects

The effect of the vapor deposition source 10 according to the present embodiment will be specifically described by using a measurement result of the film thickness distribution. However, the size, shape, and the like of each structural element and vapor deposition materials used for the following measurements in the vapor deposition source 10 are only specific examples, and the scope of the present invention shall not be limited thereby.

### Film Thickness Distribution

Film thickness distribution is known that an n value generally can be used for evaluation. The n value is a value quantitatively indicating a material specific film forming condition (scattering/diffusion conditions in the vacuum chamber 2) and a parameter indicating distribution of the vapor deposition particles 301 ejected from the vapor deposition nozzle (in other words, directivity of the vapor deposition nozzle). The n value will be described below.

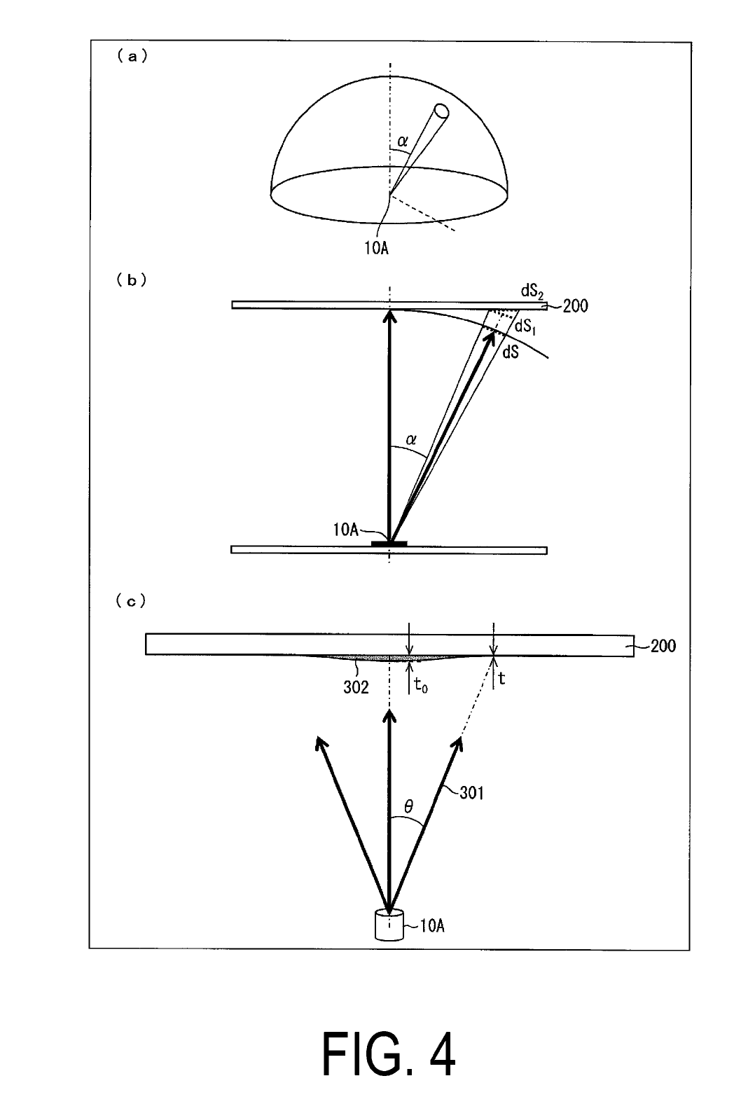

FIGS. 4A to 4C are diagrams for explaining derivation of the n value.

As illustrated in FIGS. 4A and 4B, in a case of studying a vapor deposition source point on a plane (the vapor deposition nozzle, hereinafter referred to as “a vapor deposition nozzle 10A”), distribution of vapor deposition flow density of the vapor deposition nozzle 10A D(a) is indicated as Equation (1) below

Φ(α)=Φ₀×cos α (1)

by the Lambert's cosine law.

However, the distribution is eventually limited due to the non-plane shape of a vapor deposition surface and influences of nozzle walls of the vapor deposition nozzle 10A.

In a case that an angle α of the vapor deposition nozzle 10A illustrated in FIG. 4A to the right above direction is not extremely large and the vapor deposition nozzle 10A is sufficiently small, the distribution Φ(α) of the vapor deposition flow density from the vapor deposition nozzle 10A can be approximated to be Equation (2) below

Φ(α)=Φ₀×cosⁿ α (2).

Consequently, for example, the vapor deposition speed Rsp (α) on the spherical surface of L₀ radius is represented as Equation (3) below

Rsp(α)=R₀×cosⁿ α (3),

where R₀ is vapor deposition speed right above the vapor deposition nozzle 10A.

In a case of converting the Rsp (α) into the rate on the target film forming substrate 200 as illustrated in FIG. 4B, an increment of distance cos² α and an angle correction value cosa are multiplied. Consequently, the amount of the vapor deposition (the vapor deposition speed) R (α) per unit area and unit time at the position with the angle of a from the right above direction of the vapor deposition nozzle 10A on the target film forming substrate 200 is represented as Equation (4) below

R(α)=R₀×cosⁿα×cos² α×cos α=R₀×cosⁿ⁺³ α (4).

Here, performance of the vapor deposition nozzle 10A itself is the n value. Note that, a component of “+3” is related to a geometric component.

Thus, as illustrated in FIG. 4C, the n value is derived from Equation (5) below,

t/t₀=cosⁿ⁺³ θ (5),

where the film thickness at the position with the angle of θ from the right above direction of the vapor deposition nozzle 10A on the target film forming substrate 200 is t and the film thickness at the right above the vapor deposition nozzle 10A on the target film forming substrate 200 is to.

As apparent from the Equation (5), the thickness of the vapor deposition film 302 evaporated onto the target film forming substrate 200, as illustrated in FIG. 4C, is the thickest at right above the nozzle and becomes thinner with distance from right above the vapor deposition nozzle 10A. Furthermore, the n value, as described above, indicates the directivity of the vapor deposition nozzle 10A, and thus indicates that the larger the n value is, the higher the directivity is. Consequently, the n value becomes larger, uniformity of the film thickness distribution of the vapor deposition film 302 formed by the vapor deposition particles 301 ejected from the vapor deposition nozzle 10A becomes more degraded.

### Measurement Condition of Film Thickness Distribution

The film thickness distribution was measured by following procedure: the vapor deposition source 10 was provided facing the target film forming substrate 200 and the film forming was performed with both in a stationary state; film thickness (film thickness of the vapor deposition film 302 right above the vapor deposition nozzle 52) was set to 200 nm; and the film thickness of the vapor deposition film 302 formed by the vapor deposition particles 301 ejected from a single vapor deposition nozzle 52 was optically measured per 1 mm pitch by using the known ellipsometry. Note that, the distance between the vapor deposition source 10 and the target film forming substrate 200 was set to 200 mm.

Aluminum quinolinol complex (Alq₃), which is an organic material, was used for the vapor deposition material, and a glass substrate was used for the target film forming substrate 200.

Furthermore, in the vapor deposition source 10 used for the measurement, the lengths of the first sides 32a and 52a (the opening widths dl and d11 in the Y axis direction) parallel to the Y axis direction in the vapor deposition nozzles 32 and 52 were each set to 60 mm. Furthermore, the lengths of the second sides 32b and 52b (the opening widths d2 and d12 in the X axis direction) parallel to the X axis direction in the vapor deposition nozzles 32 and 52 were each set to 3 mm With the configuration, the opening area of each vapor deposition nozzles 32 and 52 was set to 180 mm². The lengths of the third sides 32c and 52c (depths, nozzle lengths d3 and d13) parallel to the Z axis direction in the vapor deposition nozzles 32 and 52 were each set to 60 mm.

Furthermore, in the hollow portion 43, the height in the Z axis direction (that is, the distance between the vapor deposition nozzles 32 and 52) was set to 30 mm, the length in the X axis direction was set to 180 mm, and the length in the Y axis direction was set to 100 mm. Furthermore, the size of the opening 45 was set to 2 mm×4 mm (the length of a side parallel to the Z axis direction x the length of a side parallel to the Y axis direction) and thus the opening area of each opening 45 was set to 8 mm², and the total opening area of the openings 45 was set to 16 mm². With the configuration, the total opening area of the openings 45 in the hollow portion 43 was set to 1/10 or less the opening area (180 mm²) of each vapor deposition nozzle 52 in the second nozzle unit 51 downstream of the nozzle units interposing the hollow portion 43 in an ejecting direction of the vapor deposition particles (that is, the nozzle unit in the highest stage).

Furthermore, the size of the vapor deposition particles diffusion unit 20 (a drum size) was 200 mm in diameter and 200 mm in length in the X axis direction (the cylinder axis direction).

Furthermore, pressure in the vapor deposition particles diffusion unit 20 is set to a few Pa, pressure in the hollow portion 43 was set to from 1×10⁻¹ Pa to 1×10⁻³ Pa, and pressure in the vacuum chamber space 2a was set to 1×10³ Pa or less.

Furthermore, the temperature of the heating vessel (the melting pot) in the vapor deposition particles generation unit 11 was set in the range of from 250° C. to 270° C., and the temperature of each of the vapor deposition nozzles 32 and 52, the hollow portion 43, the vapor deposition particles diffusion room 21, and the pipe 12 was raised to 400° C. by the heater in order to be a sufficiently higher temperature than the temperature at which the vapor deposition material gasifies to prevent the vapor deposition material from adhering to each of the vapor deposition nozzles 32 and 52.

### Measurement Result of Film Thickness Distribution

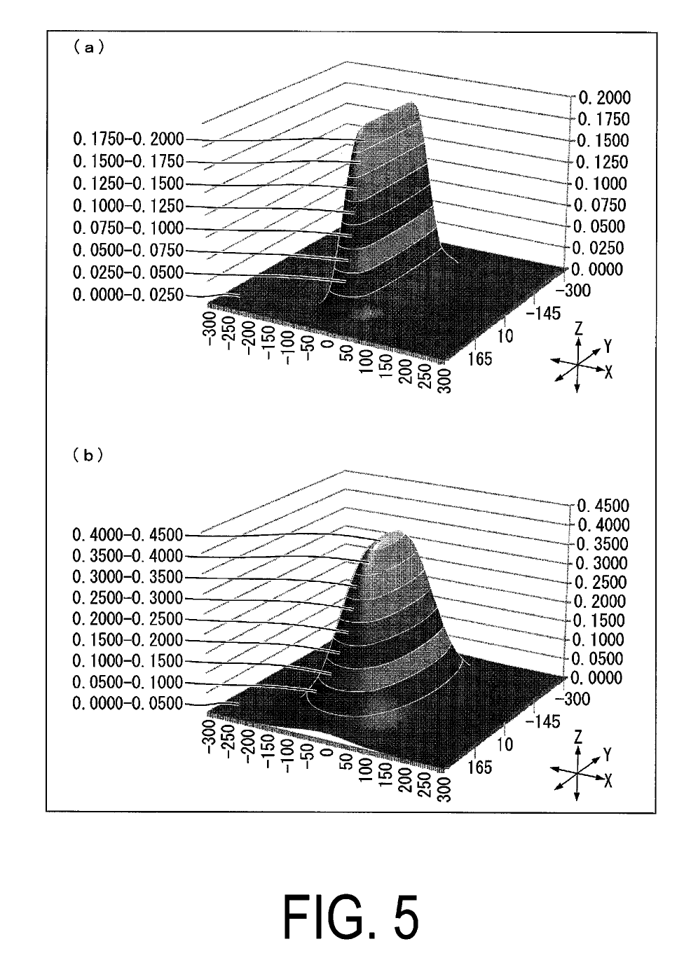

FIG. 5A is a graph schematically showing film thickness distribution of the vapor deposition film 302 formed by the vapor deposition particles 301, which are indicated by A in FIG. 1, passing the vapor deposition nozzle 52 (the second-stage nozzle) after passing the vapor deposition nozzle 32 (the first-stage nozzle). Furthermore, FIG. 5B is a graph schematically showing film thickness distribution of the vapor deposition film 302 formed by the vapor deposition particles 301, which are indicated as B in FIG. 1, passing the vapor deposition nozzle 32 (the first-stage nozzle).

Note that, in FIGS. 5A and 5B, the X axis and the Y axis, in plan view, indicate a position (unit: mm) from the central axis of the vapor deposition nozzle 52 as the ejecting source of the vapor deposition particles 301 and zero (0) indicates the position right above the central axis. Furthermore, the Z axis indicates a film thickness (unit: um) of the vapor deposition film 302.

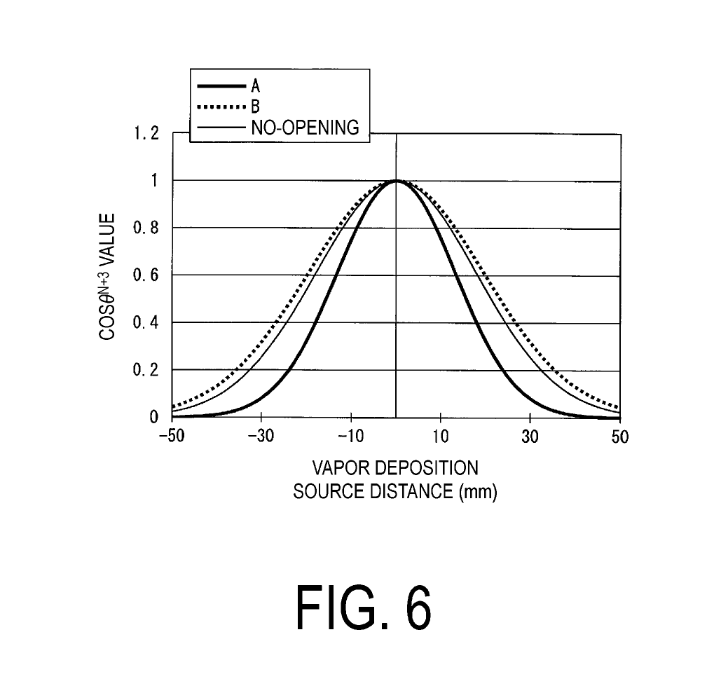

Furthermore, FIG. 6 is a graph showing effect of the vapor deposition source 10 according to the present embodiment.

In FIG. 6, a graph indicated as the bold line shows a film thickness distribution performance (that is, a relation between a cosⁿ⁺³ value and a vapor deposition source distance) of a single vapor deposition nozzle 52 at the cross section in the X axis direction of the target film forming substrate 200 in a case that the vapor deposition film 302 is formed on the target film forming substrate 200 by using the vapor deposition source 10 according to the present embodiment.

Note that, in FIG. 6, the film thickness of each area in the X axis direction is illustrated in a graph in which a cosⁿ⁺³ value is normalized with the maximum value of the film thickness of the vapor deposition film 302 formed on the target film forming substrate 200 (that is, cosⁿ⁺³ value of the right above position of a single vapor deposition nozzle 52 or vapor deposition nozzle 32) defined as 1. Furthermore, the vapor deposition source distance indicates a distance in the X axis direction from the right above position of the central axis of a single vapor deposition nozzle 52 or a single vapor deposition nozzle 32 to the film-formed area on the target film forming substrate 200.

That is, a graph indicated as the bold line is the graph showing the normalized film thickness distribution of the vapor deposition film 302 in the X axis direction formed by the vapor deposition particles 301, which are indicated as A in FIG. 1, passing the vapor deposition nozzle 52 (the second-stage nozzle) after passing the vapor deposition nozzle 32 (the first-stage nozzle).

Furthermore, a graph showed as a dotted line in FIG. 6 indicates the film thickness distribution performance of a single vapor deposition nozzle 32 at the cross section in the X axis direction of the target film forming substrate 200 in the case that the vapor deposition film 302 is formed on the target film forming substrate 200 by using the vapor deposition source 10 to which only the first-stage vapor deposition nozzle is disposed (specifically, only the vapor deposition nozzle 32). That is, the graph indicated as the dotted lines is the graph showing the normalized film thickness distribution of the vapor deposition film 302 in the X axis direction formed by the vapor deposition particles 301, which are indicated as B in FIG. 1, passing the vapor deposition nozzle 32 (the first-stage nozzle).

Furthermore, a graph indicated as a fine line in FIG. 6 shows the film thickness distribution performance of a single vapor deposition nozzle 52 at the cross section in the X axis direction of the target film forming substrate 200 in a case that the vapor deposition film 302 is formed on the target film forming substrate 200 by using the vapor deposition source 10 in which the opening 45 is not formed in the pressure adjusting unit 41. That is, a graph indicated as the fine lines is the graph showing the normalized film thickness distribution of the vapor deposition film 302 in the X axis direction formed by the vapor deposition particles 301 passing the vapor deposition nozzle 52 (the second-stage nozzle) after passing the vapor deposition nozzle 32 (the first-stage nozzle) in a case that the hollow portion 43 between the vapor deposition nozzle 32 (the first-stage nozzle) and the vapor deposition nozzle 52 (the second-stage nozzle) is closed except for the connecting section to the vapor deposition nozzles 32 and 52 as in PTL 1.

In a case of the scan vapor deposition with the Y axis direction as the scan direction for the target film forming substrate 200, the vapor deposition film 302 formed by the vapor deposition particles 301 ejected from the vapor deposition nozzle 52 becomes a stripe shaped pattern extending in the Y axis direction. Thus, because the Y axis direction is the film forming direction, the vapor deposition particles 301 scattering in the Y axis direction contribute to the film forming. Consequently, broadness of the film thickness distribution in the Y axis direction is not important issue comparing with broadness of the film thickness distribution in the X axis direction.

On the other hand, the X axis direction is a direction in which the separate deposition of the vapor deposition material is performed. The vapor deposition particles 301 scattering in the X axis direction cause the blurring of the film forming and the color mixture, and a decrease in the material utilization efficiency by flying in the vacuum chamber space 2a. Consequently, the spread of the vapor deposition particles 301 in the X axis direction is preferably suppressed as much as possible.

Especially, in the case of the scan film forming by using the scan vapor deposition technique as described above, the restriction plate unit 70 including the restriction plate 72 is preferably disposed over the vapor deposition source 10, and the vapor deposition mask 80 is preferably disposed over the restriction plate unit 70 to control the vapor deposition flow as illustrated in FIG. 3. Consequently, in a case that the film thickness distribution of the vapor deposition film 302 in the X axis direction becomes broad, the vapor deposition flow regulation by the limitation members is tightened and thus the material utilization efficiency contributing to the film forming further decreases.

As apparent from FIGS. 5A and 5B and FIG. 6, the plurality of stages of vapor deposition nozzles 32 and 52 stages are disposed to the vapor deposition source 10, and the opening 45 connecting the hollow portion 43 and the vacuum chamber space 2a at the side wall 44 of the pressure adjusting unit 41 surrounding the hollow portion 43 between the vapor deposition nozzles 32 and 52 is disposed. As a result, the sharp film thickness distribution in the X axis direction can be obtained.

The sharper film thickness distribution improves the material utilization efficiency and can form the uniform vapor deposition film 302 with sharp film thickness distribution.

Furthermore, the result of the comparison of the graph showed as the fine line with the graph showed as the dotted line both in FIG. 6 indicates the film thickness distribution of the vapor deposition film 302 in the X axis direction is little difference from the film thickness distribution of the vapor deposition film 302 in the X axis direction formed by the vapor deposition particles 301 passing the vapor deposition nozzle 32 (the first-stage nozzle) in a case that the opening 45 is not formed, that is, the hollow portion 43 between the vapor deposition nozzles 32 and 52 is closed except for the connecting section to the vapor deposition nozzles 32 and 52.

In other words, in the case that the opening 45 is not formed, that is, the hollow portion 43 between the vapor deposition nozzles 32 and 52 is closed except for the connecting section to the vapor deposition nozzles 32 and 52, the hollow portion 43 simply functions as a passing portion of the pipe (nozzle). Consequently, in the case that the opening 45 is not formed, the scattered vapor deposition particles 301 flow in from the vapor deposition nozzle 32 in the first-stage to the vapor deposition nozzle 52 in the second-stage, and thus the nozzle length is simply extended. As a result, the film thickness distribution affected by the shape of the vapor deposition nozzle 52 in the final stage located downstream in the ejecting direction is simply obtained.

Thus, in PTL 1, the vapor deposition flow regulation layers including the regulation plates 506 for limiting the flight direction of the vapor deposition particles 301 are stacked; however, no space for communicating with the outside between the vapor deposition flow regulation layers is present. As a result, the pressure difference between the vacuum chamber space and the nozzle formed by the regulation plates 506 becomes large at the outlet for the vapor deposition particles 301, and thus particles scattering eventually occurs. Consequently, in PTL 1, the vapor deposition particles component in the slant direction to the direction in which vapor deposition particles are ejected increases, and thus the material utilization efficiency is reduced.

Thus, according the present embodiment, by using the vapor deposition source 10 according to the present embodiment, scattering of the vapor deposition particles 301 at the outlet of the vapor deposition nozzle 52, that is, the final stage, can be suppressed and thus the material utilization efficiency and parallelism (collimation) of the vapor deposition particles 301 can be improved in comparison with devices of the related art.

Furthermore, since parallelism of the vapor deposition particles 301 can be improved according to the present embodiment, directivity of the vapor deposition particles 301 is high and the vapor deposition with high precision can be performed and thus the vapor deposition film 302 with high definition can be formed.

### MODIFIED EXAMPLE

FIG. 7 is a perspective view illustrating a schematic structure of the principal part of a vapor deposition device 100 according to an example of the present modified example. Note that, in FIG. 7 as well, the number of vapor deposition nozzles 32 and 52, the number of restriction plate openings 71, and the number of mask openings 81 and other descriptions are partially omitted, and each structural element shape is simplified for the sake of convenience of illustration.

A modified example according to the present embodiment will be described below with reference to FIG. 1 to FIG. 3, and FIG. 7.

### Arrangement of Vapor Deposition Source 10

As described above, in the present embodiment, an example has been described as a case that the vapor deposition source 10 includes the vapor deposition source main body 13, the pipe 12, and the vapor deposition particles generation unit 11, and among the above, part of the pipe 12 and the vapor deposition particles generation unit 11 are disposed outside of the vacuum chamber 2.

However, the present embodiment is not limited to the structure, and may have a structure that each of the vapor deposition source main body 13, the pipe 12, and the vapor deposition particles generation unit 11 is disposed in the vacuum chamber 2 (that is, the whole vapor deposition source 10 is disposed in the vacuum chamber 2).

### First Modified Example of Structure of Vapor Deposition Source 10

Furthermore, in the present embodiment, an example has been described as a case that the vapor deposition particles generation unit 11 is disposed aside from the vapor deposition source main body 13, and the vapor deposition source main body 13 and the vapor deposition particles generation unit 11 are connected with the pipe 12. However, the vapor deposition particles generation unit 11 may be disposed in the vapor deposition source main body 13 as illustrated with the dotted line in FIG. 7, for example. For example, the vapor deposition particles diffusion unit 20 (the vapor deposition particles diffusion room 21) may function as the vapor deposition particles generation section and the vapor deposition particles diffusion section in a case that the vapor deposition particles diffusion room 21 includes a heating vessel such as a melting pot configured to contain the vapor deposition material 300 therein and a heater as the vapor deposition particles generation unit 11. Note that, in a case of the vapor deposition particles diffusion room 21 housing the vapor deposition particles generation unit 11, the pipe 12 and the vapor deposition particles inlet 22 are not necessary to be disposed. In this case as well, the whole vapor deposition source 10 is disposed in the vacuum chamber 2.

### Second Modified Example of Structure of Vapor Deposition Source 10

Furthermore, in the present embodiment, an example has been described as a case that the first nozzle unit 31, the pressure adjusting unit 41, and the second nozzle unit 51 are all block shaped units and integrated as the vapor deposition particles ejecting unit 30.

However, the vapor deposition particles ejecting unit 30 is not limited to the structure, and, for example, may have a structure including through holes as the vapor deposition nozzles 32 and 52 at the top wall and the bottom wall of a hollow vessel and may also have a structure in which the opening 45 connecting the vacuum chamber space 2a and the hollow portion 43 between the vapor deposition nozzles 32 and 52 is formed in the side wall (outer wall) of the hollow vessel. Furthermore, the vapor deposition particles ejecting unit 30 may have a structure in which the inside of the frame is partitioned by the plurality of regulation plates 33 and 53.

### Third Modified Example of Structure of Vapor Deposition Source 10

Furthermore, in the present embodiment, an example has been described as a case that the vapor deposition particles ejecting unit 30 includes the first nozzle unit 31 and the second nozzle unit 51 as a plurality of stages of nozzle section (the vapor deposition nozzle section). However, the plurality of stages of nozzle unit may include three stages or more of nozzle units (the nozzle unit). In this case, the hollow portion connected to the vacuum chamber space 2a not via the vapor deposition nozzle of each stage is preferably formed between the vapor deposition nozzles of the nozzle unit of each stage, and the opening connecting the hollow portion and the vacuum chamber space 2a is preferably formed in the part of the side wall 44 (the outer wall) surrounding the hollow portion. Note that, in this case as well, the pressure adjusting valve 46 is preferably disposed in the opening connecting the hollow portion and the vacuum chamber space 2a and, the vapor deposition particles 301 discharged outside directly from the opening or through the pressure adjusting valve 46 are preferably retrieved at the vapor deposition particles retrieving member 14.

### Fourth Modified Example of Structure of Vapor Deposition Source 10

Furthermore, in FIG. 1 to FIG. 3, an example as a case that the vapor deposition particles diffusion unit 20 has a drum shape (cylindrical shape) has been illustrated. However, the shape of the vapor deposition particles diffusion unit 20 is not limited to the above shape, and is not specifically limited as long as the vapor deposition particles diffusion unit 20 includes the vapor deposition particles diffusion room 21 therein as a diffusion space for diffusing the vapor deposition particles 301. Thus, the vapor deposition particles diffusion unit 20, for example, as illustrated in FIG. 7, may be a hollow vessel whose outer shape is a quadrangular prism shape. Furthermore, the quadrangular prism shape may be a rectangular parallelepiped shape or a cube shape.

### Fifth Modified Example of Structure of Vapor Deposition Source 10

Furthermore, in the present embodiment, an example has been described as a case that the delivery port 26 has a shape identical to that of the vapor deposition nozzles 32 and 52 in plan view, and are superimposed with each other such that central axes (opening center) thereof match. However, the shape and size of the delivery port 26 are not limited to the above shape and size, and a single delivery port 26 may be formed facing the plurality of vapor deposition nozzles 32 (for example, the whole vapor deposition nozzles 32). Thus, the delivery port 26 may have a shape coupling the plurality of (for example, all) vapor deposition nozzles 32.

### Sixth Modified Example of Structure of Vapor Deposition Source 10

Furthermore, in the present embodiment, an example has been described as a case that the plurality of vapor deposition nozzles (for example, the vapor deposition nozzles 32 and 52) are arranged in the X axis direction in the nozzle unit of each stage (for example, the first nozzle unit 31 and the second nozzle unit 51). In the case that the plurality of vapor deposition nozzles are arranged in the X axis direction in the nozzle unit of each stage, the plurality of vapor deposition films 302 can be formed on the target film forming substrate 200 in the X axis direction by using a single vapor deposition source 10. Consequently, the vapor deposition film 302 can be efficiency formed even to a large target film forming substrate 200.

However, the present embodiment is not limited to the structure, the nozzle unit of each stage may include at least one vapor deposition nozzle (for example, the vapor deposition nozzles 32 and 52). As described above, the result, as illustrated in FIG. 5 and FIG. 6, of the measurement of the film thickness distribution of the vapor deposition film 302 ejected from a single vapor deposition nozzle 52 in a static film forming state apparently describes that disposing the opening 45 at the hollow portion 43 between vapor deposition nozzles enables the effect described in the present embodiment to be obtained even in a case that the vapor deposition source 10 has a structure that only one vapor deposition nozzle is disposed in the nozzle unit of each stage.

### First Modified Example of Schematic Structure of Vapor Deposition Device 100 and Method for Manufacturing Vapor Deposition Film

Furthermore, in the present embodiment, an example has been described as a case that the vapor deposition mask 80, the restriction plate unit 70, and the vapor deposition source 10 are each fixed to somewhere in the inner wall of the vacuum chamber 2, and the target film forming substrate 200 is moved relative to the vapor deposition mask 80, the restriction plate unit 70, and the vapor deposition source 10 by using the substrate carrying device 3, and thus the target film forming substrate 200 is evaporated while being scanned (scan vapor deposition).

However, the present embodiment is not limited to the above, and, for example, the target film forming substrate 200 is fixed and, for example, the vapor deposition mask 80, the restriction plate unit 70, and the vapor deposition source 10 are moved relative to the target film forming substrate 200 so that the Y axis direction is the scan direction. Furthermore, for example, a set of the vapor deposition mask 80, the restriction plate unit 70, and the vapor deposition source 10, or the target film forming substrate 200 may be moved relative to each other so that the Y axis direction is the scan direction.

In the above case, the vapor deposition mask 80, the restriction plate unit 70, and the vapor deposition source 10 may be unified as the vapor deposition unit 1. In the case that the vapor deposition mask 80, the restriction plate unit 70, and the vapor deposition source 10 are unified as a single vapor deposition unit (the vapor deposition unit 1), the vapor deposition mask 80, the restriction plate unit 70, and the vapor deposition source 10 may be, for example, (i) fixed together with a solid member, (ii) all actuated in a controlled action as one unit with each having a separate structure.

That is, in the present embodiment, at least one of the vapor deposition unit 1 and the target film forming substrate 200 may be moved relative to each other so that the Y axis direction is the scan direction.

Furthermore, a following structure is possible in which the vapor deposition mask 80, the restriction plate unit 70, and the vapor deposition source 10 are held by an identical holding member to which the shutter actuator (shutter moving device) is attached, and thus the vapor deposition mask 80, the restriction plate unit 70, the shutter 60, and the vapor deposition source 10 are held by the identical holding member (holder). In other words, the vapor deposition unit 1 may include the shutter 60.

As described above, in the case that the vapor deposition mask 80, the restriction plate unit 70, and the vapor deposition source 10 are moved relative to the target film forming substrate 200, the vapor deposition device 100 may further include a carrying device (moving device) (not illustrated) configured to move the vapor deposition mask 80, the restriction plate unit 70, and the vapor deposition source 10 relative to the target film forming substrate 200.

For example, in a case that the vapor deposition mask 80, the restriction plate unit 70, and the vapor deposition source 10 are held by separate holding members (that is, a vapor deposition mask holding member, a restriction plate unit holding member, and a vapor deposition source holding member), the vapor deposition device 100 may further include, for example, a vapor deposition mask carrying device, a restriction plate unit carrying device, and a vapor deposition source carrying device as carrying devices for separately moving each of the vapor deposition mask 80, the restriction plate unit 70, and the vapor deposition source 10 relative to the target film forming substrate 200. The operation of the vapor deposition mask carrying device, the restriction plate unit carrying device, and the vapor deposition source carrying device are controlled by a controller (not illustrated) to fix the positional relation among the vapor deposition mask 80, the restriction plate unit 70, and the vapor deposition source 10.

Furthermore, in the case that the vapor deposition mask 80, the restriction plate unit 70, and the vapor deposition source 10 are unified as a single vapor deposition unit, the vapor deposition device 100 may further include a vapor deposition unit carrying device (a vapor deposition unit moving device) (not illustrated) to move the vapor deposition unit relative to the target film forming substrate 200.

Known various moving devices such as roller type moving devices and hydraulic moving devices are used for the described carrying device.

Note that, the substrate carrying device 3 may not necessarily be disposed in a case that the vapor deposition mask 80, the restriction plate unit 70, and the vapor deposition source 10 are moved relative to the fixed target film forming substrate 200.

### Second Modified Example of Schematic Structure of Vapor Deposition Device 100 and Method for Manufacturing Vapor Deposition Film

Furthermore, in the present embodiment, an example has been described as a case that the length of the vapor deposition mask 80 in the Y axis direction is shorter than the length of the target film forming substrate 200 in the Y axis direction, and the positional relation among the vapor deposition mask 80, the restriction plate unit 70, and the vapor deposition source 10 is fixed (that is, the positional relation in all axis directions of the X axis, the Y axis, and the Z axis fixed).

However, the present embodiment is not limited to the structure, and another example in the present embodiment may have a structure in which the vapor deposition mask 80 has a size (for example, an identical size) almost identical to the target film forming substrate 200, in plan view, and the target film forming substrate 200 and the vapor deposition mask 80 are disposed in contact with each other. In this case, (i) the restriction plate unit 70 may have a structure in which, as illustrated in FIG. 3, the length of the restriction plate 72 in the Y axis direction is shorter than the length of the target film forming substrate 200 in the Y axis direction, and the positional relation between the restriction plate unit 70 and the vapor deposition source 10 is fixed, or (ii) the restriction plate unit 70 (not illustrated) may have a size (for example, an identical size) almost identical to the vapor deposition mask 80 and the target film forming substrate 200 in plan view.

In the case that the target film forming substrate 200 and the vapor deposition mask 80 have an almost identical size in plan view, and the positional relation between the restriction plate unit 70 and the vapor deposition source 10 is fixed, the scan vapor deposition can be performed by moving at least one of following (i) and (ii) relative to the other: (i) the target film forming substrate 200 and the vapor deposition mask 80, and (ii) the restriction plate unit 70 and the vapor deposition source 10.

Furthermore, in a case that the target film forming substrate 200, the vapor deposition mask 80, and the restriction plate unit 70 have an almost identical size in plan view, the scan vapor deposition can be performed by moving at least one of following (i) and (ii) relative to the other: (i) the target film forming substrate 200, the vapor deposition mask 80, and the restriction plate unit 70, and (ii) the vapor deposition source 10.

Note that, in the case that the target film forming substrate 200 and the vapor deposition mask 80 have an almost identical size in plan view, each mask opening 81 is formed corresponding to the pattern of each vapor deposition film 302 to be formed on the target film forming substrate 200.

### Third Modified Example of Schematic Structure of Vapor Deposition Device 100 and Method for Manufacturing Vapor Deposition Film

Furthermore, FIG. 3 illustrates an example as a case that the plurality of mask openings 81 having a slot shape are two-dimensionally formed. However, the vapor deposition mask 80 may have a structure illustrated in FIG. 7 as an example that the plurality of mask openings 81 having a slit shape extending along the Y axis direction are arranged in the X axis direction, as described above. Furthermore, although FIG. Sand FIG. 7 illustrate an example as a case that the vapor deposition mask 80 has at least the plurality of mask openings 81 arranged in the X axis direction, the vapor deposition mask 80 may be so called an open mask to which only a single mask opening 81 is formed. In this case as well, scattering of the vapor deposition particles 301 can be suppressed and thus the effect according to the present embodiment can be obtained.

### Another Modified Example of Method for Manufacturing Vapor Deposition Film

The vapor deposition source 10 according to the present embodiment can be suitably used for the scan vapor deposition as described above. However, the vapor deposition source 10 according to the present embodiment is not limited to the above, and can be suitably used for the followings: (i) a method for the vapor deposition with the positional relation among the target film forming substrate 200, the vapor deposition mask 80, the restriction plate unit 70, and the vapor deposition source 10 fixed, or (ii) the step vapor deposition that the vapor deposition mask 80 is sequentially moved to the target film forming substrate 200 and is brought into close contact (contact) with the target film forming substrate 200 each time of the sequential movement for the film forming. In this case, according to the present embodiment, at least the film thickness distribution in the X axis direction is improved comparing with methods of the related art. Furthermore, according to the present embodiment, forming the opening 45 in the hollow portion 43 enables the vapor deposition particles 301 from scattering at the outlet of each vapor deposition nozzles 32 and 52, and thus the film thickness distribution in the Y axis direction can be improved as well in comparison with the case that the opening 45 is not formed.

However, in a case of using the vapor deposition scheme described in the (i) or (ii), opening shapes of the vapor deposition nozzles 32 and 52 in plan view are preferably changed to improve the directivity both in the X axis direction and the Y axis direction, for example, as illustrated in third and fourth embodiments described later.

### Down Deposition

Furthermore, in the present embodiment, an example has been described as a case that the vapor deposition particles are deposited upward from downstream side (Up deposition). However, aspects of the present embodiment are not limited to the above, the vapor deposition particles may be vapor deposited downward from the above side to the target film forming substrate 200 (Down deposition).

In this case, the holding member holding the target film forming substrate 200, the vapor deposition mask 80, the restriction plate unit 70, the shutter 60, and the vapor deposition source 10 are provided such that the structural elements are disposed in the reverse position, and the vapor deposition source 10 is disposed such that the vapor deposition particles ejecting unit 30 is located under the vapor deposition particles diffusion unit 20.

As described above, in a case of the vapor deposition by the down deposition, a pattern with high definition can be precisely formed all over the surface of the target film forming substrate 200 without using methodologies such as an electrostatic chuck for suppressing deformation caused by the self-weight.

### Another Modified Example of Schematic Structure of Vapor Deposition Device 100

Furthermore, in the present embodiment, an example has been described as a case that the restriction plate unit 70 and the shutter 60 are disposed between the vapor deposition mask 80 and the vapor deposition source 10. However, the restriction plate unit 70 and the shutter 60 are not always necessary. For example, in the case that the vapor deposition mask 80 is brought into close contact (contact) with the target film forming substrate 200 for the vapor deposition as described above, the restriction plate unit 70 and the shutter 60 can be omitted.

### Second Embodiment

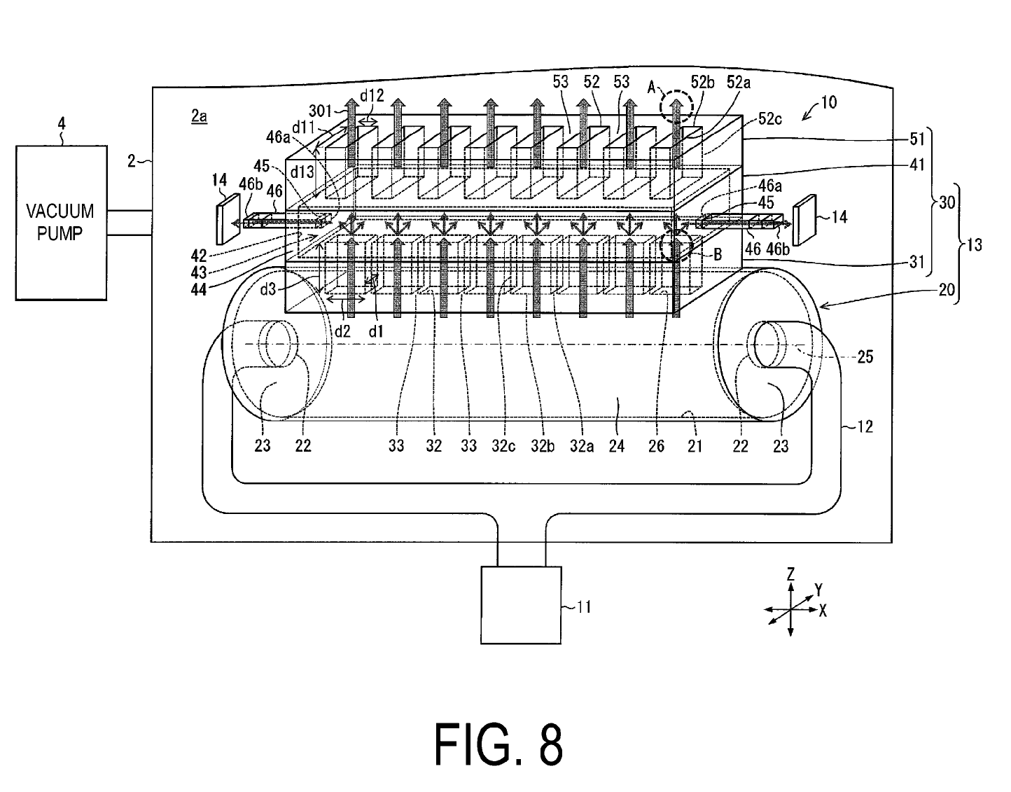

Furthermore, another embodiment in the present invention will be described below mainly on the basis of FIG. 8 to FIGS. 11A and 11B. Here, the description will be for the difference between the present embodiment and the first embodiment, and a structural element having the function identical to that of the structural element used in the first embodiment is numbered the identical number thereof and the description thereof is omitted.

### Schematic Structure of Vapor Deposition Source 10

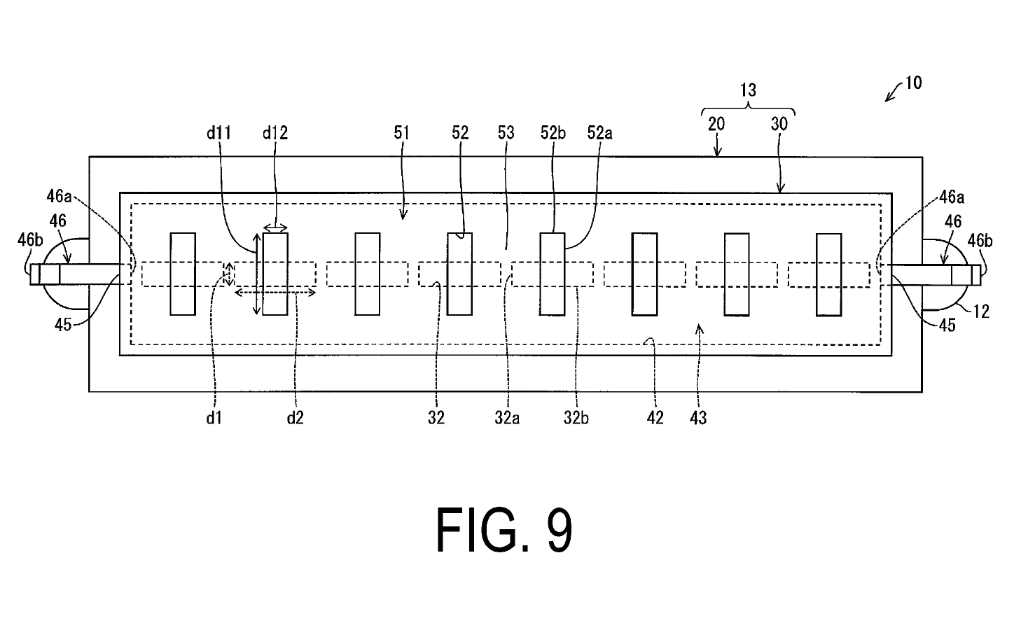

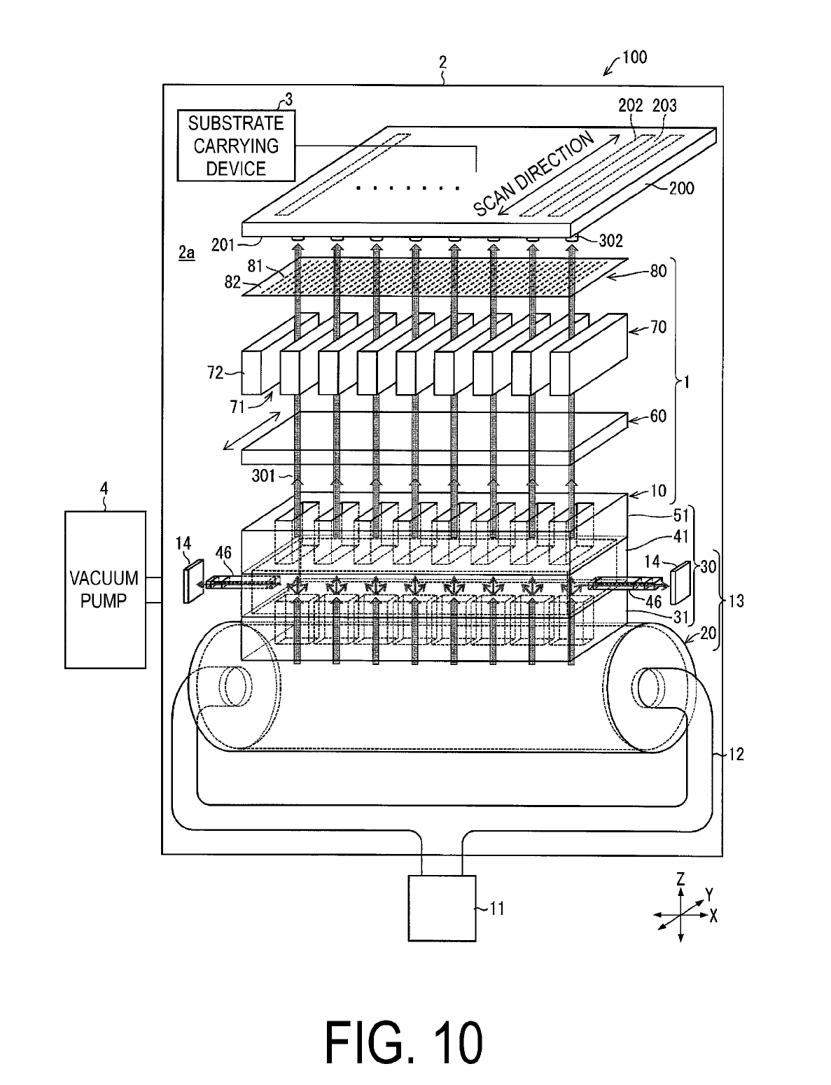

FIG. 8 is a perspective view illustrating a schematic structure of the vapor deposition source 10 according to the present embodiment. FIG. 9 is a plan view illustrating the schematic structure of the vapor deposition source 10 illustrated in FIG. 8. FIG.10 is a perspective view illustrating a schematic structure of the principal part of the vapor deposition device 100 according to the present embodiment.

Note that, in FIG. 8 to FIG. 10 as well, the number of the vapor deposition nozzles 32 and 52, the number of the restriction plate openings 71, and the number of the mask openings 81 and other descriptions are partially omitted, and each structural element shape is simplified for the sake of convenience of illustration.

The vapor deposition device 100 according to the present embodiment is identical with the vapor deposition device 100 according to the first embodiment except for the difference of opening shapes in plan view between the vapor deposition nozzle 32 and the vapor deposition nozzle 52 which are in the first nozzle unit 31 and the second nozzle unit 51 respectively in the vapor deposition source 10 in the present embodiment. However, in the present embodiment as well, the delivery port 26, as in the first embodiment, is identical with the vapor deposition nozzle 32 in shape in plan view, and is connected to the vapor deposition nozzle 32 by connecting an opening end of the delivery port 26 and an opening end of the vapor deposition nozzle 32 each other. Consequently, strictly speaking, the shape of the delivery port 26 in plan view (in other words, the long axis direction of the delivery port 26 in plan view) in the vapor deposition source 10 according to the present embodiment is also different from the shape of the delivery port 26 in plan view according to the first embodiment (the long axis direction of the delivery port 26 in plan view).

In the present embodiment, the vapor deposition nozzle 32 and the vapor deposition nozzle 52 are different in the arrangement direction by 90 degrees.

In each vapor deposition nozzle 32, in plan view, the longer axis direction is set to the Xaxis direction, and the long side of each vapor deposition nozzle 32 is parallel to the X axis and the short sides of the vapor deposition nozzles 32 face each other such that adjacent vapor deposition nozzles 32 are aligned on a straight line in the X axis direction. Consequently, each vapor deposition nozzle 32 is formed to be a rectangular shape, in plan view, in which the first side 32a parallel to the Y axis direction is the short side, and the second side 32b parallel to the X axis direction is the long side.

On the other hand, the vapor deposition nozzles 52 are each disposed such that the long sides of the vapor deposition nozzles 52 are each parallel to the Y axis and face each other in plan view. Consequently, each vapor deposition nozzle 52 is formed to be a rectangular shape, in plan view, in which the first side 52a parallel to the Y axis direction is the long side and the second side 52b parallel to the X axis direction is the short side.

As described, in a case that the opening shape of each vapor deposition nozzles 32 and 52 in plan view has a rectangular shape structured by the long sides and the short sides, the film thickness distribution of the vapor deposition film 302 formed by the vapor deposition particles 301 ejected from each of the vapor deposition nozzles 32 and 52 is broad in the long side direction; however, can be sharp in the short side direction.

Consequently, the arrangement direction of each vapor deposition nozzles 32 and 52 is changed by 90 degrees, and the vapor deposition nozzles 32 and 52 are stacked while overlapped with each other with the hollow portion 43 interposed therebetween. This allows the sharp film thickness distribution such as a square shape and a quadrangular prism shape to be obtained.

Consequently, in the present embodiment, as illustrated in FIG. 8 and FIG. 9, the arrangement direction of the identical shaped vapor deposition nozzles 32 and 52 is changed by 90 degrees, and the vapor deposition nozzles 32 and 52 are stacked while overlapped with each other with the hollow portion 43 interposed therebetween. Then, as described in first embodiment, the X axis direction is the direction in which separate deposition for the vapor deposition material is performed. Thus, as described above, the vapor deposition nozzle 52 as an ejection port to the outside preferably has the rectangular shape in plan view, with the long side in the Y axis direction and the short side in the X axis direction to suppress spread of the vapor deposition particles 301 in the X axis direction as much as possible.

Furthermore, in the case of the film forming by carrying the target film forming substrate 200 as described in the first embodiment, the opening width of the vapor deposition nozzle (the opening widths d1 and d11 in the Y axis direction) in the carrying direction of the target film forming substrate 200 is preferably as long as possible, and the opening widths d1 and d11 in the Y axis direction are preferably longer than the nozzle lengths d3 and d13 in the Z axis direction to speed up the takt time.

Consequently, the length of the long side of the vapor deposition nozzle 52 (that is, the first side 52a parallel to the Y axis direction) with the long side in the Y axis direction (that is, the opening width d11 of the vapor deposition nozzle 52 in the Y axis direction) is preferably formed longer than the nozzle length d13 of the vapor deposition nozzle 52 in the Z axis direction.

Note that, as described in the first embodiment, since the Y axis direction is the film forming direction, the vapor deposition particles 301 scattering in the Y axis direction contribute to the film forming in a case of the scan vapor deposition. Consequently, broadness of the film thickness distribution in the Y axis direction is not important issue comparing with broadness of the film thickness distribution in the X axis direction.

However, in the scan vapor deposition, first, the vapor deposition particles 301 are ejected from the vapor deposition source 10, and subsequently, the vapor deposition is performed while the target film forming substrate 200 and the vapor deposition unit 1 are relatively moved with the vapor deposition particles 301 ejected. Subsequently, the scan direction of the target film forming substrate 200 is reversed along the Y axis direction for shuttle scanning to perform the vapor deposition multiple times on an identical area for obtaining the desired film thickness.

Consequently, even in a case of the scan vapor deposition, waste of the vapor deposition material due to spread of the vapor deposition particles 301 occurs at both ends of the target film forming substrate 200 in the Y axis direction. Furthermore, regardless of the scan vapor deposition application, the whole vapor deposition particles 301 not reaching to the target film forming area 202 on the target film forming substrate 200 become the waste of the vapor deposition material. Especially, the organic material configuring an organic layer (organic EL layer) of an organic EL element is a quite expensive material in unit cost that is a peculiar functional material having electrical conductivity, carrier transportation characteristics, light-emitting characteristics, heat and electrical stability and the like.

Thus, improving the directivity of the vapor deposition particles 301 to obtain the sharp film thickness distribution both in the X axis direction and the Y axis direction is further preferable in view of further increase in the utilization efficiency of the vapor deposition material.

### Advantageous Effects

The effect of the vapor deposition source 10 according to the present embodiment will be specifically described by using a measurement result of the film thickness distribution.

### Measurement Condition of Film Thickness Distribution

Note that, as described above, the film thickness distribution was measured in the condition similar to that of the first embodiment except that the arrangement direction of the vapor deposition nozzles 32 and 52 was changed by 90 degrees.

That is, in the present embodiment, the film thickness distribution was measured in a condition identical to that of the first embodiment except that each length of the long side of the vapor deposition nozzles 32 and 52 was set to 60 mm, and each length of the short side of the vapor deposition nozzles 32 and 52 is set to 3 mm, and thus the length of the first side 32a in the vapor deposition nozzle 32 parallel to the Y axis direction (the opening width d1 in the Y axis direction) was set to 3 mm, and the length of the second side 32b in the vapor deposition nozzle 32 parallel to the X axis direction (the opening width d2 in the X axis direction) was set to 60 mm. Thus, in the present embodiment as well, the opening area of each vapor deposition nozzles 32 and 52 was 180 mm², and the total opening area of the openings 45 was 16 mm², and the total opening area of the openings 45 in the hollow portion 43 was 1/10 or less the opening area of each vapor deposition nozzle 52 in the second nozzle unit 51 (180 mm²).

### Measurement Result of Film Thickness Distribution

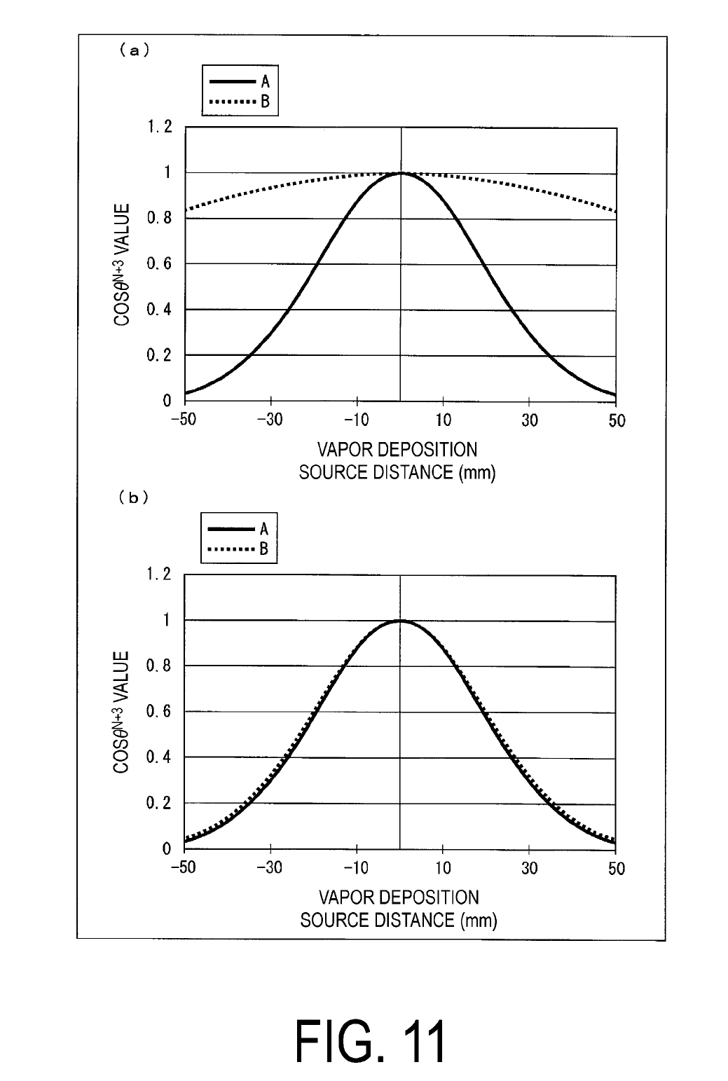

FIGS. 11A and 11B are graphs showing the effect of the vapor deposition source 10 according to the present embodiment, and FIG. 11A shows film thickness distribution of the vapor deposition film 302 in the X axis direction, and FIG. 11B shows film thickness distribution of the vapor deposition film 302 in the Y axis direction.

More specifically, graphs indicated as the bold line in FIGS. 11A and 11B shows a film thickness distribution performance (that is, the relation between a cosⁿ⁺³ value and a vapor deposition source distance) of a single vapor deposition nozzle 52 at the cross section in the X axis direction or the Y axis direction of the target film forming substrate 200 in a case that the vapor deposition film 302 is formed on the target film forming substrate 200 by using the vapor deposition source 10 according to the present embodiment.

Note that, in FIGS. 11A and 11B as well, the normalized film thickness of each area in the X axis direction or Y axis direction is showed in a graph in which a cosⁿ⁺³ value is normalized with the maximum value of the film thickness of the vapor deposition film 302 formed on the target film forming substrate 200 (that is, a cosⁿ⁺³ value of the right above position of a single vapor deposition nozzle 52 or vapor deposition nozzle 32) defined as 1. Furthermore, the vapor deposition source distance in FIG. 11A indicates a distance in the X axis direction from the right above position of the central axis of a single vapor deposition nozzle 52 or a single vapor deposition nozzle 32 to the film-formed area in the target film forming substrate 200. Furthermore, the vapor deposition source distance in FIG. 11B indicates a distance in the Y axis direction from the right above position of the central axis of a single vapor deposition nozzle 52 or a single vapor deposition nozzle 32 to the film-formed area in the target film forming substrate 200.

Thus, a graph indicated as the bold line in FIG. 11A is the graph showing the normalized film thickness distribution of the vapor deposition film 302 in the X axis direction formed by the vapor deposition particles 301, which are illustrated as A in FIG. 8, passing the vapor deposition nozzle 52 (the second-stage nozzle) after passing the vapor deposition nozzle 32 (the first-stage nozzle).

Furthermore, a graph indicated as the bold line in FIG. 11B is the graph showing the normalized film thickness distribution of the vapor deposition film 302 in the Y axis direction formed by the vapor deposition particles 301, which are illustrated as A in FIG. 8, passing the vapor deposition nozzle 52 (the second-stage nozzle) after passing the vapor deposition nozzle 32 (the first-stage nozzle).

Furthermore, graphs indicated as a dotted line in FIGS. 11A and 11B show the film thickness distribution performance of a single vapor deposition nozzle 32 at the cross section in the X axis direction or the Y axis direction of the target film forming substrate 200 in a case that the vapor deposition film 302 is formed on the target film forming substrate 200 by using the vapor deposition source 10 to which only the first-stage vapor deposition nozzle is disposed (specifically, only the vapor deposition nozzle 32).

That is, the graph indicated as the dotted line in FIG. 11A is the graph showing the normalized film thickness distribution of the vapor deposition film 302 in the X axis direction formed by the vapor deposition particles 301, which are illustrated as B in FIG. 8, passing the vapor deposition nozzle 32 (the first-stage nozzle).

Furthermore, the graph indicated as the dotted line in FIG. 11B is the graph showing the normalized film thickness distribution of the vapor deposition film 302 in the Y axis direction formed by the vapor deposition particles 301, which are illustrated as B in FIG. 8, passing the vapor deposition nozzle 32 (the first-stage nozzle).

The vapor deposition nozzle 32 has a rectangular shape in plan view with the long side in the X axis direction, and the short side in the Y axis direction as illustrated in FIG. 8 and FIG. 9. As a result, the vapor deposition film 302 formed by the vapor deposition particles 301 passing the vapor deposition nozzle 32 (the first-stage nozzle) can be obtained with the sharp film thickness distribution in the Y axis direction as illustrated in FIG. 11B; however, the film thickness distribution in the X axis direction thereof becomes broad as illustrated in FIG. 11A.

However, according to the present embodiment, the orientation of the vapor deposition nozzle 52 rotates by 90 degrees to an orientation of the vapor deposition nozzle 32 as described above, and thus the spread of the vapor deposition particles 301 in the X axis direction is suppressed. Furthermore, in the present embodiment, due to the opening 45 formed in the hollow portion 43 between the vapor deposition nozzles 32 and 52, scattering of the vapor deposition particles 301 is suppressed (or does not occur) at the outlet of the vapor deposition nozzle 32 and the outlet of the vapor deposition nozzle 52, and thus the vapor deposition particles 301 are not spread in the Y axis direction. Consequently, the film forming is performed in the Y axis direction with the distribution of the vapor deposition particles 301 passing the vapor deposition nozzle 32 maintained as it is, and thus the film thickness distribution by the vapor deposition particles 301 passing the vapor deposition nozzle 32 is maintained after passing the vapor deposition nozzle 52 as well. Thus, according to the present embodiment, as showed with the bold line in FIGS. 11A and 11B, the sharp film thickness distribution can be realized both in the X axis direction and the Y axis direction.

### Modified Example

Note that, in the present embodiment as well, an example has been described as a case that the delivery port 26 in the vapor deposition particles diffusion unit 20 has a shape, in plan view, identical to that of the vapor deposition nozzle 32. However, as described in first embodiment, the shape and size of the delivery port 26 are not limited to this, and a single delivery port 26 may be formed facing the plurality of vapor deposition nozzles 32 (for example, the whole vapor deposition nozzles 32). Thus, the delivery port 26 may have a shape coupling the plurality of (for example, all) vapor deposition nozzles 32 (a rectangular shape with the X axis direction as the long axis direction in any case in the present embodiment).

Furthermore, needless to say, the modification similar to the first embodiment can be applied in the present embodiment.

### Third Embodiment

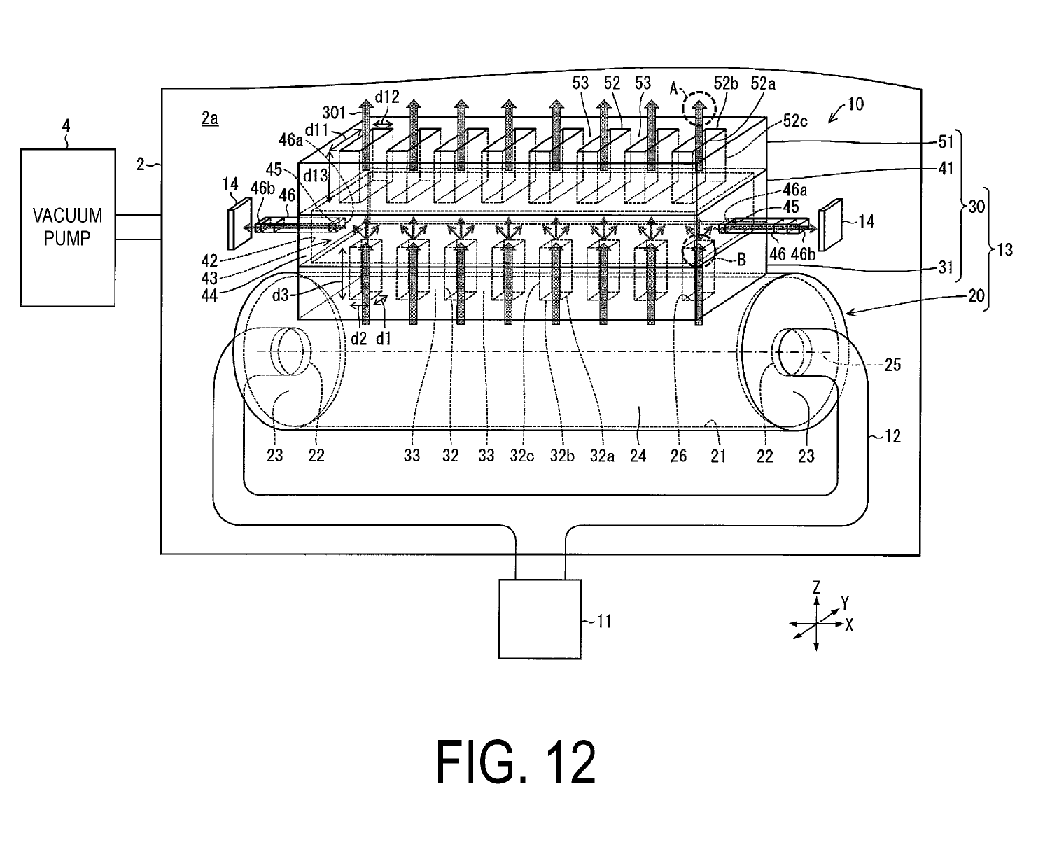

Furthermore, another embodiment in the present invention will be described below mainly on the basis of FIG. 12 to FIGS. 14A and 14B. Here, the description will be for the difference between the present embodiment and the first and second embodiments, and a structural element having a function identical to that of the structural element used in the first and second embodiments is numbered the identical number thereof and the description thereof is omitted.

### Schematic Structure of Vapor Deposition Source 10

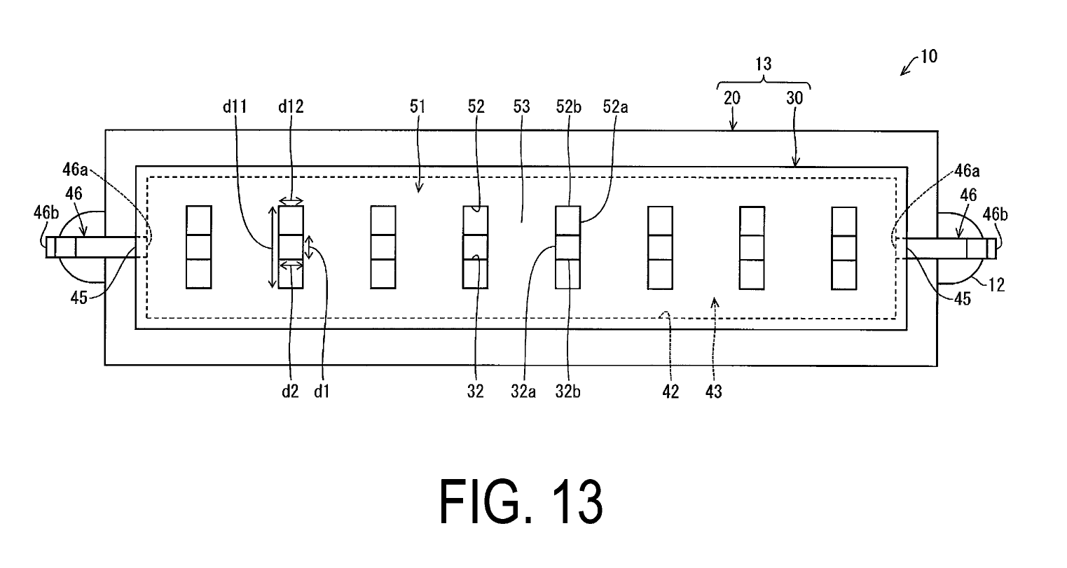

FIG. 12 is a perspective view illustrating a schematic structure of the vapor deposition source 10 according to the present embodiment. FIG. 13 is a plan view illustrating the schematic structure of the vapor deposition source 10 illustrated in FIG. 12. Note that, in FIG. 12 and FIG. 13 as well, the numbers of the vapor deposition nozzles 32 and 52, and other descriptions are partially omitted, and each structural element shape is simplified for the sake of convenience of illustration.

The vapor deposition device 100 according to the present embodiment is identical with the vapor deposition device 100 according to the first and second embodiments except for the difference of opening shapes in plan view between the vapor deposition nozzle 32 and the vapor deposition nozzle 52 which are in the first nozzle unit 31 and the second nozzle unit 51 respectively in the vapor deposition source 10 in the present embodiment. Consequently, an illustration of the whole vapor deposition device 100 is omitted in the present embodiment.

Note that, in the present embodiment as well, the delivery port 26 in the vapor deposition particles diffusion unit 20, for example, is identical with the vapor deposition nozzle 32 in shape in plan view, and is connected to the vapor deposition nozzle 32 by connecting an opening end of the delivery port 26 and an opening end of the vapor deposition nozzle 32 each other.

The vapor deposition source 10 illustrated in FIG. 12 and FIG. 13 is different from the vapor deposition source 10 illustrated in the first and second embodiments only in the shape of the vapor deposition nozzle 32 in plan view which is formed in a square shape.

Each vapor deposition nozzle 52 is similar with the vapor deposition nozzle 52 in the vapor deposition source 10 according to the first and second embodiments that is formed in a rectangular shape, in plan view, with the first side 32a parallel to the Y axis direction as a long side, and the second side 32b parallel to the X axis direction as a short side.

Note that, in the present embodiment, since only the vapor deposition nozzle 32 is formed in a square shape in plan view, the opening areas (areas in plan view) of the vapor deposition nozzles 32 and 52 differ from each other. As described above, even in the case that the opening areas of the vapor deposition nozzles 32 and 52 differ from each other, the total opening area of the openings 45, in other words, the sum of the opening areas of the openings 45 is preferably sufficiently small compared with the opening area of the vapor deposition nozzle 52. The vapor deposition nozzle 52 is in the second nozzle unit 51 and is also the nozzle unit in the succeeding stage of the hollow portion 43 (upper row, that is, downstream of two nozzle units interposing the hollow portion 43 in an ejecting direction of the vapor deposition particles). Thus, the total opening areas of the openings 45, is preferably 1/10 or less the opening area of each vapor deposition nozzle 52 (in other words, the opening area of a single vapor deposition nozzle 52).

Furthermore, in the present embodiment as well, the length of the long side of the vapor deposition nozzle 52 (that is, the first side 52a parallel to the Y axis direction) with the long side in the Y axis direction (that is, the opening width d11 of the vapor deposition nozzle 52 in the Y axis direction) is preferably formed longer than the nozzle length d13 of the vapor deposition nozzle 52 in the Z axis direction.

### Advantageous Effects

The effect of the vapor deposition source 10 according to the present embodiment will be specifically described by using a measurement result of the film thickness distribution.

### Measurement Condition of Film Thickness Distribution

Note that, the film thickness distribution was measured similarly as in the first and second embodiments except for forming the vapor deposition nozzle 32 in a square shape in plan view as described above.

That is, in the present embodiment, the film thickness distribution was measured in a condition identical to that of the first and second embodiments except that the length of the first side 32a parallel to the Y axis direction (the opening width d1 in the Y axis direction) and the length of the second side 32b parallel to the X axis direction (the opening width d2 in the X axis direction) both in the vapor deposition nozzle 32 were set to 3 mm. Thus, the opening area of the vapor deposition nozzle 52 according to the present embodiment was 180 mm², identical with that in the first and second embodiments, and the total opening area of the openings 45 was 16 mm². Furthermore, the total opening area of the openings 45 in the hollow portion 43 was 1/10 or less the opening area of each vapor deposition nozzle 52 in the second nozzle unit 51 which is the nozzle unit downstream of the nozzle units interposing the hollow portion 43 in the ejecting direction of the vapor deposition particles (that is, the nozzle unit of the highest stage).

### Measurement Result of Film Thickness Distribution

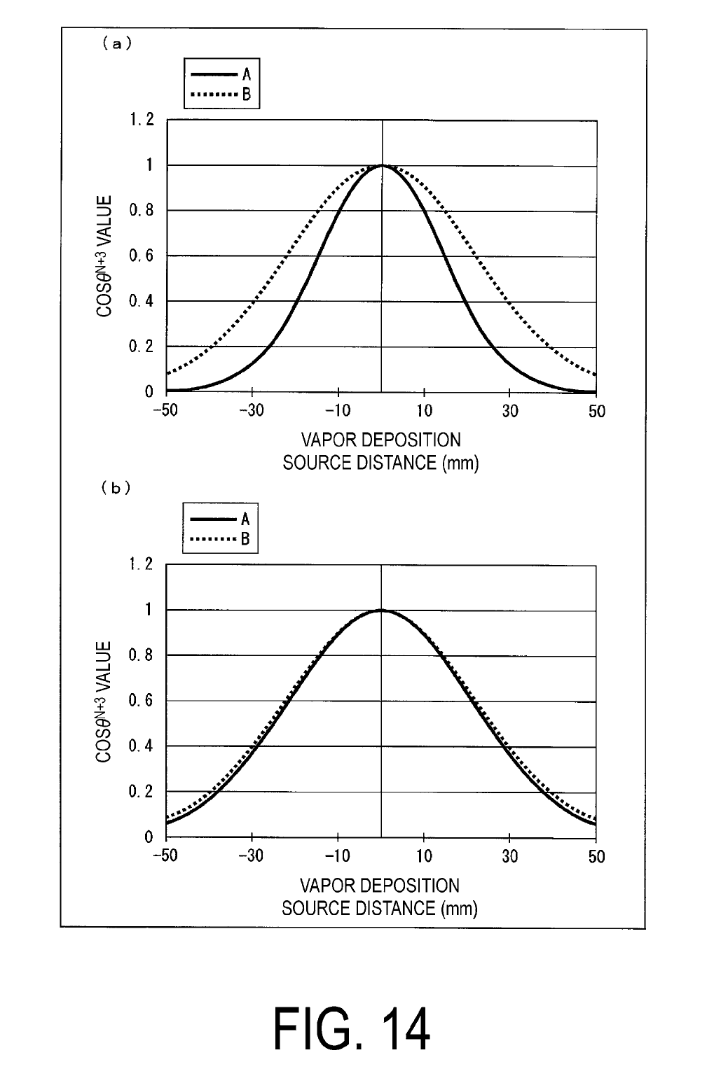

FIGS. 14A and 14B are graphs showing the effect of the vapor deposition source 10 according to the present embodiment, and FIG. 14A shows film thickness distribution of the vapor deposition film 302 in the X axis direction, and FIG. 14B shows film thickness distribution of the vapor deposition film 302 in the Y axis direction.

Similar to the graphs indicated in the bold lines in FIGS. 11A and 11B, the graphs indicated in the bold line in FIGS. 14A and 14B show a film thickness distribution performance (that is, the relation between a cosⁿ⁺³ value and a vapor deposition source distance) of a single vapor deposition nozzle 52 at the cross section in the X axis direction or the Y axis direction of the target film forming substrate 200 in a case that the vapor deposition film 302 is formed on the target film forming substrate 200 by using the vapor deposition source 10 according to the present embodiment. Furthermore, a cosⁿ⁺³ value is a normalized value with the maximum value of the thickness of the formed vapor deposition film 302 on the target film forming substrate 200 defined as 1.

Thus, a graph indicated as the bold line in FIG. 14A is the graph showing the normalized film thickness distribution of the vapor deposition film 302 in the X axis direction formed by the vapor deposition particles 301, which are illustrated as A in FIG. 12, passing the vapor deposition nozzle 52 (the second-stage nozzle) after passing the vapor deposition nozzle 32 (the first-stage nozzle).

Furthermore, a graph indicated as the bold line in FIG. 14B is the graph showing the normalized film thickness distribution of the vapor deposition film 302 in the Y axis direction formed by the vapor deposition particles 301, which are illustrated as A in FIG. 12, passing the vapor deposition nozzle 52 (the second-stage nozzle) after passing the vapor deposition nozzle 32 (the first-stage nozzle).

Furthermore, similar to the graphs indicated as the dotted lines in FIGS. 11A and 11B, the graphs indicated as the dotted lines in FIGS. 14A and 14B show the film thickness distribution performance of a single vapor deposition nozzle 32 at the cross section in the X axis direction or the Y axis direction of the target film forming substrate 200 in a case that the vapor deposition film 302 is formed on the target film forming substrate 200 by using the vapor deposition source 10 to which only the first-stage vapor deposition nozzle is disposed (specifically, only the vapor deposition nozzle 32).

That is, the graph indicated as the dotted line in FIG. 14A is the graph showing the normalized film thickness distribution of the vapor deposition film 302 in the X axis direction formed by the vapor deposition particles 301, which are illustrated as B in FIG. 12, passing the vapor deposition nozzle 32 (the first-stage nozzle).

Furthermore, the graph indicated as the dotted line in FIG. 14B is the graph showing the normalized film thickness distribution of the vapor deposition film 302 in the Y axis direction formed by the vapor deposition particles 301, which are illustrated as B in FIG. 12, passing the vapor deposition nozzle 32 (the first-stage nozzle).

As showed in FIGS. 14A and 14B, in the case that only the vapor deposition nozzle 32 has a square shape in plan view, spread of the vapor deposition particles 301 in the X axis and the Y axis directions is suppressed, and subsequently the vapor deposition particles 301 pass the vapor deposition nozzle 52 having the opening shape longer in the Y axis direction which is the carrying direction of the target film forming substrate 200. As a result, the film thickness distribution is formed in a reduced shape only in the X axis direction comparing with the film thickness distribution of the vapor deposition film 302 formed by the vapor deposition particles 301 passing the square-shaped vapor deposition nozzle 32 (the first-stage nozzle).

As described above, in the case that the vapor deposition nozzle 32 is formed in a square shape in plan view, the vapor deposition particles 301 have a limited moving area and no escape, and thus the film thickness distribution is slightly spread in the X axis direction comparing with the film thickness distribution in the direction of the short side of a rectangular-shaped vapor deposition nozzle in case of using the rectangular-shaped vapor deposition nozzle in plan view. Consequently, the film thickness distribution of the vapor deposition film 302 formed by the vapor deposition source 10 according to the present embodiment has a distribution slightly spread in the X axis direction comparing with the film thickness distribution in the case of using the vapor deposition source 10 according to the first embodiment. However, in the present embodiment as well, scattering of the vapor deposition particles 301 is suppressed (or does not occur) at the outlet of the vapor deposition nozzle 32 and the outlet of the vapor deposition nozzle 52 due to the opening 45 formed the hollow portion 43 between the vapor deposition nozzles 32 and 52. As a result, the sharp film thickness distribution can be realized comparing with the film thickness distribution indicated as the dotted line and the fine line in FIG. 6 and the dotted line in FIG. 14A.

Furthermore, in the present embodiment as well, since the opening 45 is formed in the hollow portion 43 as described above, the film forming is performed in the Y axis direction with the distribution of the vapor deposition particles 301 passing the vapor deposition nozzle 32 maintained as it is, and thus the film thickness distribution by the vapor deposition particles 301 passing the vapor deposition nozzle 32 is maintained after passing the vapor deposition nozzle 52 as well. Thus, according to the present embodiment, as indicated as the bold lines in FIGS. 14A and 14B, the sharp film thickness distribution can be realized both in the X axis direction and the Y axis direction.

Furthermore, according to the present embodiment, the vapor deposition nozzle 32 has a square shape in plan view as described above, and thus, the percentage of the number of the vapor deposition particles 301 ejected into the inlet of the vapor deposition nozzle 52 increases at the outlet of the vapor deposition nozzle 32. As a result, the film forming efficiency can be improved comparing with the case that the opening shape of the vapor deposition nozzle 32 is a rectangular shape in plan view as illustrated in the first and second embodiments.

For example, in a case that the heating temperature of the heating vessel (the melting pot) in the vapor deposition particles generation unit 11, the temperature of the pipe 12, and the temperature of the vapor deposition source main body 13 are constant, the vapor deposition source 10 in which the vapor deposition nozzle 32 has a square shape in plan view as the present embodiment can obtain a film forming rate 20 times greater than the film forming rate obtained by the vapor deposition source 10 as used for measuring the film thickness distribution in the first and second embodiments in which the vapor deposition nozzles 32 and 52 have the rectangular-shaped openings with the ratio between the long side and the short side in each of the vapor deposition nozzles 32 and 52 being 20:1.

### Modified Example

Note that, in the present embodiment, an example has been described as a case that only the vapor deposition nozzle 32 has a square shape in plan view in the vapor deposition source 10 illustrated in the first and second embodiments. However, the present embodiment is not limited to this, the similar result can be obtained in a case that only the vapor deposition nozzle 52 has a square shape in plan view in the vapor deposition source 10 illustrated in the first embodiment.

Note that, in this case, the length of the long side (that is, the first side 32a parallel to the Y axis direction) of the vapor deposition nozzle 32 with the long side in the Y axis direction (that is, the opening width d1 of the vapor deposition nozzle 32 in the Y axis direction) is preferably formed longer than the nozzle length d3 of the vapor deposition nozzle 32 in the Z axis direction. Furthermore, in this case, the total opening area of the openings 45 is preferably made small (for example, in the case of the opening area of the vapor deposition nozzle 52 set to 9 mm², the total opening area of the openings 45 set to 0.84 mm²) such that the total opening area of the openings 45 in the hollow portion 43 is 1/10 or less the opening area of each vapor deposition nozzle 52 of the second nozzle unit 51.

Although the description is omitted, needless to say, the modification similar to that in the first and second embodiments can be applied in the present embodiment. Thus, for example, only the vapor deposition nozzle 52 may be formed in a square shape in plan view in the vapor deposition source 10 illustrated in the second embodiment.

Furthermore, as apparent from the description, the opening shape of the vapor deposition nozzle in any nozzle unit may be a rectangular shape in plan view in a case that three stages or greater of the nozzle unit (the nozzle unit) is provided in the present embodiment.

### Fourth Embodiment

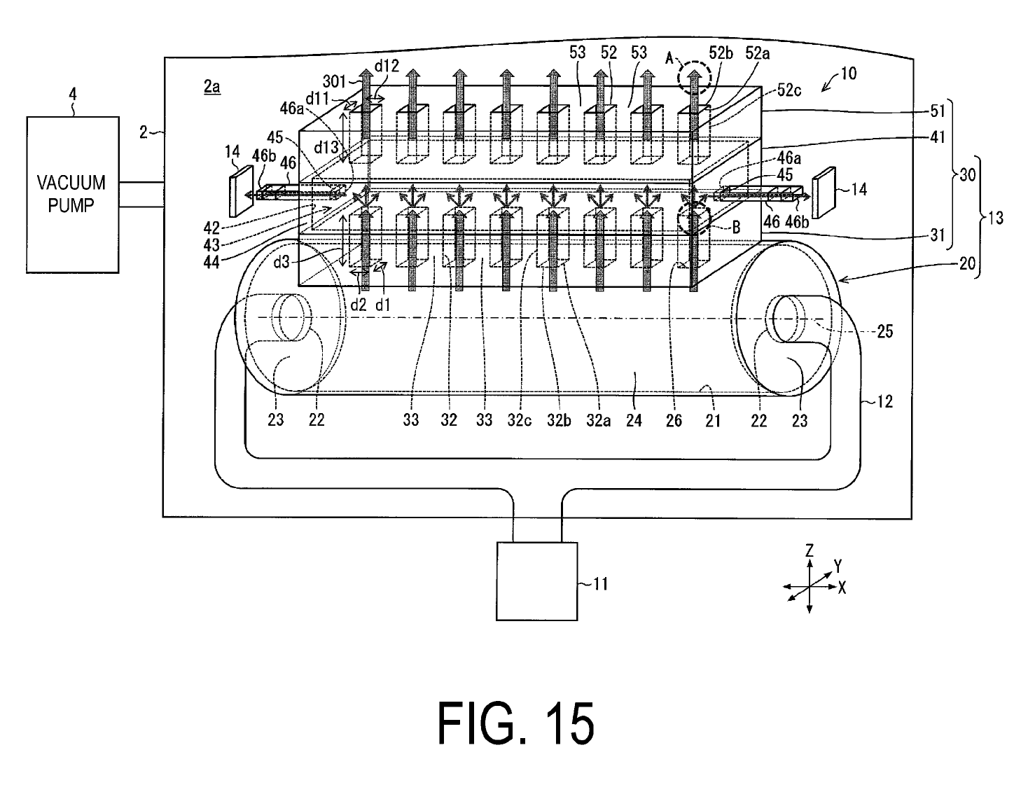

Furthermore, another embodiment in the present invention will be described below mainly on the basis of FIG. 15 to FIG. 17. Here, the description will be for the difference between the present embodiment and the first to third embodiments, and a structural element having a function identical to that of the structural element used in the first to third embodiments is numbered the identical number thereof and the description thereof is omitted.

### Schematic Structure of Vapor Deposition Source 10

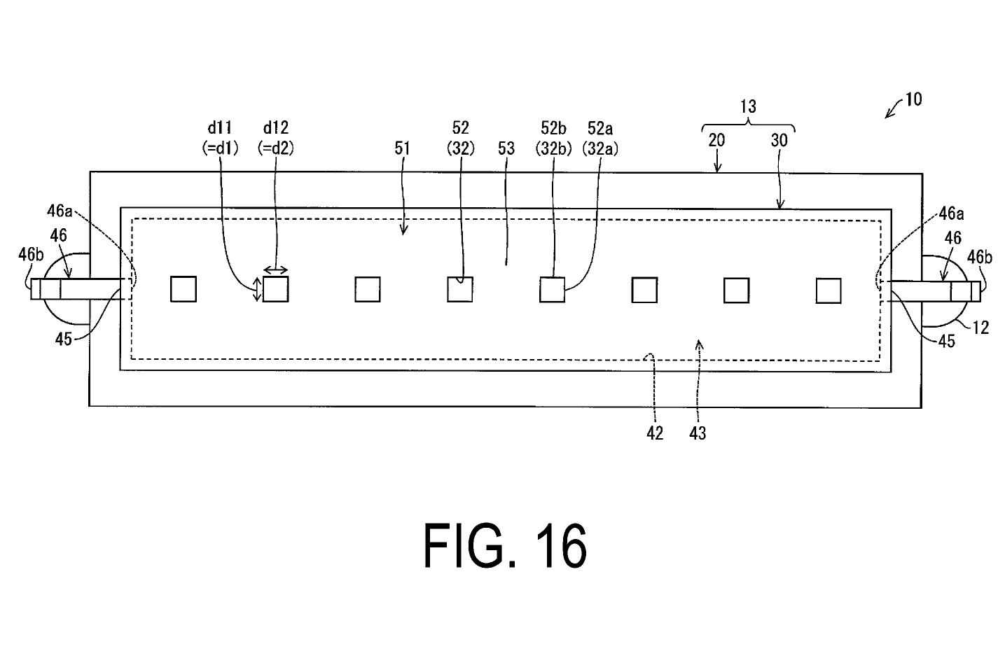

FIG. 15 is a perspective view illustrating a schematic structure of the vapor deposition source 10 according to the present embodiment. FIG. 16 is a plan view illustrating the schematic structure of the vapor deposition source 10 illustrated in FIG. 15. FIG. 16 illustrates that the vapor deposition nozzle 32 and the vapor deposition nozzle 52 fully overlap each other in plan view. Note that, in FIG. 15 and FIG. 16 as well, the numbers of the vapor deposition nozzles 32 and 52, and other descriptions are partially omitted, and each structural element shape is simplified for the sake of convenience of illustration.

As illustrated in FIG. 15 and FIG. 16, the vapor deposition device 100 according to the present embodiment is identical with the vapor deposition device 100 according to the first to third embodiments except that the opening shapes of the vapor deposition nozzles 32 and 52 are both in a square shape in plan view in the vapor deposition source 10 illustrated in the first to third embodiments. Consequently, in the present embodiment as well, an illustration of the whole vapor deposition device 100 is omitted.

Note that, in the present embodiment as well, the delivery port 26, for example, is identical with the vapor deposition nozzle 32 in shape in plan view, and is connected to the vapor deposition nozzle 32 by connecting an opening end of the delivery port 26 and the opening end of the vapor deposition nozzle 32 each other.

### Advantageous Effects

The effect of the vapor deposition source 10 according to the present embodiment will be specifically described by using a measurement result of the film thickness distribution.

### Measurement Condition of Film Thickness Distribution

Note that, the film thickness distribution was measured similarly as in the first to third embodiments except for forming the vapor deposition nozzles 32 and 52 in a square shape in plan view as described above.

That is, in the present embodiment, the film thickness distribution was measured in a condition identical to that in the first to third embodiments except that the lengths of the first sides 32a and 52a parallel to the Y axis direction of the vapor deposition nozzles 32 and 52 (the opening widths d1 and d11 in the Y axis direction) and the lengths of the second sides 32b and 52b parallel to the X axis direction of the vapor deposition nozzles 32 and 52 (the opening widths d2 and d12 in the X axis direction) were each set to 3 mm to set the opening area of each vapor deposition nozzles 32 and 52 to 9 mm², and the size of the opening 45 was set to 0.6 mm×0.7 mm (the length of the side parallel to the Z axis direction x the length of the side parallel to the Y axis direction) so that the opening area of each opening 45 was set to 0.42 mm², the total opening area of the openings 45 was set to 0.84 mm². As described above, in the present embodiment as well, the total opening area of the openings 45 in the hollow portion 43 was 1/10 or less the opening area of each vapor deposition nozzle 52 in the second nozzle unit 51 (9 mm²) which is the nozzle unit downstream of the nozzle units interposing the hollow portion 43 in the ejecting direction of the vapor deposition particles (that is, the nozzle unit in the highest stage).

### Measurement Result of Film Thickness Distribution

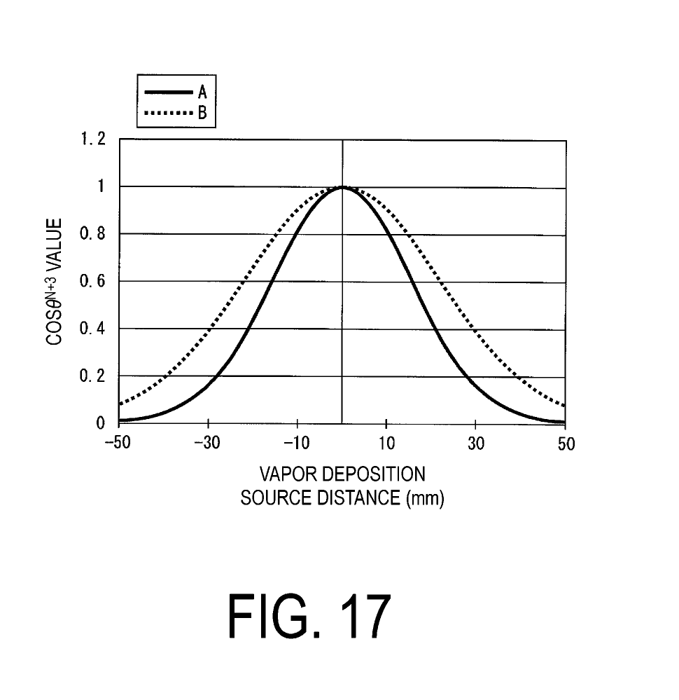

FIG. 17 is a graph showing effect of the vapor deposition source 10 according to the present embodiment. Note that, in the present embodiment, since the film thickness distributions of the vapor deposition film 302 in the X axis and the Y axis directions are identical in shape, the film thickness distributions of the vapor deposition film 302 in the X axis direction and the Y axis direction are both illustrated in FIG. 17.

A graph indicated as the bold line in FIG. 17 shows a film thickness distribution performance (that is, the relation between a cosⁿ⁺³ value and a vapor deposition source distance) of a single vapor deposition nozzle 52 at the cross sections in the X axis direction and the Y axis direction of the target film forming substrate 200 in a case that the vapor deposition film 302 is formed on the target film forming substrate 200 by using the vapor deposition source 10 according to the present embodiment. Furthermore, a cosⁿ⁺³ value is a normalized value with the maximum value of the thickness of the formed vapor deposition film 302 on the target film forming substrate 200 defined as 1.

Thus, a graph indicated as the bold line in FIG. 17 is the graph showing the normalized film thickness distribution of the vapor deposition film 302 in the X axis direction and the Y axis direction formed by the vapor deposition particles 301, which are illustrated as A in FIG. 15, passing the vapor deposition nozzle 52 (the second-stage nozzle) after passing the vapor deposition nozzle 32 (the first-stage nozzle).

Furthermore, a graph indicated as the dotted line in FIG. 17 shows the film thickness distribution performance of a single vapor deposition nozzle 32 at the cross section in the X axis direction and the Y axis direction of the target film forming substrate 200 in a case that the vapor deposition film 302 is formed on the target film forming substrate 200 by using the vapor deposition source 10 to which only the first-stage vapor deposition nozzle is provided (specifically, only the vapor deposition nozzle 32).

That is, the graph indicated as the dotted line in FIG. 17 is the graph showing the normalized film thickness distribution of the vapor deposition film 302 in the X axis direction and the Y axis direction formed by the vapor deposition particles 301, which are illustrated as B in FIG. 15, passing the vapor deposition nozzle 32 (the first-stage nozzle).

As showed in FIG. 17, the film thickness distribution is formed in a reduced shape both in the X axis direction and the Y axis direction according to the present embodiment.

According to the structure described above, in a case of the scan vapor deposition, although the takt time becomes slow compared with the case that the vapor deposition nozzle section including the vapor deposition nozzle with a rectangular-shaped opening shape in plan view is provided, the shapes of the film thickness distribution is reduced twice in the X axis direction and the Y axis direction. Thus, the directivity is improved comparing with the case that the vapor deposition nozzles 32 and 52 are formed in a rectangular shape in plan view, and as a result, spread of the film thickness distribution can be suppressed.

### Modified Example

Although the description is omitted, needless to say, the modification similar to that in the first to third embodiments is applicable in the present embodiment.

Especially, in the present embodiment as well, although an example is described as a case that the vapor deposition particles ejecting unit 30 includes the first nozzle unit 31 and the second nozzle unit 51 as a plurality of stages of nozzle sections (the vapor deposition nozzle section), the plurality of stages of nozzle sections may include three stages or more of nozzle sections (the nozzle unit).

### Fifth Embodiment

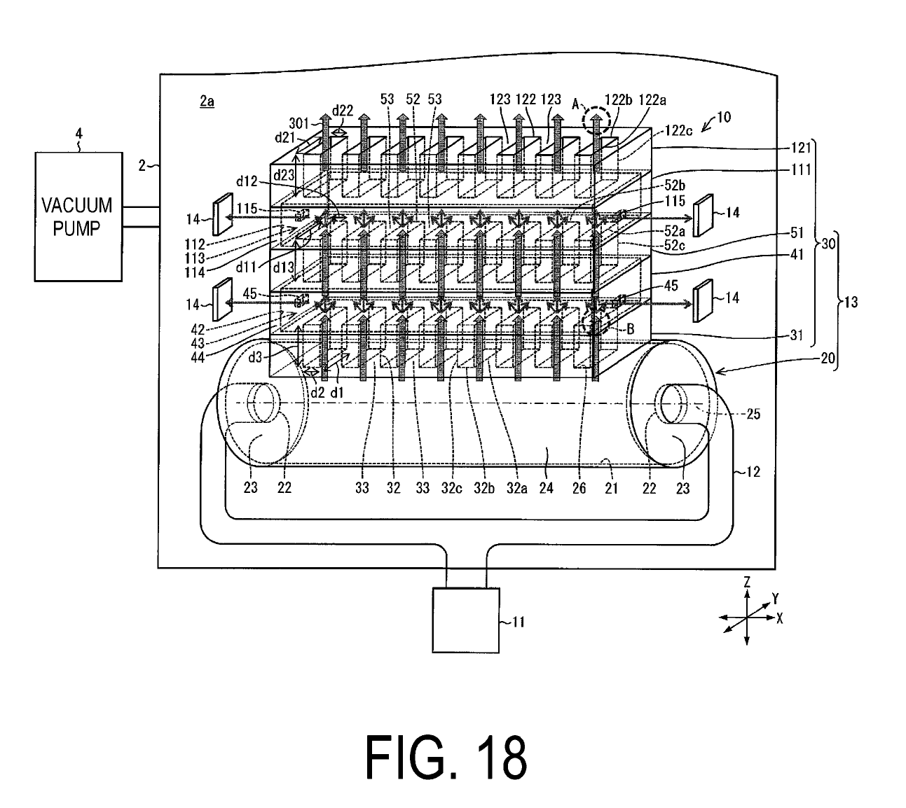

Furthermore, another embodiment in the present invention will be described below mainly on the basis of FIG. 18 to FIG. 20. Here, the description will be described for the difference between the present embodiment and the first to fourth embodiments, and a structural element having a function identical to that of the structural element used in the first to fourth embodiments is numbered the identical number thereof and the description thereof is omitted.

### Schematic Structure of Vapor Deposition Source 10

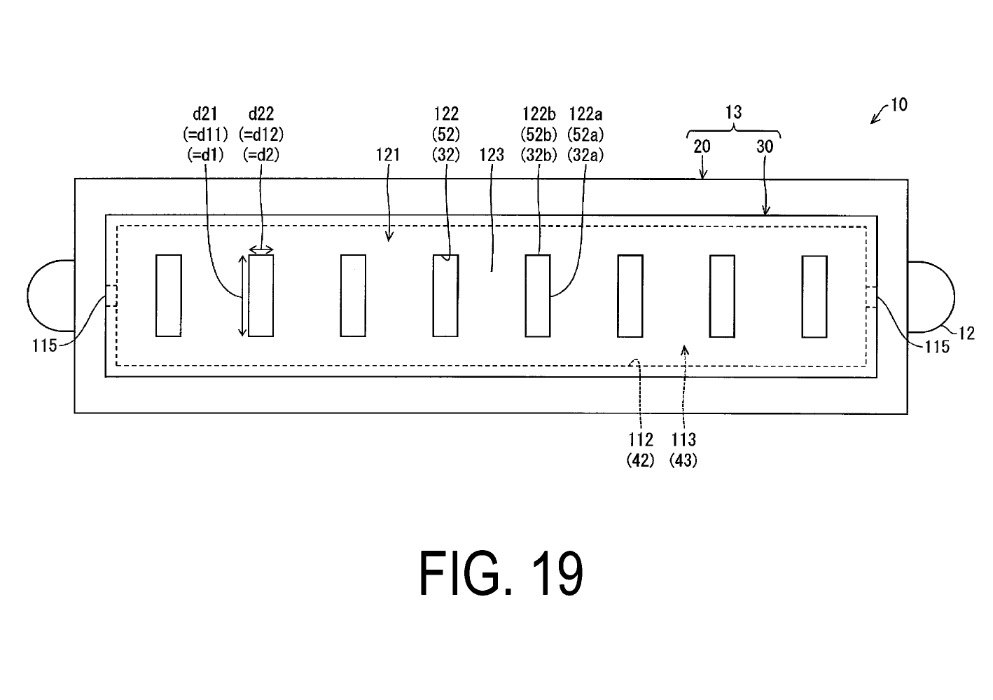

FIG. 18 is a perspective view illustrating a schematic structure of the vapor deposition source 10 according to the present embodiment. FIG. 19 is a plan view illustrating the schematic structure of the vapor deposition source 10 illustrated in FIG. 18.

The vapor deposition device 100 according to the present embodiment is identical with, for example, the vapor deposition device 100 according to the first embodiment except that the nozzle unit (the nozzle unit) of the vapor deposition particles ejecting unit 30 includes a three-stages structure and two of the hollow portions which are formed between each stage of the nozzle unit and connected to the vacuum chamber space 2a not via the vapor deposition nozzle of each stage of the nozzle unit. Consequently, in the present embodiment as well, an illustration of the whole vapor deposition device 100 is omitted.

That is, in the vapor deposition device 100 according to the present embodiment, as illustrated in FIG. 18 and FIG. 19, the vapor deposition particles ejecting unit 30 further includes a third nozzle unit 121 (third vapor deposition nozzle section) at the highest stage as a nozzle unit and a pressure adjusting unit 111 forming a hollow portion 113 between the second nozzle unit 51 and the third nozzle unit 121.

Consequently, in the vapor deposition particles ejecting unit 30, a vapor deposition nozzle 122 in the third nozzle unit 121 is used as the ejection port ejecting the vapor deposition particles 301 outside of the vapor deposition source 10 in place of the vapor deposition nozzle 52 in the second nozzle unit 51.

Note that, in FIG. 18 and FIG. 19, the numbers or the like of the vapor deposition nozzles 32, 52 and 122, and other descriptions are partially omitted, and each structural element shape is simplified for the sake of convenience of illustration.

The pressure adjusting unit 111 and the third nozzle unit 121 illustrated in FIG. 18 are block-shaped units similar to the first nozzle unit 31, the pressure adjusting unit 41, the second nozzle unit 51, the pressure adjusting unit 111, and the third nozzle unit 121, and the first nozzle unit 31, the pressure adjusting unit 41, the second nozzle unit 51, the pressure adjusting unit 111, and the third nozzle unit 121 are stacked in this order from the vapor deposition particles diffusion unit 20 side and integrated.

The third nozzle unit 121 has a structure similar to that of the first nozzle unit 31 and the second nozzle unit 51. Thus, the third nozzle unit 121 is a plate member with the XY plane as the main surface and, for example, has a rectangular shape in plan view with the longer axis in the X axis direction.

Consequently, the third nozzle unit 121 includes the plurality of vapor deposition nozzles 122 (the nozzle opening, the third vapor deposition nozzle; hereinafter, referred to as “the third-stage nozzle” in some cases). The plurality of vapor deposition nozzles 122 are each the nozzle-shaped opening penetrating in the up-down direction and are disposed along the X axis direction at a constant pitch.

Furthermore, similar to the vapor deposition nozzles 32 and 52, each vapor deposition nozzle 122 has a rectangular shape, in plan view, with longer axis direction in the Y axis direction. That is, each vapor deposition nozzle 122, in plan view, is formed in a rectangular shape with a first side 122a parallel to the Y axis direction as the long side, and a second side 122b parallel to the X axis direction as the short side.

The vapor deposition nozzles 122 are disposed such that the long sides thereof are parallel to the Y axis and face each other in plan view. Consequently, a plurality of regulation plates 123 (the non-opening) forming nozzle walls of the vapor deposition nozzles 122 as shields are arranged in the X axis direction at a constant pitch between the vapor deposition nozzles 122 adjacent each other in the X axis direction.

Furthermore, similar to the vapor deposition nozzles 32 and 52, each vapor deposition nozzle 122 is formed, in plan view, such that the length of the first side 122a parallel to the Y axis direction (the opening width d21 in the Y axis direction) is longer than the length of a third side 122c parallel to the Z axis direction of each vapor deposition nozzle 122 (depth, a nozzle length d23). As described above, the vapor deposition nozzles 32, 52, and 122, especially the vapor deposition nozzles 122 at the highest stage (the final stage), in plan view, each having the opening shape longer in the Y axis direction, for example, make it possible to speed up the takt time similar to the first embodiment.

The delivery port 26, the vapor deposition nozzle 32, the vapor deposition nozzle 52, and the vapor deposition nozzle 122 have, in plan view, an identical shape and are provided while superimposed with each other such that central axes (opening center) thereof match.

Furthermore, the pressure adjusting unit 111 has a structure similar to that of the pressure adjusting unit 41. The pressure adjusting unit 111 is a frame-shaped block member similar to the pressure adjusting unit 41. While the pressure adjusting unit 41 includes the space forming opening section 42 forming the hollow portion 43 connecting the vapor deposition nozzle 32 and the vapor deposition nozzle 52, the pressure adjusting unit 111 includes a space forming opening section 112 forming the hollow portion 113 connecting the vapor deposition nozzle 52 and the vapor deposition nozzle 122.

An opening 115 as an exhaust port (the ventilation port) is formed in a part of the side wall 114 which is the outer wall of the pressure adjusting unit 111. With the configuration, the part of the pressure adjusting unit 111 is opened facing the outside of the vapor deposition source 10 (that is, the vacuum chamber space 2a). Consequently, the hollow portion 113 in the pressure adjusting unit 111 is partially connected to the vacuum chamber space 2a to form a closed space partially opened to the vacuum chamber space 2a.

That is, the hollow portion 113 has a structure including the second nozzle unit 51 and the third nozzle unit 121 as the bottom wall and the top wall, respectively, and surrounded on four sides by the side wall 114 of the pressure adjusting unit 111. In addition, the hollow portion 113 connects to the outside of the vapor deposition source 10, in other words, the vacuum chamber space 2a,only through the vapor deposition nozzle 122 and the opening 115. Consequently, the opening 115 functions as a pressure adjusting section for relieving pressure in the closed hollow portion 113.

The opening 115 can be similarly designed with the opening 45. Thus, the opening 115 is preferably formed to keep inner pressure in the hollow portion 113 at a constant pressure, and may be formed at least one, or preferably at least one pair of set.

Furthermore, the openings 115 are more preferably formed in the side walls 114 (the side wall surfaces of the short sides) which are both ends of the pressure adjusting unit 111 in the X axis direction, at positions facing each other and interposing the center point of the pressure adjusting unit 111 (that is, the center point of the hollow portion 113).

Note that, an example is illustrated in FIG. 18 and FIG. 19 as a case that each of the openings 45 and 115 is formed to directly face the vacuum chamber 2 so as to be directly connected to the vacuum chamber space 2a.

However, the present embodiment is not limited to this, and each of the openings 45 and 115, as described in the first embodiment, may be connected to the vacuum chamber space 2a through a pressure adjusting device such as the pressure adjusting valve 46 (refer to FIG. 1 to FIG. 3).

As described above, disposing the pressure adjusting valves 46 in the openings 45 and 115 for adjusting the degree of opening (the opening area) of the openings 45 and 115 enables the film forming rate to be adjusted and makes it possible to prevent excess emission (discharge) of the vapor deposition particles 301 from the opening 45, as described in the first embodiment as an example in which the pressure adjusting valve 46 is disposed in the opening 45.

In this case, in the present embodiment, the vapor deposition particles 301 are ejected from the vapor deposition source 10 with all the pressure adjusting valves 46 being closed to check the film forming rate in the step of confirming a film forming rate. Subsequently, in the step of adjusting a film forming rate, first, the pressure adjusting valve 46 is opened to reduce pressure in the hollow portion 43 lower than pressure in the vapor deposition nozzle 32 in the first nozzle unit 31 which is the nozzle unit upstream of the nozzle units interposing the hollow portion 43 in an ejecting direction of the vapor deposition particles, and reduce pressure in the hollow portion 113 lower than pressure in the vapor deposition nozzle 52 in the second nozzle unit 51 which is the nozzle unit upstream of the nozzle units interposing the hollow portion 113 in the ejecting direction of the vapor deposition particles. Subsequently, while the vapor deposition film 302 formed on the target film forming substrate 200 is checked for the film thickness distribution, the vapor deposition particles 301 are ejected from the vapor deposition source 10 to adjust the film forming rate.

The vapor deposition particles 301 discharged from the openings 45 and 115 or from the pressure adjusting valve 46 to the outside of the vapor deposition source 10 are retrieved by the vapor deposition particles retrieving member 14, in the present embodiment as well.

Furthermore, the vapor deposition source 10 is preferably heated to the temperature higher than the temperature at which the vapor deposition material gasifies in the present embodiment as well, similar to the first embodiment.

Consequently, the pressure adjusting unit 111 and the third nozzle unit 121, similar to the pipe 12, the vapor deposition particles diffusion unit 20, the first nozzle unit 31, the pressure adjusting unit 41, and the second nozzle unit 51, are all preferably heated to a higher temperature by 50° C. (for example, 400° C.) than the temperature at which the vapor deposition material gasifies by the heating member (heater, not illustrated).

In the present embodiment, the vapor deposition particles 301 supplied from the vapor deposition particles diffusion unit 20 to the vapor deposition particles ejecting unit 30 except for the vapor deposition particles 301 discharged outside through the openings 45 and 115, are injected through the vapor deposition nozzle 32 and the hollow portion 43 into the vapor deposition nozzle 52, and pass from the vapor deposition nozzle 52 through the hollow portion 113 to the vapor deposition nozzle 122, and thus ejected from the vapor deposition source 10.

In the vapor deposition particles ejecting unit 30, the physical nozzle lengths d3, d13 and d23 of each of the vapor deposition nozzles 32, 52 and 122 in the direction of the normal line (that is, the Z axis direction) of the first nozzle unit 31, the second nozzle unit 51, and the third nozzle unit 121 improve linearity of the vapor deposition particles 301.

In this case, in the vapor deposition source 10, the hollow portion 43 is formed between the vapor deposition nozzle 32 and the vapor deposition nozzle 52, and the hollow portion 113 is formed between the vapor deposition nozzle 52 and the vapor deposition nozzle 122, and the openings 45 and 115 are formed as connecting ports connecting the hollow portion 43 and 113 and the vacuum chamber space 2a,that is vacuum space. This allows pressure in the hollow portions 43 and 113 to naturally reduce.

As a result, pressure in the vapor deposition particles ejecting unit 30 becomes higher as being closer to the vapor deposition particles generation section (the vapor deposition particles diffusion unit 20 side in the vapor deposition source main body 13) that is the inlet for the vapor deposition particles 301, and becomes lower as being closer to the outlet (ejection ports) to the outside (that is, the vacuum chamber space 2a) for the vapor deposition particles 301. Thus, according to the present embodiment, a physical phenomenon led by the physical structure of the vapor deposition particles ejecting unit 30 always results in pressure in the vapor deposition particles diffusion unit 20 and pressure in the vapor deposition nozzle 32>pressure in the hollow portion 43>pressure in the vapor deposition nozzle 52>pressure in the hollow portion 113>pressure in the vapor deposition nozzle 122>pressure in the vacuum chamber space 2a. This relationship is always maintained.

This causes pressure in the hollow portion 43 to be lower than pressure in the vapor deposition nozzle 32 which is located on the inlet side for the vapor deposition particles 301, and to be higher than pressure in the vapor deposition nozzle 52 which is located on the outlet side for the vapor deposition particles 301. As a result, scattering of the vapor deposition particles 301 at the outlet to the vapor deposition nozzle 52 is suppressed.

Furthermore, pressure in the hollow portion 113 is lower than pressure in the vapor deposition nozzle 52 which is located on the inlet side for the vapor deposition particles 301, and is higher than pressure in the vapor deposition nozzle 122 which is located on the outlet side for the vapor deposition particles 301. As a result, scattering of the vapor deposition particles 301 at the outlet for the vapor deposition particles 301 to the vapor deposition nozzle 122 is suppressed.

As a result, according to the vapor deposition source 10, the vapor deposition particles 301 are prevented from scattering at the final outlet (ejection port) for the vapor deposition particles 301, and thus, waste of the vapor deposition particles 301 reduces. This allows the number of vapor deposition particles 301 contributing to the film forming in the predetermined direction to increase.

Note that, in the present embodiment as well, a pressure in the vapor deposition particles diffusion unit 20 is preferably a few Pa, and pressures in the hollow portions 43 and 113 are preferably from 1×10 ⁻¹ Pa to 1×10 ⁻³ Pa, and a pressure in the vacuum chamber space 2a is preferably 1×10 ⁻³ Pa or less (here, pressure in the hollow portion 43>pressure in the hollow portion 113>pressure in the vacuum chamber space 2a).

Furthermore, pressure difference between the outlet and the inlet of the vapor deposition nozzle 32 preferably ranges from 10 to 1000 times, and pressure difference between the outlet and the inlet of the second-stage and subsequent vapor deposition nozzles, for example, pressure difference between the outlet and the inlet of the vapor deposition nozzle 52 and pressure difference between the outlet and the inlet of the vapor deposition nozzle 122 preferably range from 10 to 100 times. Note that, pressure in the vapor deposition particles ejecting unit 30 as described above is higher as being closer to the upstream side in the ejecting direction of the vapor deposition particles and is lower as being closer to the downstream side in the ejecting direction of the vapor deposition particles, and the more the number of stages of the nozzle unit is, the less pressure difference between pressure at the outlet (ejection port) to the vacuum chamber space 2a for the vapor deposition particles 301 and pressure in the vacuum chamber space 2a. Consequently, pressure difference between the outlet and the inlet of the vapor deposition nozzle in the second-stage and the subsequent vapor deposition nozzle becomes smaller as the vapor deposition nozzle being closer to the downstream side in the ejecting direction of the vapor deposition particles.

Furthermore, the opening 115 may be formed in a part of the side wall 114 of the pressure adjusting unit 111, and can be designed similar to the opening 45 as described above.

As described in the first embodiment, the total opening area of the openings which each are a connecting port to the vacuum chamber space 2a and are formed at the hollow portion between respective nozzle units is preferably sufficiently smaller than the opening area of each of the vapor deposition nozzles in the nozzle unit located at the subsequent stage of the hollow portion (that is, downstream of the nozzle units interposing the hollow portion in the ejecting direction of the vapor deposition particles), and is preferably 1/10 or less the opening area of the vapor deposition nozzle. Note that, as described above, even if a plurality of hollow portions exist, the nozzle units interposing the hollow portion are referred to as the two nozzle units interposing the hollow portion, in other words, the nozzle units that directly interpose each hollow portion.

Consequently, in the present embodiment, the sum of the opening areas (total opening area) of the openings 45 is preferably sufficiently smaller than the opening area of each vapor deposition nozzle 52, and is preferably 1/10 or less the opening area of each vapor deposition nozzle 52 (that is, a single vapor deposition nozzle 52).

Furthermore, the sum of opening areas (total opening area) of the openings 115 is preferably sufficiently smaller than the opening area of each vapor deposition nozzle 122, and is preferably 1/10 or less the opening area of each vapor deposition nozzle 122 (that is, a single vapor deposition nozzle 122).

Consequently, although the identical size and number of the openings 45 and 115 may be formed within a range satisfying the condition, the opening 115 larger in size than the opening 45, or the openings 115 larger in number than the openings 45 may be formed within the range, and this opening 115 may located near the ejection port (particle discharging port) of the vapor deposition particles 301 to the outside (that is, downstream side in the ejecting direction of the vapor deposition particles).

Following describes the reason. The vapor deposition particles ejecting unit 30 needs to be formed such that pressure in the hollow portion at the downstream side in the ejecting direction of the vapor deposition particles is lower than pressure in the hollow portion at the upstream side in the ejecting direction of the vapor deposition particles. In addition, the flow of the vapor deposition particles 301 is collimated as being closer to the downstream side in the ejecting direction of the vapor deposition particles due to the vapor deposition nozzle of each stage. As a result, the discharging (leaking) rate of the vapor deposition particles 301 from the opening formed in the hollow portion during evacuation becomes smaller as the hollow portion being closer to the downstream side in the ejecting direction of the vapor deposition particles.

### Advantageous Effects

The effect of the vapor deposition source 10 according to the present embodiment will be specifically described by using a measurement result of the film thickness distribution.

### Measurement Condition of Film Thickness Distribution

Note that, as described above, the film thickness distribution was measured in a condition similar to that of the first embodiment except that the third nozzle unit 121 having a structure identical to that of the first nozzle unit 31 and the second nozzle unit 51 was disposed at the highest stage of the vapor deposition particles ejecting unit 30, and the pressure adjusting unit 111 having a structure identical to that of the pressure adjusting unit 41 was disposed between the second nozzle unit 51 and the third nozzle unit 121.

Thus, in the vapor deposition source 10 used for the measurement in the present embodiment, the lengths of the first side 32a,52a and 122a parallel to the Y axis direction of the vapor deposition nozzles 32, 52 and 122 (the opening widths dl, d11 and d21 in the Y axis direction) were each set to 60 mm. Furthermore, the lengths of the second sides 32b,52b and 122b parallel to the X axis direction of the vapor deposition nozzles 32, 52 and 122 (the opening widths d2, d12 and d22 in the X axis direction) were each set to 3 mm. Consequently, the opening area of each of the vapor deposition nozzles 32, 52 and 122 was set to 180 mm². The length of the third sides 32c,52c and 122c parallel to the Z axis direction of the vapor deposition nozzles 32, 52 and 122 (depth, the nozzle length d3, d13 and d23) were each set to 60 mm.

Furthermore, in the hollow portions 43 and 113, the height in the Z axis direction (that is, the distance between the vapor deposition nozzles 32 and 52 and the distance between the vapor deposition nozzles 52 and 122) were each set to 30 mm, the lengths in the X axis direction were each set to 180 mm and the lengths in the Y axis direction were each set to 100 mm. Furthermore, the size of the opening 45 was set to 2 mm×4 mm (the length of the side parallel to the Z axis direction x the length of the side parallel to the Y axis direction), and the size of the opening 115 was set to 2 mm×4 mm (the length of the side parallel to the Z axis direction x the length of the side parallel to the Y axis direction), and thus the total opening area of the openings 45 (that is, the sum of the opening areas of the openings 45) was set to 16 mm², and the total opening area of the openings 115 (that is, the sum of the opening areas of the openings 115) was set to 16 mm². As described, in the present embodiment as well, the total opening area of the openings 45 in the hollow portion 43 was 1/10 or less the opening area of each vapor deposition nozzle 52 in the second nozzle unit 51 (180 mm²) which is the nozzle unit downstream of the nozzle unites interposing the hollow portion 43 in the ejecting direction of the vapor deposition particles. Furthermore, the total opening area of the openings 115 in the hollow portion 113 was set to 1/10 or less the opening area of each vapor deposition nozzle 122 (180 mm²) in the third nozzle unit 121 which is the nozzle unit downstream of the nozzle units interposing the hollow portion 113 in the ejecting direction of the vapor deposition particles.

### Measurement Result of Film Thickness Distribution

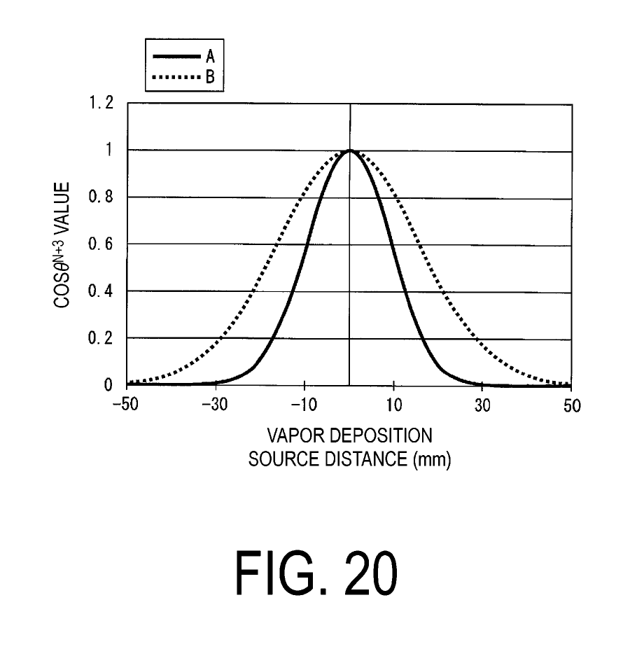

FIG. 20 is a graph showing effect of the vapor deposition source 10 according to the present embodiment.

In FIG. 20, a graph indicated as a bold line shows a film thickness distribution performance (that is, a relation between a cosⁿ⁺³ value and a vapor deposition source distance) of a single vapor deposition nozzle 52 at the cross section in the X axis direction of the target film forming substrate 200 in a case that the vapor deposition film 302 is formed on the target film forming substrate 200 by using the vapor deposition source 10 according to the present embodiment. Furthermore, a cosⁿ⁺³ value is a normalized value with the maximum value of the thickness of the formed vapor deposition film 302 in the target film forming substrate 200 defined as 1.

Furthermore, the graph indicated as the bold line in FIG. 20 is the graph showing the normalized film thickness distribution of the vapor deposition film 302 in the X axis direction formed by the vapor deposition particles 301, which are illustrated as A in FIG. 18, ejected from the vapor deposition source 10 to the outside. Note that, in the present embodiment, the vapor deposition particles 301 ejected from the vapor deposition source 10 to the outside are different from the vapor deposition particles 301 in the first to fourth embodiments in that the vapor deposition particles 301 have passed the vapor deposition nozzle 122 (the third-stage nozzle) after passing the vapor deposition nozzle 32 (the first-stage nozzle), and the vapor deposition nozzle 52 (the second-stage nozzle).

Furthermore, a graph indicated as a dotted line in FIG. 20 shows the film thickness distribution performance of a single vapor deposition nozzle 32 at the cross section in the X axis direction of the target film forming substrate 200 in the case that the vapor deposition film 302 is formed on the target film forming substrate 200 by using the vapor deposition source 10 to which only the first-stage vapor deposition nozzle is provided (specifically, only the vapor deposition nozzle 32).

That is, the graph indicated as the dotted line in FIG. 20 is the graph showing the normalized film thickness distribution of the vapor deposition film 302 in the X axis direction formed by the vapor deposition particles 301, which are illustrated as B in FIG. 18, passing the vapor deposition nozzle 32 (the first-stage nozzle).

According to the present embodiment, the number of stages of the nozzle unit is increased as compared with that in the first embodiment, and thus, pressure difference between a part of the vapor deposition nozzle 122 which serves as the outlet (the ejection port) for the vapor deposition particles 301 to the outside and the vacuum chamber space 2a at the final stage where the vapor deposition particles 301 are ejected in the vapor deposition particles ejecting unit 30 can be decreased. This allows the vapor deposition particles 301 to be prevented from scattering. That is, with parallelism of the vapor deposition particles 301 increased, pressure at the outlet portion (the ejection ports) (near outlet) for the vapor deposition particles 301 to the outside in the vapor deposition source 10 can be closer to pressure in the vacuum chamber space 2a.

Consequently, according to the present embodiment, as illustrated in FIG. 20, the sharper film thickness distribution in the X axis direction can be obtained as compared with the film thickness distribution indicated as the bold line in FIG. 6 in the first embodiment.

Note that, in the present embodiment as well, since each of the vapor deposition nozzles 32, 52 and 122 has a rectangular shape longer in the Y axis direction, in plan view, the film thickness distribution of the vapor deposition film 302 formed by the vapor deposition particles 301 ejected from the vapor deposition nozzle 122 is broad in the long side direction, as same as the first embodiment. However, similarly to the first embodiment, since the Y axis direction is the film forming direction, the vapor deposition particles 301 scattering in the Y axis direction contribute to the film forming. Consequently, broadness of the film thickness distribution in the Y axis direction is not important issue as compared with broadness of the film thickness distribution in the X axis direction.

The number of stages of the nozzle unit is increased in the vapor deposition source 10 in the second to fourth embodiments, as in the present embodiment. As a result, with parallelism of the vapor deposition particles 301 increased, pressure at the outlet portion (the ejection ports) (near outlet) for the vapor deposition particles 301 to the outside in the vapor deposition source 10 can be closer to pressure in the vacuum chamber space 2a in the second to fourth embodiments. Thus, the vapor deposition source 10 in the second to fourth embodiments can be used for obtaining the sharper film thickness distribution in the Y axis direction.

Note that, although difference from the vapor deposition device 100 illustrated in FIG. 1 to FIG. 3 in the first embodiment has been described as an example in the present embodiment, needless to say, the modification similar to the first to fourth embodiments is applicable to the present embodiment as well.

### Conclusion

The vapor deposition source 10 according to a first aspect in the present invention includes a vapor deposition particles generation section (the vapor deposition particles generation unit 11) configured to heat a vapor deposition material and generate vapor deposition particles 301 in a gaseous state, and a vapor deposition particles ejecting section (the vapor deposition particles ejecting unit 30) configured to eject the vapor deposition particles 301 generated in the vapor deposition particles generation section. The vapor deposition particles ejecting section is at least disposed in the vacuum chamber 2 (the vacuum chamber space 2a), and includes a plurality of stages of vapor deposition nozzle sections including at least one vapor deposition nozzle (for example, the vapor deposition nozzles 32, 52 and 122) and stacked while separated from each other in a vertical direction, and at least one hollow portion (for example, the hollow portion 43, and the hollow portion 113) formed between the at least one vapor deposition nozzle and the at least one vapor deposition nozzle of respective stages of the plurality of stages of vapor deposition nozzle sections. The at least one hollow portion is surrounded on four sides by an outer wall (the side wall 44 and the side wall 114) including at least one opening (for example, the opening 45 and the opening 115) formed in the outer wall and connecting the at least one hollow portion and an inner space of the vacuum chamber 2 (the vacuum chamber space 2a).

According to the structure, the opening portion connecting the hollow portion and a space in the vacuum chamber 2 (that is, the vacuum chamber space 2a), that is a vacuum space (reduced pressure space), is formed in the hollow portion surrounded on four sides by the outer walls and formed between the vapor deposition nozzles of respective stages. This allows pressure in the hollow portion to naturally reduce.

As a result, pressure in the vapor deposition particles ejecting section is high at near the inlet (near the vapor deposition particles generation section) for the vapor deposition particles 301, and low at near the outlet (the ejection port) for the vapor deposition particles 301 to the outside (that is, the vacuum chamber space 2a).

Consequently, according to the above described structure, pressure difference between the vacuum chamber space 2a and the outlet of the vapor deposition nozzle in the vapor deposition nozzle section located downstream in an ejecting direction of the vapor deposition particles can be reduced, and thus scattering of the vapor deposition particles 301 at the outlet can be suppressed. As a result, the vapor deposition particles 301 can be efficiently ejected in the desired ejecting direction.

Thus, by using the vapor deposition source 10, directivity of the vapor deposition particles 301 can be improved and thus the material utilization efficiency can be improved as compared with that in devices of the related art.

In the vapor deposition source 10 according to a second aspect in the present invention, in the first aspect, vapor deposition nozzles of each stages of the plurality of stages of vapor deposition nozzle sections may each have a rectangular shape with a pair of long sides and a pair of short sides in plan view and may be disposed while superimposed with each other with directions of long sides of the vapor deposition nozzles matching and directions of short sides of the vapor deposition nozzles matching.

According to the above described structure, the film thickness distribution of the vapor deposition film 302 formed by the vapor deposition particles 301 can be reduced especially in the short side direction. Consequently, the vapor deposition film 302 having the sharp film thickness distribution in the short side direction can be formed.

Thus, performing the scan vapor deposition with the long side direction set to a scan direction allows the vapor deposition film 302 with high definition to be formed.

In the vapor deposition source 10 according to third aspect in the present invention, in the second aspect, a length of each of the pair of long sides of the vapor deposition nozzles of respective stages of the plurality of stages of vapor deposition nozzle sections may be longer than a nozzle length of each of the vapor deposition nozzles in a vertical direction.

In a case of the scan vapor deposition, a takt time can be speeded up by making the opening width of the vapor deposition nozzle longer in the scan direction. Thus, according to the above described structure, the takt time can be speeded up by the scan vapor deposition with the long side direction set to the scan direction.

In the vapor deposition source 10 according to a fourth aspect in the present invention, in the first aspect, the plurality of stages of vapor deposition nozzle sections may include at least two stages of vapor deposition nozzle sections including a first vapor deposition nozzle section (the first nozzle unit 31) and a second vapor deposition nozzle section (the second nozzle unit 51) stacked above the first vapor deposition nozzle section with the hollow portion interposed between the first vapor deposition nozzle section and the second vapor deposition nozzle section. Vapor deposition nozzles (the vapor deposition nozzles 32 and 52)in the first vapor deposition nozzle section and the second vapor deposition nozzle section may each have a rectangular shape with a pair of long sides and a pair of the short sides in plan view, and may be disposed while partially superimposed with each other with directions of long sides of the vapor deposition nozzles orthogonal to each other and directions of short sides of the vapor deposition nozzles orthogonal to each other.

In a case of using the rectangular-shaped vapor deposition nozzle, the sharp film thickness distribution can be realized especially in the short side direction. Consequently, as described above, the arrangement direction of the vapor deposition nozzle in the first vapor deposition nozzle section and the arrangement direction of the vapor deposition nozzle in the second vapor deposition nozzle section are changed by 90 degrees, and the vapor deposition nozzles are stacked with the hollow portion interposed therebetween and thus the sharp film thickness distribution such as a square shape and a quadrangular prism shape can be obtained.

In the vapor deposition source 10 according to a fifth aspect in the present invention, in the fourth aspect, a length of each of the pair of long sides of a vapor deposition nozzle in the second vapor deposition nozzle section may be longer than a nozzle length of the vapor deposition nozzle in a vertical direction.

In a case of the scan vapor deposition, the vapor deposition nozzle of the vapor deposition nozzle section downstream in an ejecting direction of the vapor deposition particles preferably has a shape longer in the scan direction to suppress spread of the vapor deposition particles 301 in the direction orthogonal to the scan direction. Furthermore, in the case of the scan vapor deposition, the opening width of the vapor deposition nozzle longer in the scan direction can speed up the takt time.

Thus, according to the above described structure, the scan vapor deposition with the long side direction of the vapor deposition nozzle in the second vapor deposition nozzle section set to the scan direction can suppress spread of the vapor deposition particles 301 in the direction orthogonal to the scan direction and speed up the takt time.

In the vapor deposition source 10 according to a sixth aspect in the present invention, in the first aspect, the plurality of stages of vapor deposition nozzle sections may include a vapor deposition nozzle section including a vapor deposition nozzle having a rectangular shape with a pair of long sides and a pair of short sides in plan view, and a vapor deposition nozzle section including a vapor deposition nozzle having a square shape in plan view and superimposed with the vapor deposition nozzle.

According to the above described structure, although the film thickness distribution in the short side direction is slightly spread compared with the film thickness distribution in the short side direction of the vapor deposition nozzle in a case that every vapor deposition nozzle in the vapor deposition nozzle section of each stage has a rectangular-shaped opening in plan view, the sharp film thickness distribution can be realized both in the long side direction and the short side direction. In addition, according to the above described structure, the film forming efficiency can be improved as compared with the case that every vapor deposition nozzle in the vapor deposition nozzle section of each stage has a rectangular-shaped opening in plan view.

The vapor deposition source 10 according to a seventh aspect in the present invention, in the sixth aspect, each of the pair of long sides of the vapor deposition nozzle having a rectangular shape with the pair of the long sides and the pair of the short sides in plan view may be longer than a nozzle length of the vapor deposition nozzle in the vertical direction.

In the case of the scan vapor deposition, the takt time can be speeded up by the vapor deposition nozzle including the opening with longer in the scan direction. Thus, according to the above described structure, the takt time can be speeded up by the scan vapor deposition with the long side direction set to the scan direction.

In the vapor deposition source 10 according to an eighth aspect in the present invention, in the first aspect, vapor deposition nozzles of respective stages of the plurality of stages of vapor deposition nozzles may each have a square shape in plan view and may be disposed while superimposed with each other.

According to the structure, the film thickness distribution can be narrowed multiple times in each side direction as described above. Consequently, according to the above described structure, the takt time becomes slow in the case of the scan vapor deposition compared with that the vapor deposition nozzle section including the vapor deposition nozzle with a rectangular-shaped opening in plan view is provided. However, directivity can be improved and thus spread of the film thickness distribution can be suppressed compared with that the vapor deposition nozzle section including the vapor deposition nozzle with a rectangular-shaped opening in plan view is provided.

In the vapor deposition source 10 according to a ninth aspect in the present invention, in any one of the first to eighth aspects, the at least one vapor deposition nozzle includes a plurality of vapor deposition nozzles, and the plurality of the vapor deposition nozzles may be arranged in a first direction in plan view in a vapor deposition nozzle section of each stage of the plurality of stages of vapor deposition nozzle sections.

According to the above described structure, a single vapor deposition source 10 can form the plurality of vapor deposition films 302 in the first direction on the vapor deposition target by the vapor deposition source (specifically, the target film forming substrate 200). Consequently, the vapor deposition film 302 can be efficiency formed even in a case that the vapor deposition target is large, for example.

In the vapor deposition source 10 according to a tenth aspect in the present invention, in any one of the first to ninth aspects, the at least one opening may include a plurality of openings, and the plurality of openings may be formed at positions facing each other on the outer wall interposing a center point of the at least one hollow portion.

According to the above described structure, inner pressure in the hollow portion can be at constant.

In the vapor deposition source 10 according to an eleventh aspect in the present invention, in any one of the first to tenth aspects, the at least one opening may include a plurality of openings, and a total opening area of the plurality of openings in a hollow portion of the at least one hollow portion may be 1/10 or less an opening area of a vapor deposition nozzle (the vapor deposition nozzle 52 or the vapor deposition nozzle 122) in a vapor deposition nozzle section downstream of two vapor deposition nozzle sections directly interposing the hollow portion in an ejecting direction of the vapor deposition particles.

The opening may be formed in a part of the outer wall surrounding the hollow portion. However, the too large opening decreases the number of vapor deposition particles 301 discharged from the vapor deposition nozzle in the vapor deposition nozzle section in the subsequent stage of the hollow portion (that is, downstream of two vapor deposition nozzle sections directly interposing the hollow portion in the ejecting direction of the vapor deposition particles). Consequently, the total opening area of the openings is preferably sufficiently smaller than the opening area of a single vapor deposition nozzle in the vapor deposition nozzle section downstream of two vapor deposition nozzle sections directly interposing the hollow portion in the ejecting direction of the vapor deposition particles, and preferably set within the above described range.

In the vapor deposition source 10 according to a twelfth aspect in the present invention, in any one of the first to eleventh aspects, a pressure adjusting valve 46 may be disposed in the opening.

According to the above described structure, the film forming rate can be adjusted, and excessive discharge of the vapor deposition particles 301 through the opening can be prevented.

The vapor deposition source 10 according to a thirteenth aspect in the present invention, in any one of the first to twelfth aspects, two stages of vapor deposition nozzle sections of the plurality of stages of vapor deposition nozzles may be provided, pressure difference between an outlet and an inlet of a vapor deposition nozzle section of the two stages of vapor deposition nozzle sections on a lower stage side may range from 10 to 1000 times, and pressure difference between an outlet and an inlet of a vapor deposition nozzle section of the two stages of vapor deposition nozzle sections on an upper stage side may range from 10 to 100 times.

Large pressure difference between the outlet and the inlet of the vapor deposition nozzles 32 and 52 of each stage tends to increase scattering of the vapor deposition particles 301. Consequently, pressure difference between the outlet and the inlet of the vapor deposition nozzle 32 in the lower stage side and the pressure difference between the outlet and the inlet of the vapor deposition nozzle 52 in the upper stage side are preferably within the above described range.

The vapor deposition source 10 according to a fourteenth aspect in the present invention, in any one of the first to thirteenth aspects, may further include a vapor deposition particles diffusion section (vapor deposition particles diffusion unit 20) configured to diffuse the vapor deposition particles generated in the vapor deposition particles generation section and supply the vapor deposition particles to the vapor deposition particles ejecting section.

According to the above described structure, the vapor deposition particles 301 can be uniformly ejected from the vapor deposition nozzle in the vapor deposition nozzle section of the highest stage in the vapor deposition particles ejecting section.

The vapor deposition source 10 according to a fifteenth aspect in the present invention, in any one of the first to fourteenth aspects, pressure in the vacuum chamber 2 may be 1.0×10⁻³ Pa or less.

Too high pressure in the vacuum chamber 2 (specifically, pressure in the vacuum chamber 2 over 1.0×10⁻³ Pa) causes the mean free path of the vapor deposition particles 301 to shorten, and the vapor deposition particles 301 are scattered. This may cause decreased efficiency for the vapor deposition particles 301 to reach the target film forming substrate 200 and decreased collimation components. Consequently, pressure in the vacuum chamber 2 is preferably 1.0×10⁻³ Pa or less.

The vapor deposition device 100 according to a sixteenth aspect in the present invention is a vapor deposition device configured to form the vapor deposition film 302 with a predetermined pattern on the target film forming substrate 200, and includes the vapor deposition unit 1 including the vapor deposition source according to any one of the first to fifteenth aspects and the vacuum chamber 2 configured to hold at least the vapor deposition particles ejecting section of the vapor deposition unit 1 in the vacuum chamber2 under reduced pressure atmosphere.

Thus, the effect similar to that of the first aspect can be obtained by using the vapor deposition device 100.

The vapor deposition device 100 according to a seventeenth aspect in the present invention, in the sixteenth aspect, may further include a vapor deposition particles retrieving member 14 configured to retrieve the vapor deposition particles 301 discharged from the opening into the vacuum chamber 2 (the vacuum chamber space 2a).

According to the above described structure, the vapor deposition particles 301 discharged from the opening and not contributing to the film forming can be retrieved for reuse.

A method for manufacturing a vapor deposition film according to an eighteenth aspect in the present invention is a method for forming the vapor deposition film 302 on the target film forming substrate 200 using the vapor deposition device 100. The vapor deposition device 100 may include the vapor deposition unit 1 and the vacuum chamber 2. The vapor deposition unit 1 may include the vapor deposition source 10 including a vapor deposition particles generation section (the vapor deposition particles generation unit 11) configured to heat a vapor deposition material and generate the vapor deposition particles 301 in a gaseous state, and a vapor deposition particles ejecting section (the vapor deposition particles ejecting unit 30) configured to eject the vapor deposition particles 301 generated in the vapor deposition particles generation section. The vapor deposition particles ejecting section may be at least disposed in the vacuum chamber 2 (the vacuum chamber space 2a), and include a plurality of stages of vapor deposition nozzle sections (for example, the first nozzle unit 31 and the second nozzle unit 51) each including at least one vapor deposition nozzle (for example, the vapor deposition nozzles 32 and 52) and stacked while separated from each other in a vertical direction and at least one hollow portion formed between the at least one vapor deposition nozzle and the at least one vapor deposition nozzle of respective stages of the plurality of stages of vapor deposition nozzle sections. The at least one hollow portion may be surrounded on four sides by an outer wall (the side wall 44) including at least one opening formed in the outer wall and connecting the at least one hollow portion and an inner space of the vacuum chamber (the vacuum chamber space 2a). The vacuum chamber 2 may be configured to hold at least the vapor deposition particles ejecting section of the vapor deposition unit 1 in the vacuum chamber 2 under reduced pressure atmosphere. The method may include ejecting the vapor deposition particles 301 from the vapor deposition source 10 under the reduced pressure atmosphere, and covering a target film forming area 202 on the target deposition substrate 200 with the vapor deposition particles 301.

Thus, the effect similar to that of the first aspect can be obtained by using the method for manufacturing a vapor deposition film to form the vapor deposition film 302.

In the method for manufacturing a vapor deposition film according to a nineteenth aspect in the present invention, in the eighteenth aspect, the pressure adjusting valve 46 may be disposed in the at least one opening, and the ejecting the vapor deposition particles may include confirming a film forming rate by ejecting the vapor ejection particles 301 while the pressure adjusting valve 46 is closed, and after the confirming a film forming rate, adjusting a film forming rate by ejecting the vapor ejection particles 302 while film thickness distribution of the vapor ejection film 302 formed on the target film forming substrate 200 is confirmed after the pressure adjusting valve 46 is opened, and a pressure in the at least one hollow portion is lowered than a pressure in a vapor deposition nozzle in a vapor deposition nozzle section upstream of deposition nozzle sections of the plurality of stages of vapor deposition nozzle sections interposing the at least one hollow portion in a direction in which the vapor deposition nozzles are ejected (for example, the pressure in the hollow portion 43 is lowered than the pressure in the vapor deposition nozzle 32, and then the pressure in the hollow portion 113 is lowered than the pressure in the vapor deposition nozzle 122).

According to the above described method, the film forming rate can be adjusted while confirming the film thickness distribution. Thus, both can be balanced, and the sharp film thickness distribution can be realized while a decrease in the film forming rate is suppressed.

In the method for manufacturing the vapor deposition film according to a twentieth aspect in the present invention, in the above described eighteenth or nineteenth aspect, the at least one vapor deposition nozzle may include a plurality of vapor deposition nozzles, the plurality of vapor deposition nozzles are arranged in a first direction in plan view in a vapor deposition nozzle section of each stage of the plurality of stages of vapor deposition nozzle sections, and the covering a target film forming area includes performing a vapor deposition while at least one of the vapor deposition unit 1 and the target film forming substrate 200 is moved relative to the other in a second direction orthogonal to the first direction in plan view.

According to the above described method, the vapor deposition film 302 can be efficiently formed on the target film forming substrate 200 in large size.

The present invention is not limited to each of the embodiments described above, and various modifications may be implemented within a range not departing from the scope of the claims. Embodiments obtained by appropriately combining technical approaches described in each of the different embodiments also fall within the scope of the technology of the present invention. Moreover, novel technical features may be formed by combining the technical approaches described in each of the embodiments.

### INDUSTRIAL APPLICABILITY

The vapor deposition source, the vapor deposition device and the method for manufacturing a vapor deposition film in the present invention can be suitably used for the manufacture of various device using vapor deposition such as EL display devices including organic EL display devices or inorganic EL display devices.

### REFERENCE SIGNS LIST

1 Vapor deposition unit
2 Vacuum chamber
2a Vacuum chamber space
3 Substrate carrying device
4 Vacuum pump
10 Vapor deposition source
10A, 32, 52, 122 Vapor deposition nozzle
11 Vapor deposition particles generation unit (Vapor deposition particles generation section)
13 Vapor deposition source main body
14 Vapor deposition particles retrieving member
20 Vapor deposition particles diffusion unit (Vapor deposition particles diffusion section)
21 Vapor deposition particles diffusion room
22 Vapor deposition particles inlet
24 Peripheral surface
25 Cylinder axis
26 Delivery port
30 Vapor deposition particles ejecting unit (Vapor deposition particles ejecting section)
31 First nozzle unit (Vapor deposition nozzle section, first vapor deposition nozzle section)
32a,52a,122a First side
32b,52b,122b Second side
32c,52c,122c Third side
33, 53, 123 Regulation plate
41, 111 Pressure adjusting unit
42, 112 Space forming opening section
43, 113 Hollow portion
44, 114 Side wall (outer wall)
45, 115 Opening
46 Pressure adjusting valve
46a , 46b Opening end
51 Second nozzle unit (Second vapor deposition nozzle section)
60 Shutter
70 Restriction plate unit
71 Restriction plate opening
72 Restriction plate
80 Vapor deposition mask
81 Mask opening
82 Non-opening
100 Vapor deposition device
121 Third nozzle unit (Third vapor deposition nozzle section)
200 Target film forming substrate
201 Target film forming surface
202 Target film forming area
203 Non-target film forming area
300 Vapor deposition material
301 Vapor deposition particles
302 Vapor deposition film

1. A vapor deposition source comprising:
a vapor deposition particles generation section configured to heat a vapor deposition material and generate vapor deposition particles in a gaseous state; and
a vapor deposition particles ejecting section configured to eject the vapor deposition particles generated in the vapor deposition particles generation section,
wherein the vapor deposition particles ejecting section is at least disposed in a vacuum chamber, and includes
a plurality of stages of vapor deposition nozzle sections each including at least one vapor deposition nozzle, and stacked while separated from each other in a vertical direction; and
at least one hollow portion formed between the at least one vapor deposition nozzle and the at least one vapor deposition nozzle of respective stages of the plurality of stages of vapor deposition nozzle sections, and
the at least one hollow portion is surrounded on four sides by an outer wall including at least one opening formed in the outer wall and connecting the at least one hollow portion and an inner space of the vacuum chamber.

2. The vapor deposition source according to claim 1
wherein vapor deposition nozzles of respective stages of the plurality of stages of vapor deposition nozzle sections each have a rectangular shape with a pair of long sides and a pair of short sides in plan view and, are disposed while superimposed with each other with directions of long sides of the vapor deposition nozzles matching and directions of short sides of the vapor deposition nozzles matching.

3. The vapor deposition source according to claim 2,
wherein a length of each of the pair of long sides of the vapor deposition nozzles of respective stages of the plurality of stages of vapor deposition nozzle sections is longer than a nozzle length of each of the vapor deposition nozzles in a vertical direction.

4. The vapor deposition source according to claim 1,
wherein the plurality of stages of vapor deposition nozzle sections include at least two stages of vapor deposition nozzle sections including a first vapor deposition nozzle section and a second vapor deposition nozzle section stacked above the first vapor deposition nozzle section with the hollow portion interposed between the first vapor deposition nozzle section and the second vapor deposition nozzle section, and vapor deposition nozzles in the first vapor deposition nozzle section and the second vapor deposition nozzle section each have a rectangular shape with a pair of long sides and a pair of the short sides in plan view, and are disposed while partially superimposed with each other with directions of long sides of the vapor deposition nozzles orthogonal to each other and directions of short sides of the vapor deposition nozzles orthogonal to each other.

5. The vapor deposition source according to claim 4,
wherein a length of each of the pair of long sides of a vapor deposition nozzle in the second vapor deposition nozzle section is longer than a nozzle length of the vapor deposition nozzle in a vertical direction.

6. The vapor deposition source according to claim 1,
wherein the plurality of stages of vapor deposition nozzle sections include a vapor deposition nozzle section including a vapor deposition nozzle having a rectangular shape with a pair of long sides and a pair of short side in plan view, and a vapor deposition nozzle section including a vapor deposition nozzle having a square shape in plan view and superimposed with the vapor deposition nozzle.

7. The vapor deposition source according to claim 1,
wherein vapor deposition nozzles of respective stages of the plurality of stages of vapor deposition nozzles each has a square shape in plan view and are disposed while superimposed with each other.

8. The vapor deposition source according to claim 1,
wherein the at least one vapor deposition nozzle includes a plurality of vapor deposition nozzles, and the plurality of vapor deposition nozzles are arranged in a first direction in plan view in a vapor deposition nozzle section of each stage of the plurality of stages of vapor deposition nozzle sections.

9. The vapor deposition source according to claim 1,
wherein the at least one opening includes a plurality of openings, and the plurality of openings are formed at positions facing each other on the outer wall interposing a center point of the at least one hollow portion.

10. The vapor deposition source according to claim 1,
wherein the at least one opening includes a plurality of openings, and a total opening area of the plurality of openings in a hollow portion of the at least one hollow portion is 1/10 or less an opening area of a vapor deposition nozzle in a vapor deposition nozzle section downstream of two vapor deposition nozzle sections directly interposing the hollow portion in an ejecting direction of the vapor deposition particles.

11. The vapor deposition source according to claim 1,
wherein a pressure adjusting valve is disposed in the at least one opening.

12. The vapor deposition source according to claim 1,
wherein two stages of vapor deposition nozzle sections of the plurality of stages of vapor deposition nozzles are provided, pressure difference between an outlet and an inlet of a vapor deposition nozzle section of the two stages of vapor deposition nozzle sections on a lower stage side ranges from 10 to 1000 times, and pressure difference between an outlet and an inlet of a vapor deposition nozzle section of the two stages of vapor deposition nozzle sections on an upper stage side ranges from 10 to 100 times.

13. The vapor deposition source according to claim 1 further comprising
a vapor deposition particles diffusion section configured to diffuse the vapor deposition particles generated in the vapor deposition particles generation section and supply the vapor deposition particles to the vapor deposition particles ejecting section.

14. A vapor deposition device configured to form a vapor deposition film with a predetermined pattern on a target film forming substrate, comprising:
a vapor deposition unit including the vapor deposition source according to claim 1; and
the vacuum chamber configured to hold at least the vapor deposition particles ejecting section of the vapor deposition unit in the vacuum chamber under reduced pressure atmosphere.

15. The vapor deposition device according to claim 14 further comprising
a vapor deposition particles retrieving member configured to retrieve vapor deposition particles discharged from the at least one opening into the vacuum chamber.

16. A method for manufacturing a vapor deposition film, the method involving forming the vapor deposition film on a target film forming substrate using a vapor deposition device, the vapor deposition device including,
a vapor deposition unit including a vapor deposition source including a vapor deposition particles generation section configured to heat a vapor deposition material and generate vapor deposition particles in a gaseous state and a vapor deposition particles ejecting section configured to eject the vapor deposition particles generated in the vapor deposition particles generation section, the vapor deposition particles ejecting section being at least disposed in a vacuum chamber and including a plurality of stages of vapor deposition nozzle sections each including at least one vapor deposition nozzle and stacked while separated from each other in a vertical direction, and at least one hollow portion formed between the at least one vapor deposition nozzle and the at least one vapor deposition nozzle of respective stages of the plurality of stages of vapor deposition nozzle sections, the at least one hollow portion being surrounded on four sides by an outer wall including at least one opening formed in the outer wall and connecting the at least one hollow portion and an inner space of the vacuum chamber, and
the vacuum chamber configured to hold at least the vapor deposition particles ejecting section of the vapor deposition unit in the vacuum chamber under reduced pressure atmosphere,
the method comprising:
ejecting the vapor deposition particles from the vapor deposition source under the reduced pressure atmosphere; and
covering a target film forming area on the target film forming substrate with the vapor deposition particles.

17. The method for manufacturing a vapor deposition film according to claim 16,
wherein a pressure adjusting valve is disposed in the at least one opening, and the ejecting of the vapor deposition particles includes:
confirming a film forming rate by ejecting the vapor ejection particles while the pressure adjusting valve is closed, and
after the confirming a film forming rate, adjusting a film forming rate by ejecting the vapor ejection particles while film thickness distribution of the vapor ejection film formed on the target film forming substrate is confirmed after the pressure adjusting valve is opened, and a pressure in the at least one hollow portion is lowered than a pressure in a vapor deposition nozzle in a vapor deposition nozzle section upstream of deposition nozzle sections of the plurality of stages of vapor deposition nozzle sections interposing the at least one hollow portion in an ejecting direction of the vapor deposition nozzles.

18. The method for manufacturing a vapor deposition film according to claim 16,
wherein the at least one vapor deposition nozzle includes a plurality of vapor deposition nozzles, the plurality of vapor deposition nozzles are arranged in a first direction in plan view in a vapor deposition nozzle section of each stage of the plurality of stages of vapor deposition nozzle sections, and the covering a target film forming area includes performing a vapor deposition while at least one of the vapor deposition unit and the target film forming substrate is moved relative to the other in a second direction orthogonal to the first direction in plan view.
